(19) United States
(12) Patent Application Publication
(10) Pub. No.: US 2020/0243685 A1
(43) Pub. Date: Jul. 30, 2020

(54) SEMICONDUCTOR DEVICE AND MANUFACTURING METHOD OF SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tsutomu MURAKAWA, Isehara (JP); Hajime KIMURA, Atsugi (JP)

(21) Appl. No.: 16/486,182

(22) PCT Filed: Feb. 23, 2018
(86) PCT No.: PCT/IB2018/051127

§ 371 Date: Aug. 15, 2019

(30) Foreign Application Priority Data
Mar. 9, 2017 (JP) 2017-044778

(51) Int. Cl. H01L 29/786; H01L 21/02; H01L 29/24; H01L 29/49; H01L 29/66; H01L 21/4757; H01L 21/4763; H01L 27/12

(52) U.S. Cl. CPC H01L 29/7869; H01L 29/78696; H01L 21/02194; H01L 29/24; H01L 29/4908; H01L 29/66969; H01L 27/10805; H01L 21/47573; H01L 21/47635; H01L 21/0228; H01L 21/02274; H01L 21/02266; H01L 27/1225; H01L 21/02565

(57) ABSTRACT

A semiconductor device that can be miniaturized or highly integrated is provided.

The semiconductor device which includes a first insulator provided over a substrate; an oxide provided over the first insulator; a second insulator provided over the oxide; a conductor provided over the second insulator; a third insulator provided in contact with a side surface of the second insulator and a side surface of the conductor; a fourth insulator provided in contact with at least a top surface of the oxide and in contact with a side surface of the third insulator and a top surface of the conductor; a fifth insulator provided over the fourth insulator; a sixth insulator provided over the fifth insulator; and a seventh insulator provided over the sixth insulator, in which the sixth insulator contains oxygen and the sixth insulator and the first insulator include a region where the sixth insulator and the first insulator are in contact with each other.

### TECHNICAL FIELD

One embodiment of the present invention relates to a semiconductor device and a manufacturing method thereof. Another embodiment of the present invention relates to a semiconductor wafer, a module, and an electronic device.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. In some cases, it can be said that a display device (e.g., a liquid crystal display device and a light-emitting display device), a projection device, a lighting device, an electro-optical device, a power storage device, a memory device, a semiconductor circuit, an imaging device, an electronic device, and the like each include a semiconductor device.

Note that one embodiment of the present invention is not limited to the above technical field. One embodiment of the invention disclosed in this specification and the like relates to an object, a method, or a manufacturing method. Furthermore, one embodiment of the present invention relates to a process, a machine, manufacture, or a composition of matter.

### BACKGROUND ART

In recent years, semiconductor devices have been developed to be used mainly for an LSI, a CPU, or a memory. A CPU is an aggregation of semiconductor elements each provided with an electrode which is a connection terminal, which includes a semiconductor integrated circuit (including at least a transistor and a memory) separated from a semiconductor wafer.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is applied to a wide range of electronic devices such as an integrated circuit (IC) or an image display device (also simply referred to as a display device). A silicon-based semiconductor material is widely known as a semiconductor thin film applicable to the transistor; in addition, an oxide semiconductor has attracted attention as another material.

It is known that a transistor including an oxide semiconductor has an extremely low leakage current in a non-conduction state. For example, a low-power-consumption CPU or the like utilizing a characteristic of low leakage current of the transistor including an oxide semiconductor has been disclosed (see Patent Document 1).

In addition, a technique in which oxide semiconductor layers with different electron affinities (or conduction band minimum states) are stacked to increase the carrier mobility of a transistor is disclosed (see Patent Document 2 and Patent Document 3).

In recent years, demand for an integrated circuit in which transistors and the like are integrated with high density has risen with reductions in the size and weight of an electronic device. In addition, the productivity of a semiconductor device including an integrated circuit is required to be improved.

### REFERENCES

### Patent Document

### [Patent Document 1] Japanese Published Patent Application No. 2012-257187

### [Patent Document 2] Japanese Published Patent Application No. 2011-124360

### [Patent Document 3] Japanese Published Patent Application No. 2011-138934

### SUMMARY OF THE INVENTION

### Problems to be Solved by the Invention

An object of one embodiment of the present invention is to provide a semiconductor device having favorable electrical characteristics. Another object of one embodiment of the present invention is to provide a semiconductor device that can be miniaturized or highly integrated. Another object of one embodiment of the present invention is to provide a semiconductor device with high productivity.

Another object of one embodiment of the present invention is to provide a semiconductor device capable of retaining data for a long time. Another object of one embodiment of the present invention is to provide a semiconductor device capable of high-speed data writing. Another object of one embodiment of the present invention is to provide a semiconductor device with high design flexibility. Another object of one embodiment of the present invention is to provide a semiconductor device in which power consumption can be reduced. Another object of one embodiment of the present invention is to provide a novel semiconductor device.

Note that the descriptions of these objects do not disturb the existence of other objects. In one embodiment of the present invention, there is no need to achieve all of these objects. Objects other than these will be apparent from the descriptions of the specification, the drawings, the claims, and the like, and can be derived from the descriptions of the specification, the drawings, the claims, and the like.

### Means for Solving the Problems

One embodiment of the present invention is a semiconductor device including a first insulator provided over a substrate; an oxide over the first insulator; a second insulator over the oxide; a conductor over the second insulator; a third insulator in contact with a side surface of the second insulator and a side surface of the conductor; a fourth insulator in contact with at least a top surface of the oxide and in contact with a side surface of the third insulator and a top surface of the conductor; a fifth insulator over the fourth insulator; a sixth insulator over the fifth insulator; and a seventh insulator over the sixth insulator, in which the sixth insulator contains oxygen and the sixth insulator and the first insulator include a region where the sixth insulator and the first insulator are in contact with each other.

Another embodiment of the present invention is a semiconductor device including a first insulator provided over a substrate; a first oxide over the first insulator; a second oxide over the first oxide; a third oxide over the second oxide; a second insulator over the third oxide; a conductor over the second insulator; a third insulator in contact with a side surface of the second insulator and a side surface of the conductor; a fourth insulator in contact with at least a top surface of the second oxide and in contact with a side surface of the third oxide, a side surface of the third insulator, and a top surface of the conductor; a fifth insulator over the fourth insulator; a sixth insulator over the fifth insulator; and a seventh insulator over the sixth insulator, in which the sixth insulator contains oxygen, the sixth insulator and the first insulator include a region where the sixth insulator and the first insulator are in contact with each other, the third oxide less easily transmits oxygen than the second insulator, and the third oxide less easily transmits oxygen than the second oxide.

In the semiconductor device, the third insulator, the fifth insulator, and the seventh insulator include an oxide of one or both of aluminum and hafnium.

In the semiconductor device, an angle formed by a side surface of the conductor and a bottom surface of the oxide is greater than or equal to 75° and less than or equal to 100°.

In the semiconductor device, the oxide has a curved surface between a side surface and a top surface of the oxide, and a radius of curvature of the curved surface is greater than or equal to 3 nm and less than or equal to 10 nm.

In the semiconductor device, the oxide includes In, an element M (M is Al, Ga, Y, or Sn), and Zn.

In the semiconductor device, the oxide includes a first region and a second region overlapping with the second insulator, at least part of the first region is in contact with the fourth insulator, and the first region has a higher concentration of at least one of hydrogen and nitrogen than the second region.

In the semiconductor device, the second region includes a portion overlapping with the third insulator and the second insulator.

In the semiconductor device, the conductor includes a conductive oxide.

In the semiconductor device, the fourth insulator includes one or both of hydrogen and nitrogen.

One embodiment of the present invention is a manufacturing method of a semiconductor device, which includes the steps of: forming a first insulator over a substrate; forming an oxide layer over the first insulator; forming a first insulating film and a conductive film in order over the oxide layer; etching the first insulating film and the conductive film to form a second insulator and a conductor; depositing a second insulating film by an ALD method to cover the first insulator, the oxide layer, the second insulator, and the conductor; performing dry etching treatment on the second insulating film to form a third insulator in contact with a side surface of the second insulator and a side surface of the conductor; depositing a third insulating film by a PECVD method to cover the first insulator, the oxide layer, the third insulator, and the conductor; depositing a fourth insulating film over the third insulating film; processing the third insulating film and the fourth insulating film so that the oxide layer is covered, to form a fourth insulator and a fifth insulator; forming a sixth insulator over the fifth insulator; and forming a seventh insulator over the sixth insulator by a sputtering method.

### Effect of the Invention

One embodiment of the present invention can provide a semiconductor device having favorable electrical characteristics. One embodiment of the present invention can provide a semiconductor device that can be miniaturized or highly integrated. One embodiment of the present invention can provide a semiconductor device with high productivity.

A semiconductor device capable of retaining data for a long time can be provided. A semiconductor device capable of high-speed data writing can be provided. A semiconductor device with high design flexibility can be provided. A semiconductor device in which power consumption can be reduced can be provided. A novel semiconductor device can be provided.

Note that the descriptions of these effects do not disturb the existence of other effects. One embodiment of the present invention does not have to have all of these effects. Other effects will be apparent from and can be derived from the descriptions of the specification, the drawings, the claims, and the like.

### BRIEF DESCRIPTION OF THE DRAWINGS

FIG. 1 A top view and cross-sectional views of a semiconductor device of one embodiment of the present invention.

FIG. 2 A top view and cross-sectional views of a semiconductor device of one embodiment of the present invention.

FIG. 3 A top view and cross-sectional views of a semiconductor device of one embodiment of the present invention.

FIG. 4 A top view and cross-sectional views of a semiconductor device of one embodiment of the present invention.

FIG. 5 A top view and cross-sectional views of a semiconductor device of one embodiment of the present invention.

FIG. 6 A top view and cross-sectional views of a semiconductor device of one embodiment of the present invention.

FIG. 7 A top view and cross-sectional views of a semiconductor device of one embodiment of the present invention.

FIG. 8 A top view and cross-sectional views of a semiconductor device of one embodiment of the present invention.

FIG. 9 A top view and cross-sectional views of a semiconductor device of one embodiment of the present invention.

FIG. 10 A top view and cross-sectional views of a semiconductor device of one embodiment of the present invention.

FIG. 11 Cross-sectional views of a semiconductor device of one embodiment of the present invention.

FIG. 12 Top views of a semiconductor device of one embodiment of the present invention.

FIG. 13 Top views of a semiconductor device of one embodiment of the present invention.

FIG. 14 Top views of a semiconductor device of one embodiment of the present invention.

FIG. 15 A top view and cross-sectional views illustrating a method for manufacturing a semiconductor device of one embodiment of the present invention.

FIG. 16 A top view and cross-sectional views illustrating a method for manufacturing a semiconductor device of one embodiment of the present invention.

FIG. 17 A top view and cross-sectional views illustrating a method for manufacturing a semiconductor device of one embodiment of the present invention.

FIG. 18 A top view and cross-sectional views illustrating a method for manufacturing a semiconductor device of one embodiment of the present invention.

FIG. 19 A top view and cross-sectional views illustrating a method for manufacturing a semiconductor device of one embodiment of the present invention.

FIG. 20 A top view and cross-sectional views illustrating a method for manufacturing a semiconductor device of one embodiment of the present invention.

FIG. 21 A top view and cross-sectional views illustrating a method for manufacturing a semiconductor device of one embodiment of the present invention.

FIG. 22 A top view and cross-sectional views illustrating a method for manufacturing a semiconductor device of one embodiment of the present invention.

FIG. 23 A top view and cross-sectional views illustrating a method for manufacturing a semiconductor device of one embodiment of the present invention.

FIG. 24 A diagram showing an energy band structure of an oxide.

FIG. 25 A cross-sectional view illustrating a structure of a memory device of one embodiment of the present invention.

FIG. 26 A circuit diagram and a cross-sectional view of a memory device of one embodiment of the present invention.

FIG. 27 A cross-sectional view illustrating a structure of a memory device of one embodiment of the present invention.

FIG. 28 A cross-sectional view illustrating a structure of a memory device of one embodiment of the present invention.

FIG. 29 A block diagram illustrating a configuration example of a memory device of one embodiment of the present invention.

FIG. 30 Circuit diagrams illustrating configuration examples of a memory device of one embodiment of the present invention.

FIG. 31 A block diagram illustrating a configuration example of a memory device of one embodiment of the present invention.

FIG. 32 A block diagram and a circuit diagram illustrating a configuration example of a memory device of one embodiment of the present invention.

FIG. 33 Block diagrams illustrating a configuration example of a semiconductor device of one embodiment of the present invention.

FIG. 34 A block diagram and a circuit diagram illustrating a configuration example of a semiconductor device of one embodiment of the present invention and a timing chart showing an operation example of the semiconductor device.

FIG. 35 A block diagram illustrating a configuration example of a semiconductor device of one embodiment of the present invention.

FIG. 36 A circuit diagram illustrating a configuration example of a semiconductor device of one embodiment of the present invention and a timing chart showing an operation example of the semiconductor device.

FIG. 37 A block diagram illustrating a structure example of an AI system of one embodiment of the present invention.

FIG. 38 Block diagrams illustrating application examples of an AI system of one embodiment of the present invention.

FIG. 39 A schematic perspective view illustrating a structure example of an IC incorporating an AI system of one embodiment of the present invention.

FIG. 40 Top views of a semiconductor wafer of one embodiment of the present invention.

FIG. 41 A flow chart and a schematic perspective view showing an example of a fabricating process of an electronic component.

FIG. 42 Diagrams illustrating electronic devices of one embodiment of the present invention.

FIG. 43 A top view and cross-sectional views of a semiconductor device of one embodiment of the present invention.

FIG. 44 A top view and cross-sectional views of a semiconductor device of one embodiment of the present invention.

FIG. 45 A top view and cross-sectional views of a semiconductor device of one embodiment of the present invention.

FIG. 46 Top views of display devices.

FIG. 47 A cross-sectional view of a display device.

FIG. 48 A cross-sectional view of a display device.

FIG. 49 A block diagram and circuit diagrams of a display device.

FIG. 50 A structure example of a display module.

### MODE FOR CARRYING OUT THE INVENTION

Hereinafter, embodiments will be described with reference to drawings. Note that the embodiments can be implemented with many different modes, and it will be readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views illustrating ideal examples, and embodiments of the present invention are not limited to shapes or values shown in the drawings. For example, in the actual manufacturing process, a layer, a resist mask, or the like might be unintentionally reduced in size by treatment such as etching, which is not illustrated in some cases for easy understanding. In the drawings, the same portions or portions having similar functions are denoted by the same reference numerals in different drawings, and explanation thereof will not be repeated in some cases. Furthermore, the same hatching pattern is applied to portions having similar functions, and the portions are not denoted by reference numerals in some cases.

Especially in a top view (also referred to as a “plan view”), a perspective view, or the like, some components might not be illustrated for easy understanding of the invention. In addition, some hidden lines and the like might not be shown.

Note that the ordinal numbers such as “first,” “second,” and the like in this specification and the like are used for convenience and do not denote the order of steps or the stacking order of layers. Therefore, for example, description can be made even when “first” is replaced with “second,” “third,” or the like as appropriate. In addition, the ordinal numbers in this specification and the like are not necessarily the same as those which specify one embodiment of the present invention.

In this specification, terms for describing arrangement, such as “over” and “under”, are used for convenience in describing a positional relation between components with reference to drawings. Furthermore, the positional relation between components is changed as appropriate in accordance with a direction in which each component is described. Thus, terms for the description are not limited to those used in this specification, and description can be made appropriately depending on the situation.

In the case where there is an explicit description, X and Y are connected, in this specification and the like, for example, the case where X and Y are electrically connected, X and Y are functionally connected, and X and Y are directly connected are disclosed in this specification and the like. Accordingly, without being limited to a predetermined connection relation, for example, a connection relation shown in drawings or texts, a connection relation other than one shown in drawings or texts is included in the drawings or the texts.

Here, X and Y each denote an object (e.g., a device, an element, a circuit, a wiring, an electrode, a terminal, a conductive film, or a layer).

An example of the case where X and Y are directly connected is the case where an element that allows an electrical connection between X and Y (for example, a switch, a transistor, a capacitor, an inductor, a resistor, a diode, a display element, a light-emitting element, a load, or the like) is not connected between X and Y, and is the case where X and Y are connected without the element that allows the electrical connection between X and Y (for example, a switch, a transistor, a capacitor, an inductor, a resistor, a diode, a display element, a light-emitting element, a load, or the like) provided therebetween.

An example of the case where X and Y are electrically connected is the case where one or more elements that allow an electrical connection between X and Y (for example, a switch, a transistor, a capacitor, an inductor, a resistor, a diode, a display element, a light-emitting element, a load, or the like) can be connected between X and Y. Note that a switch has a function of being controlled to be turned on or off. That is, a switch has a function of being in a conduction state (on state) or a non-conduction state (off state) to control whether or not current flows. Alternatively, the switch has a function of selecting and changing a current path. Note that the case where X and Y are electrically connected includes the case where X and Y are directly connected.

An example of the case where X and Y are functionally connected is the case where one or more circuits that allow functional connection between X and Y (for example, a logic circuit (an inverter, a NAND circuit, a NOR circuit, or the like), a signal converter circuit (a DA converter circuit, an AD converter circuit, a gamma correction circuit, or the like), a potential level converter circuit (a power supply circuit (a step-up circuit, a step-down circuit, or the like), a level shifter circuit for changing the potential level of a signal, or the like), a voltage source, a current source, a switching circuit, an amplifier circuit (a circuit capable of increasing signal amplitude, the amount of current, or the like, an operational amplifier, a differential amplifier circuit, a source follower circuit, a buffer circuit, or the like), a signal generator circuit, a memory circuit, a control circuit, or the like) can be connected between X and Y. Note that even if another circuit is sandwiched between X and Y, for example, X and Y are regarded as being functionally connected in the case where a signal output from X is transmitted to Y. Note that the case where X and Y are functionally connected includes the case where X and Y are directly connected and the case where X and Y are electrically connected.

In this specification and the like, a transistor is an element having at least three terminals of a gate, a drain, and a source. In addition, the transistor includes a channel formation region between the drain (a drain terminal, a drain region, or a drain electrode) and the source (a source terminal, a source region, or a source electrode), and current can flow between the source and the drain through the channel formation region. Note that in this specification and the like, a channel region refers to a region through which current mainly flows.

Furthermore, functions of a source and a drain might be switched when transistors having different polarities are employed or a direction of current is changed in circuit operation, for example. Therefore, the terms “source” and “drain” are used interchangeably in some cases in this specification and the like.

Note that the channel length refers to, for example, the distance between a source (a source region or a source electrode) and a drain (a drain region or a drain electrode) in a region where a semiconductor (or a portion where current flows in a semiconductor when a transistor is in an on state) and a gate electrode overlap with each other or a region where a channel is formed in a top view of the transistor. Note that in one transistor, channel lengths in all regions are not necessarily the same. In other words, the channel length of one transistor is not fixed to one value in some cases. Thus, in this specification, the channel length is any one of values, the maximum value, the minimum value, or the average value in a region where a channel is formed.

The channel width refers to, for example, the length of a portion where a source and a drain face each other in a region where a semiconductor (or a portion where current flows in a semiconductor when a transistor is in an on state) and a gate electrode overlap with each other, or a region where a channel is formed. Note that in one transistor, channel widths in all regions are not necessarily the same. In other words, the channel width of one transistor is not fixed to one value in some cases. Thus, in this specification, the channel width is any one of values, the maximum value, the minimum value, or the average value in a region where a channel is formed.

Note that depending on transistor structures, a channel width in a region where a channel is actually formed (hereinafter, referred to as an “effective channel width”) is different from a channel width shown in a top view of a transistor (hereinafter, referred to as an “apparent channel width”) in some cases. For example, when a gate electrode covers a side surface of a semiconductor, an effective channel width is greater than an apparent channel width, and its influence cannot be ignored in some cases. For example, in a miniaturized transistor having a gate electrode covering a side surface of a semiconductor, the proportion of a channel formation region formed in the side surface of the semiconductor is increased in some cases. In that case, an effective channel width is greater than an apparent channel width.

In such a case, an effective channel width is difficult to estimate by actual measurement in some cases. For example, estimation of an effective channel width from a design value requires an assumption that the shape of a semiconductor is known. Accordingly, in the case where the shape of a semiconductor is not known accurately, it is difficult to measure an effective channel width accurately.

Thus, in this specification, an apparent channel width is referred to as a “surrounded channel width (SCW)” in some cases. Furthermore, in this specification, the simple term “channel width” refers to a surrounded channel width or an apparent channel width in some cases. Alternatively, in this specification, the simple term “channel width” refers to an effective channel width in some cases. Note that a channel length, a channel width, an effective channel width, an apparent channel width, a surrounded channel width, and the like can be determined, for example, by analyzing a cross-sectional TEM image and the like.

Note that an impurity in a semiconductor refers to, for example, elements other than the main components of a semiconductor. For example, an element with a concentration of lower than 0.1 atomic % can be regarded as an impurity. When an impurity is contained, for example, DOS (Density of States) in a semiconductor may be increased, or the crystallinity may be decreased. In the case where the semiconductor is an oxide semiconductor, examples of an impurity which changes characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. In the case of an oxide semiconductor, water also serves as an impurity in some cases. Also in the case of an oxide semiconductor, oxygen vacancies are formed by entry of impurities, for example. Furthermore, when the semiconductor is silicon, examples of the impurity which changes characteristics of the semiconductor include oxygen, Group 1 elements except hydrogen, Group 2 elements, Group 13 elements, and Group 15 elements.

In this specification and the like, a silicon oxynitride film contains more oxygen than nitrogen. A silicon oxynitride film preferably contains, for example, oxygen, nitrogen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively. A silicon nitride oxide film contains more nitrogen than oxygen. A silicon nitride oxide film preferably contains nitrogen, oxygen, silicon, and hydrogen in the ranges of 55 atomic % to 65 atomic % inclusive, 1 atomic % to 20 atomic % inclusive, 25 atomic % to 35 atomic % inclusive, and 0.1 atomic % to 10 atomic % inclusive, respectively.

In this specification and the like, the term “film” and the term “layer” can be interchanged with each other. For example, the term “conductive layer” can be changed into the term “conductive film” in some cases. For another example, the term “insulating film” can be changed into the term “insulating layer” in some cases.

In addition, in this specification and the like, the term “insulator” can be replaced with insulating film or insulating layer. Moreover, the term “conductor” can be replaced with conductive film or conductive layer. Furthermore, the term “semiconductor” can be replaced with semiconductor film or semiconductor layer.

Unless otherwise specified, transistors described in this specification and the like are field-effect transistors. Furthermore, unless otherwise specified, transistors described in this specification and the like are n-channel transistors. Thus, unless otherwise specified, the threshold voltage (also referred to as “Vth”) is higher than 0 V.

In this specification and the like, “parallel” indicates a state where two straight lines are placed at an angle of greater than or equal to −10° and less than or equal to 10°. Thus, the case where the angle is greater than or equal to −5° and less than or equal to 5° is also included. In addition, the term “substantially parallel” indicates a state where two straight lines are placed at an angle of greater than or equal to −30° and less than or equal to 30°. Moreover, “perpendicular” indicates a state where two straight lines are placed at an angle of greater than or equal to 80° and less than or equal to 100°. Thus, the case where the angle is greater than or equal to 85° and less than or equal to 95° is also included. Furthermore, “substantially perpendicular” indicates a state where two straight lines are placed at an angle of greater than or equal to 60° and less than or equal to 120°.

In this specification, in the case where a crystal is a trigonal crystal or a rhombohedral crystal, the crystal is regarded as a hexagonal crystal system.

Note that in this specification, a barrier film refers to a film having a function of suppressing transmission of oxygen and impurities such as hydrogen, and in the case where the barrier film has conductivity, it is referred to as a conductive barrier film in some cases.

In this specification and the like, a metal oxide means an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, in the case where an OS FET is stated, it can also be referred to as a transistor including an oxide or an oxide semiconductor.

### Embodiment 1

An example of a semiconductor device including a transistor 200 of one embodiment of the present invention is described below.

### Structure Example 1 of Semiconductor Device

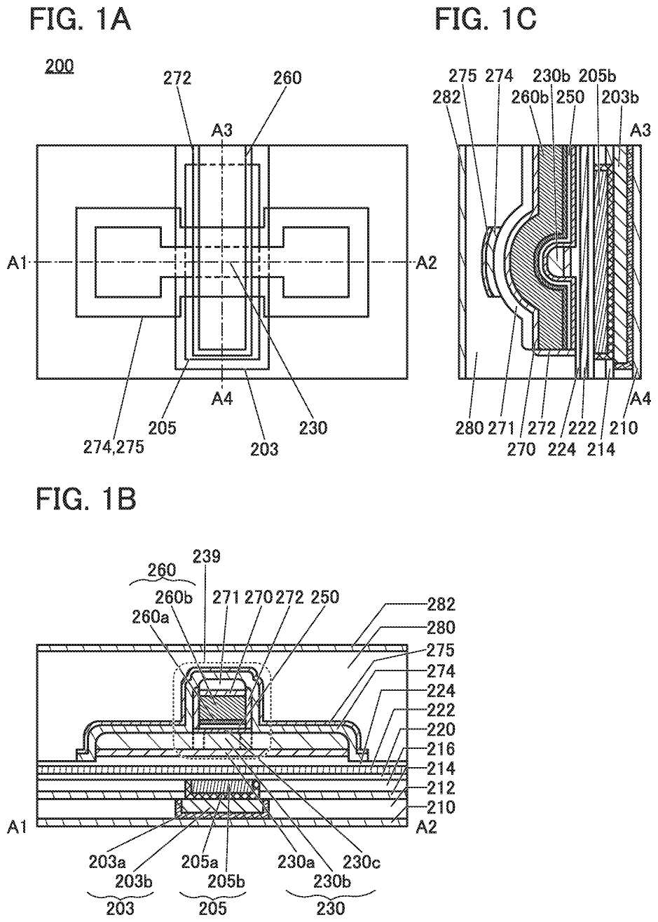

FIG. 1(A), FIG. 1(B), and FIG. 1(C) are a top view and cross-sectional views of the transistor 200 of one embodiment of the present invention and the periphery of the transistor 200.

FIG. 1(A) is a top view of the semiconductor device including the transistor 200. FIG. 1(B) and FIG. 1(C) are cross-sectional views of the semiconductor device. Here, FIG. 1(B) is a cross-sectional view of a portion indicated by a dashed-dotted line A1-A2 in FIG. 1(A), and is a cross-sectional view in the channel length direction of the transistor 200. FIG. 1(C) is a cross-sectional view of a portion indicated by a dashed-dotted line A3-A4 in FIG. 1(A), and is a cross-sectional view in the channel width direction of the transistor 200. For clarity of the drawing, some components are not illustrated in the top view in FIG. 1(A).

The semiconductor device of one embodiment of the present invention includes the transistor 200 and an insulator 210, an insulator 212, an insulator 280, and an insulator 282 that serve as interlayer films. The semiconductor device further includes a conductor 203 (a conductor 203a and a conductor 203b) that is electrically connected to the transistor 200 and serves as a wiring.

In the conductor 203, a conductor 203a that is formed in contact with an inner wall of an opening of the insulator 212, and the conductor 203b is formed on an inner side than the conductor 203a. Here, the top surface of the conductor 203 can be at substantially the same level as the top surface of the insulator 212. Although a structure in which the conductor 203a and the conductor 203b are stacked in the transistor 200 is illustrated, the present invention is not limited to this structure. For example, a structure in which only the conductor 203b is provided may be employed.

### [Transistor 200]

As illustrated in FIG. 1, the transistor 200 includes an insulator 214 and an insulator 216 provided over a substrate (not illustrated); a conductor 205 provided to be embedded in the insulator 214 and the insulator 216; an insulator 220 provided over the insulator 216 and the conductor 205; an insulator 222 provided over the insulator 220; an insulator 224 provided over the insulator 222; an oxide 230 (an oxide 230a, an oxide 230b, and an oxide 230c) provided over the insulator 224; an insulator 250 provided over the oxide 230; a conductor 260 (a conductor 260a and a conductor 260b) provided over the insulator 250; an insulator 270 and an insulator 271 provided over the conductor 260; an insulator 272 provided in contact with at least side surfaces of the insulator 250 and the conductor 260; an insulator 274 provided in contact with the oxide 230 and the insulator 272; and an insulator 275 over the insulator 274. Furthermore, the transistor 200 includes a region in which the insulator 280 and the insulator 224 are in contact with each other.

Although the transistor 200 having a structure in which the oxide 230a, the oxide 230b, and the oxide 230c are stacked is described, the present invention is not limited thereto. For example, as illustrated in FIG. 1, the transistor 200 may have a three-layer structure of the oxide 230a, the oxide 230b, and the oxide 230c or may have a stacked-layer structure of four or more layers. Alternatively, a structure in which a single layer of the oxide 230b is provided or a structure in which the oxide 230b and the oxide 230c are provided may be employed. Although a structure in which the conductor 260a and the conductor 260b are stacked is employed in the transistor 200, the present invention is not limited to this structure. For example, a single-layer structure or a stacked-layer structure of three or more layers may be employed.

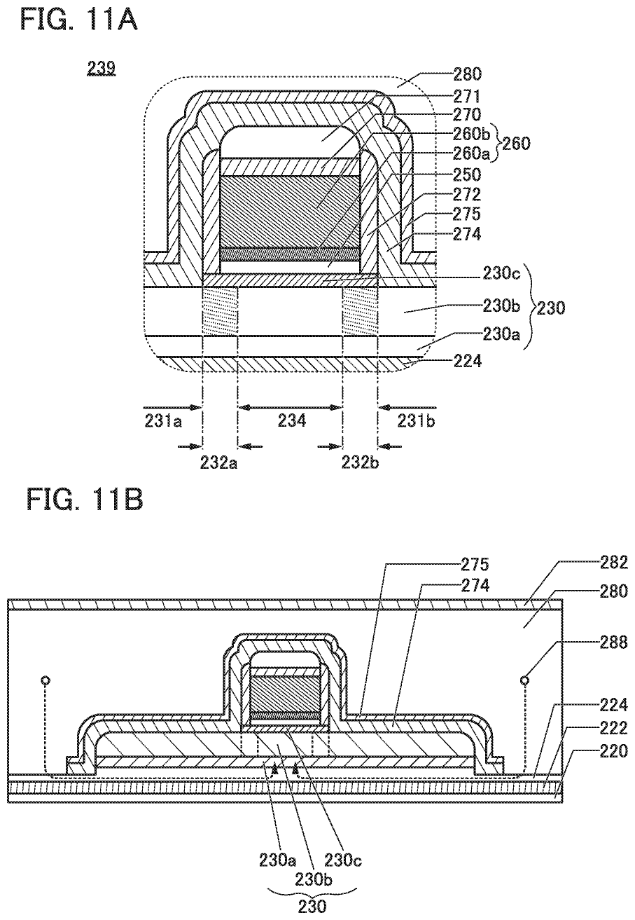

FIG. 11(A) shows an enlarged view of a region 239 including a channel and the vicinity thereof, which is surrounded by a dashed line in FIG. 1(B).

As illustrated in FIG. 11(A), the oxide 230 includes a junction region 232 (a junction region 232a and a junction region 232b) between a region 234 functioning as a channel formation region in the transistor 200 and a region 231 (a region 231a and a region 231b) functioning as a source region or a drain region. The region 231 functioning as the source region or the drain region is a region having a high carrier density and reduced resistance. The region 234 functioning as the channel formation region is a region having a lower carrier density than the region 231 functioning as the source region or the drain region. The junction region 232 is a region having a lower carrier density than the region 231 functioning as the source region or the drain region and having a higher carrier density than the region 234 functioning as the channel formation region. That is, the junction region 232 functions as a junction region between the channel formation region and the source region or the drain region.

The junction region prevents a high-resistance region from being formed between the region 231 functioning as the source region or the drain region and the region 234 functioning as the channel formation region, thereby increasing on-state current of the transistor.

The junction region 232 sometimes functions as an overlap region (also referred to as an Lov region) which overlaps with the conductor 260 that functions as a gate electrode.

Note that it is preferable that the region 231 be in contact with the insulator 274. It is preferable that the concentration of at least one of a metal element such as indium and impurity elements such as hydrogen and nitrogen in the region 231 be higher than that in the junction region 232 and the region 234.

The junction region 232 includes a region overlapping with the insulator 272. The concentration of at least one of a metal element such as indium and impurity elements such as hydrogen and nitrogen in the junction region 232 is preferably higher than that in the region 234. On the other hand, the concentration of at least one of a metal element such as indium and impurity elements such as hydrogen and nitrogen in the junction region 232 is preferably lower than that in the region 231.

The region 234 overlaps with the conductor 260. The region 234 is provided between the junction region 232a and the junction region 232b, and the concentration of at least one of a metal element such as indium and impurity elements such as hydrogen and nitrogen in the region 234 is preferably lower than that in the region 231 and the junction region 232.

In the oxide 230, a boundary between the region 231, the junction region 232, and the region 234 cannot be observed clearly in some cases. The concentration of a metal element such as indium or impurity elements such as hydrogen and nitrogen, which is detected in each region, may be gradually changed (such a change is also referred to as gradation) not only between the regions but also in each region. That is, the region closer to the region 234, from the region 231 toward the junction region 232, preferably has a lower concentration of a metal element such as indium and impurity elements such as hydrogen and nitrogen.

Although the region 234, the region 231, and the junction region 232 are formed in the oxide 230b in FIG. 11(A), one embodiment of the present invention is not limited thereto, and for example, these regions may also be formed in the oxide 230a or the oxide 230c. Although boundaries between the regions are indicated substantially perpendicularly to the top surface of the oxide 230 in the figure, this embodiment is not limited thereto. For example, the junction region 232a may have a shape which recedes to the A1 (in FIG. 1(B)) side in the vicinity of the bottom surface of the oxide 230b, or the junction region 232b may have a shape which recedes to the A2 (in FIG. 1(B)) side in the vicinity of the bottom surface of the oxide 230b.

In the transistor 200, the oxide 230 is preferably formed using a metal oxide functioning as an oxide semiconductor (hereinafter also referred to as an oxide semiconductor). A transistor formed using an oxide semiconductor has an extremely low leakage current (off-state current) in a non-conduction state; thus, a semiconductor device with low power consumption can be provided. An oxide semiconductor can be deposited by a sputtering method or the like and thus can be used in a transistor included in a highly integrated semiconductor device.

However, the transistor formed using an oxide semiconductor is likely to have its electrical characteristics changed by impurities and oxygen vacancies in the oxide semiconductor; as a result, the reliability is reduced, in some cases. Hydrogen contained in an oxide semiconductor reacts with oxygen bonded to a metal atom to be water, and thus causes an oxygen vacancy, in some cases. Entry of hydrogen into the oxygen vacancy generates an electron serving as a carrier in some cases. A transistor including an oxide semiconductor containing oxygen vacancies in the channel formation region is likely to have normally-on characteristics. Thus, it is preferable that oxygen vacancies in the channel formation region be reduced as much as possible.

When oxygen vacancies exist at an interface between the region 234 in the oxide 230 where a channel is formed and the insulator 250 functioning as a gate insulating film, a variation in the electrical characteristics is likely to occur and the reliability is reduced in some cases.

In view of the above, the insulator 250 in contact with the region 234 of the oxide 230 preferably contains oxygen at a higher proportion than oxygen in the stoichiometric composition (also referred to as excess oxygen). That is, excess oxygen contained in the insulator 250 is diffused into the region 234, whereby oxygen vacancies in the region 234 can be reduced.

The insulator 272 is preferably provided in contact with the insulator 250. For example, it is preferable that the insulator 272 have a function of suppressing diffusion of oxygen (e.g., at least one of oxygen atoms, oxygen molecules, and the like) (that the insulator 272 not easily transmit the above oxygen). When the insulator 272 has a function of suppressing diffusion of oxygen, oxygen in an excess-oxygen region is not diffused to the insulator 274 side and thus is supplied to the region 234 efficiently. Thus, formation of oxygen vacancies at an interface between the oxide 230 and the insulator 250 can be suppressed, leading to an improvement in the reliability of the transistor 200.

Furthermore, the transistor 200 is preferably covered with an insulator which has a barrier property and prevents entry of impurities such as water or hydrogen. The insulator having a barrier property is an insulator formed using an insulating material having a function of suppressing diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material which does not easily transmit the above impurities). Alternatively, an insulating material having a function of suppressing diffusion of oxygen (e.g., at least one of oxygen atoms, oxygen molecules, and the like) (an insulating material which does not easily transmit the above oxygen) is preferably used.

The detailed structure of a semiconductor device including the transistor 200 of one embodiment of the present invention is described below.

The conductor 205 functioning as a second gate electrode is provided to overlap with the oxide 230 and the conductor 260.

Here, the conductor 205 is preferably provided to be longer in the channel width direction than the region 234 in the oxide 230. It is particularly preferable that the conductor 205 extend to a region on an outer side of the end portion of the region 234 of the oxide 230 that intersects with the channel width direction. That is, it is preferable that the conductor 205 and the conductor 260 overlap with each other with the insulator therebetween at the side surface of the oxide 230 in the channel width direction.

Here, the conductor 260 functions as a first gate electrode in some cases. The conductor 205 functions as a second gate electrode in some cases. In that case, by changing a potential applied to the conductor 205 independently of a potential applied to the conductor 260, the threshold voltage of the transistor 200 can be controlled. In particular, by applying a negative potential to the conductor 205, the threshold voltage of the transistor 200 can be higher than 0 V, and the off-state current can be reduced. Accordingly, a drain current when a voltage applied to the conductor 260 is 0 V can be reduced.

As illustrated in FIG. 1(A), the conductor 205 is provided to overlap with the oxide 230 and the conductor 260. The conductor 205 is preferably provided to overlap with the conductor 260 also in a region on an outer side of the end portion of the oxide 230 that intersects with the channel width direction (W length direction). That is, the conductor 205 and the conductor 260 preferably overlap with each other with the insulator therebetween on an outer side of the side surface of the oxide 230.

With the above structure, in the case where potentials are applied to the conductor 260 and the conductor 205, an electric field generated from the conductor 260 and an electric field generated from the conductor 205 are connected, so that a closed circuit which covers the channel formation region in the oxide 230 can be formed.

That is, the channel formation region in the region 234 can be electrically surrounded by the electric field of the conductor 260 functioning as the first gate electrode and the electric field of the conductor 205 functioning as the second gate electrode. In this specification, such a transistor structure in which the channel formation region is electrically surrounded by the electric fields of the first gate electrode and the second gate electrode is referred to as a surrounded channel (S-channel) structure.

In the conductor 205, a conductor 205a is formed in contact with an inner wall of an opening of the insulator 214 and the insulator 216, and a conductor 205b is formed on an inner side than the conductor 205a. Here, top surfaces of the conductor 205a and the conductor 205b can be at substantially the same level as the top surface of the insulator 216. Although a structure in which the conductor 205a and the conductor 205b are stacked in the transistor 200 has been described, the present invention is not limited thereto. For example, a structure in which only the conductor 205b is provided may be employed.

The conductor 205a is preferably formed using a conductive material having a function of suppressing diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (a conductive material which does not easily transmit the above impurities). Alternatively, the conductor 205a is preferably formed using a conductive material having a function of suppressing diffusion of oxygen (e.g., at least one of oxygen atoms, oxygen molecules, and the like) (a conductive material which does not easily transmit the above oxygen). Note that in this specification, a function of suppressing diffusion of impurities or oxygen means a function of suppressing diffusion of any one or all of the above impurities or the above oxygen.

When the conductor 205a has a function of suppressing diffusion of oxygen, the conductivity of the conductor 205b can be prevented from being lowered because of oxidation. As a conductive material having a function of suppressing diffusion of oxygen, for example, tantalum, tantalum nitride, ruthenium, ruthenium oxide, or the like is preferably used. Accordingly, the conductor 205a may be a single layer or a stacked layer of the above conductive materials. Thus, impurities such as hydrogen and water can be prevented from being diffused to the transistor 200 side through the conductor 205 from the substrate side of the insulator 214.

Furthermore, the conductor 205b is preferably formed using a conductive material including tungsten, copper, or aluminum as its main component. Note that the conductor 205b is a single layer in the drawing but may have a stacked-layer structure, for example, a stacked layer of titanium, titanium nitride, and any of the above conductive materials.

The insulator 214 preferably functions as a barrier insulating film for preventing impurities such as water and hydrogen from entering the transistor from the substrate side. Accordingly, the insulator 214 is preferably formed using an insulating material having a function of suppressing diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material which does not easily transmit the above impurities). Alternatively, the insulator 214 is preferably formed using an insulating material having a function of suppressing diffusion of oxygen (e.g., at least one of oxygen atoms, oxygen molecules, and the like) (an insulating material which does not easily transmit the above oxygen).

For example, it is preferable that aluminum oxide, silicon nitride, or the like be used for the insulator 214. Thus, impurities such as hydrogen and water can be prevented from being diffused to the transistor side from the insulator 214. In addition, oxygen contained in the insulator 224 and the like can be prevented from being diffused to the substrate side of the insulator 214.

The relative permittivity of the insulator 216 and the insulator 280 functioning as interlayer films is preferably lower than that of the insulator 214. In the case where a material with a low relative permittivity is used as an interlayer film, the parasitic capacitance between wirings can be reduced.

For example, as the insulator 216 and the insulator 280 functioning as interlayer films, a single layer or a stacked layer of an insulator such as silicon oxide, silicon oxynitride, silicon nitride oxide, aluminum oxide, hafnium oxide, tantalum oxide, zirconium oxide, lead zirconate titanate (PZT), strontium titanate (SrTiO₃), or (Ba,Sr)TiO₃ (BST) can be used. Aluminum oxide, bismuth oxide, germanium oxide, niobium oxide, silicon oxide, titanium oxide, tungsten oxide, yttrium oxide, or zirconium oxide may be added to the insulator, for example. The insulator may be subjected to nitriding treatment. A layer of silicon oxide, silicon oxynitride, or silicon nitride may be stacked over the insulator.

The insulator 220, the insulator 222, and the insulator 224 have a function of a gate insulator.

Here, as the insulator 224 in contact with the oxide 230, an oxide insulator that contains more oxygen than that in the stoichiometric composition is preferably used. That is, an excess-oxygen region is preferably formed in the insulator 224. When such an insulator containing excess oxygen is provided in contact with the oxide 230, oxygen vacancies in the oxide 230 can be reduced, leading to an improvement in reliability.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 3.0×10²⁰ atoms/cm³ in TDS (Thermal Desorption Spectroscopy) analysis. In the TDS analysis, the film surface temperature is preferably higher than or equal to 100° C. and lower than or equal to 700° C., or higher than or equal to 100° C. and lower than or equal to 400° C.

In the case where the insulator 224 includes an excess-oxygen region, it is preferable that the insulator 222 have a function of suppressing diffusion of oxygen (e.g., at least one of oxygen atoms and oxygen molecules) (not easily transmit the above oxygen).

When the insulator 222 has a function of suppressing diffusion of oxygen, oxygen in the excess-oxygen region is not diffused to the insulator 220 side and thus can be supplied to the oxide 230 efficiently. The conductor 205 can be inhibited from reacting with oxygen in the excess-oxygen region of the insulator 224.

A single layer or a stacked layer of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) is preferably used as the insulator 222, for example. When a high-k material is used for the insulator functioning as a gate insulator, miniaturization and high integration of the transistor become possible. It is particularly preferable to use an insulating material such as aluminum oxide and hafnium oxide having a function of suppressing diffusion of impurities, oxygen, and the like (an insulating material which does not easily transmit the above oxygen). The insulator 222 formed of such a material serves as a layer that prevents release of oxygen from the oxide 230 and entry of impurities such as hydrogen from the periphery of the transistor 200.

Alternatively, aluminum oxide, bismuth oxide, germanium oxide, niobium oxide, silicon oxide, titanium oxide, tungsten oxide, yttrium oxide, or zirconium oxide may be added to these insulators, for example. These insulators may be subjected to nitriding treatment. A layer of silicon oxide, silicon oxynitride, or silicon nitride may be stacked over the insulator.

It is preferable that the insulator 220 be thermally stable. Because silicon oxide and silicon oxynitride have thermal stability, combination of silicon oxide or silicon oxynitride with an insulator which is a high-k material allows the stacked-layer structure to be thermally stable and have a high relative permittivity, for example.

Note that the insulator 220, the insulator 222, and the insulator 224 may each have a stacked-layer structure of two or more layers. In that case, the stacked-layer structure is not necessarily formed of the same material and may be formed of different materials. A structure in which the insulator 220, the insulator 222, and the insulator 224 function as a gate insulator in the transistor 200 has been described; however, this embodiment is not limited thereto. For example, a structure of two layers or one layer of any of the insulator 220, the insulator 222, and the insulator 224 may be formed as a gate insulator.

The oxide 230 includes the oxide 230a, the oxide 230b over the oxide 230a, and the oxide 230c over the oxide 230b. The oxide 230 includes the region 231, the junction region 232, and the region 234. Note that it is preferable that at least part of the region 231 be in contact with the insulator 274. Note that it is preferable that at least part of the region 231 have a higher concentration of at least one of hydrogen, nitrogen, and a metal element such as indium than the region 234.

When the transistor 200 is turned on, the region 231a or the region 231b functions as the source region or the drain region. At least part of the region 234 functions as a channel formation region.

Here, as illustrated in FIG. 11(A), the oxide 230 preferably includes the junction region 232. With this structure, the transistor 200 can have a high on-state current and a low leakage current in a non-conduction state (off-state current).

When the oxide 230b is provided over the oxide 230a, impurities can be prevented from being diffused into the oxide 230b from the components formed below the oxide 230a. Moreover, when the oxide 230b is provided under the oxide 230c, impurities can be prevented from being diffused into the oxide 230b from the components formed above the oxide 230c.

In the case where the oxide 230c is provided as illustrated in FIG. 1, the oxide 230c can be formed using a metal oxide which can be used for the oxide 230a or the oxide 230b.

Note that an oxide film to be the oxide 230c may be deposited under deposition conditions similar to those of an oxide film to be the oxide 230a or those of an oxide film to be the oxide 230b. Alternatively, these deposition conditions may be combined.

In this embodiment, the oxide film to be the oxide 230c is formed by a sputtering method using a target with In:Ga:Zn=4:2:4.1 [atomic ratio]. The oxide film may be deposited at a proportion of oxygen of 70% or higher, preferably 80% or higher, further preferably 100%.

Note that the above oxide film is preferably formed using appropriate deposition conditions and an appropriate atomic ratio to have required characteristics of the oxide 230.

Here, as illustrated in FIG. 1(B), the oxide 230c is preferably provided to cover the oxide 230a and the oxide 230b. That is, the oxide 230b is surrounded by the oxide 230a and the oxide 230c. With this structure, in the region 234, impurities can be prevented from entering the oxide 230b where a channel is formed.

In the case where the oxide 230a and the oxide 230c are provided, the energy of the conduction band minimum of the oxide 230a and the oxide 230c is preferably higher than the energy of the conduction band minimum in a region of the oxide 230b where the energy of the conduction band minimum is low. In other words, the electron affinity of the oxide 230a and the oxide 230c is preferably smaller than the electron affinity of the region of the oxide 230b where the energy of the conduction band minimum is low.

Here, the energy level of the conduction band minimum is gradually varied in the oxide 230a, the oxide 230b, and the oxide 230c. In other words, it continuously changes or is continuously connected. To obtain such a band diagram, the density of defect states in a mixed layer formed at an interface between the oxide 230a and the oxide 230b or an interface between the oxide 230b and the oxide 230c is preferably made low.

Specifically, when the oxide 230a and the oxide 230b or the oxide 230b and the oxide 230c contain the same element (as a main component) in addition to oxygen, a mixed layer with a low density of defect states can be formed. For example, when the oxide 230b is an In—Ga—Zn oxide, it is preferable to use an In—Ga—Zn oxide, a Ga—Zn oxide, gallium oxide, or the like as the oxide 230a and the oxide 230c.

At this time, a narrow-gap portion formed in the oxide 230b serves as a main carrier path. Since the density of defect states at the interface between the oxide 230a and the oxide 230b and the interface between the oxide 230b and the oxide 230c can be made low, the influence of interface scattering on carrier conduction is small, and a high on-state current can be obtained.

The oxide 230 has a curved surface between the side surface and the top surface of the oxide 230b. That is, an end portion of the side surface and an end portion of the top surface are preferably curved (hereinafter such a curved shape is also referred to as a rounded shape). The radius of curvature of the curved surface at an end portion of the oxide 230b is greater than or equal to 3 nm and less than or equal to 10 nm, preferably greater than or equal to 5 nm and less than or equal to 6 nm, for example.

The oxide 230 is preferably formed using a metal oxide functioning as an oxide semiconductor (hereinafter also referred to as an oxide semiconductor). For example, the metal oxide to be the region 234 preferably has an energy gap of 2 eV or more, preferably 2.5 eV or more. With the use of a metal oxide having such a wide energy gap, the off-state current of the transistor can be reduced.

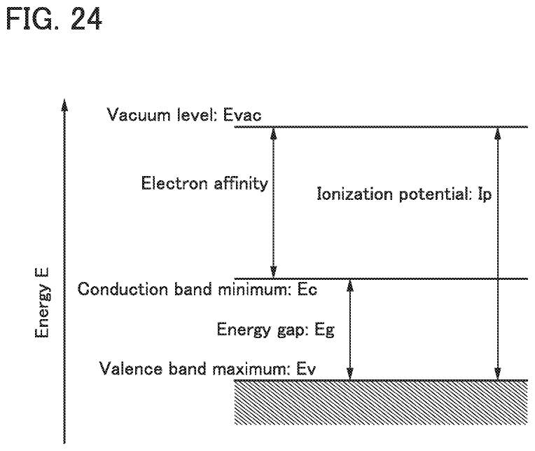

As shown in FIG. 24, the electron affinity or the energy level E_{c} of the conduction band minimum can be obtained from a band gap E_{g} and an ionization potential Iₚ, which is a difference between a vacuum level E_{vac} and an energy Eᵥ of the valence band maximum. The ionization potential Iₚ can be measured with, for example, an ultraviolet photoelectron spectroscopy (UPS) apparatus. The energy gap E_{g} can be measured with, for example, a spectroscopic ellipsometer.

Note that in this specification and the like, a metal oxide including nitrogen is also called a metal oxide in some cases. Moreover, a metal oxide including nitrogen may be called a metal oxynitride.

A transistor using an oxide semiconductor has an extremely low leakage current in a non-conduction state; thus, a semiconductor device with low power consumption can be provided. In addition, an oxide semiconductor can be deposited by a sputtering method or the like, and thus can be used for a transistor included in a highly integrated semiconductor device.

For example, as the oxide 230, a metal oxide such as an In-M-Zn oxide (the element M is one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like) may be used. An In—Ga oxide or an In—Zn oxide may be used as the oxide 230.

Here, the region 234 in the oxide 230 is described.

The region 234 preferably has a stacked-layer structure of oxides which differ in the atomic ratio of metal atoms. Specifically, in the case where the region 234 has the stacked-layer structure of the oxide 230a and the oxide 230b, the atomic ratio of the element M to constituent elements in the metal oxide used as the oxide 230a is preferably greater than that in the metal oxide used as the oxide 230b. Moreover, the atomic ratio of the element M to In in the metal oxide used as the oxide 230a is preferably greater than that in the metal oxide used as the oxide 230b. Moreover, the atomic ratio of In to the element M in the metal oxide used as the oxide 230b is preferably greater than that in the metal oxide used as the oxide 230a. As the oxide 230c, a metal oxide which can be used as the oxide 230a or the oxide 230b can be used.

Next, the region 231 and the junction region 232 in the oxide 230 are described.

The region 231 and the junction region 232 are low-resistance regions which are obtained by addition of a metal atom such as indium or impurities to a metal oxide provided as the oxide 230. Note that each of the regions has higher conductivity than at least the oxide 230b in the region 234. For addition of impurities to the region 231 and the junction region 232, for example, a dopant which is at least one of a metal element such as indium and impurities can be added by plasma treatment, an ion implantation method by which an ionized source gas is subjected to mass separation and then added, an ion doping method by which an ionized source gas is added without mass separation, a plasma immersion ion implantation method, or the like.

That is, when the metal atom (e.g., indium) content in the oxide 230 is increased in the region 231 and the junction region 232, the electron mobility can be increased and the resistance can be decreased.

When the insulator 274 containing elements serving as impurities is deposited in contact with the oxide 230, impurities can be added to the region 231 and the junction region 232.

That is, when an element that forms oxygen vacancies or an element trapped by oxygen vacancies is added to the region 231 and the junction region 232, the resistance of the region 231 and the junction region 232 is reduced. Typical examples of the element are hydrogen, boron, carbon, nitrogen, fluorine, phosphorus, sulfur, chlorine, titanium, and a rare gas. Typical examples of the rare gas element are helium, neon, argon, krypton, and xenon. Accordingly, the region 231 and the junction region 232 are made to include one or more of the above elements.

For example, as the insulator 274, a film which extracts and absorbs oxygen contained in the region 231 and the junction region 232 may be used. When oxygen is extracted, oxygen vacancies are generated in the region 231 and the junction region 232. Hydrogen, boron, carbon, nitrogen, fluorine, phosphorus, sulfur, chlorine, titanium, a rare gas, or the like is trapped by oxygen vacancies, whereby the resistance of the region 231 and the junction region 232 is reduced.

When the junction region 232 is provided in the transistor 200, a high-resistance region is not formed between the region 231 functioning as the source region and the drain region and the region 234 where a channel is formed, so that the on-state current and the mobility of the transistor can be increased. Moreover, when the junction region 232 is included, the gate does not overlap with the source region and the drain region in the channel length direction, so that formation of unnecessary capacitance can be suppressed. Furthermore, when the junction region 232 is included, the leakage current in a non-conduction state can be reduced.

Thus, by appropriately selecting the area of the junction region 232, a transistor having electrical characteristics which meet the requirements according to the circuit design can be easily provided.

The insulator 250 functions as a gate insulating film. The insulator 250 is preferably provided in contact with the top surface of the oxide 230c. The insulator 250 is preferably formed using an insulator from which oxygen is released by heating and is, for example, an oxide film of which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy analysis (TDS analysis). Note that the temperature of the film surface in the TDS analysis is preferably higher than or equal to 100° C. and lower than or equal to 700° C., or higher than or equal to 100° C. and lower than or equal to 500° C.

When as the insulator 250, an insulator from which oxygen is released by heating is provided in contact with the top surface of the oxide 230, oxygen can be effectively supplied to the region 234 of the oxide 230b. Furthermore, as in the insulator 224, the concentration of impurities such as water or hydrogen in the insulator 250 is preferably lowered. The thickness of the insulator 250 is preferably greater than or equal to 1 nm and less than or equal to 20 nm.

The conductor 260 functioning as the first gate electrode includes the conductor 260a and the conductor 260b over the conductor 260a. A conductive oxide is preferably used for the conductor 260a. For example, the metal oxide that can be used as the oxide 230a or the oxide 230b can be used. In particular, an In—Ga—Zn-based oxide with a metal atomic ratio of [In]:[Ga]:[Zn]=4:2:3 to 4.1 or in the neighborhood thereof, which has high conductivity, is preferably used. When such a conductor 260a is provided, transmission of oxygen to the conductor 260b can be inhibited, and an increase in electric resistance value of the conductor 260b due to oxidation can be prevented.

When the above-described conductive oxide is deposited by a sputtering method, oxygen can be added to the insulator 250, so that oxygen can be supplied to the oxide 230b. Thus, oxygen vacancies in the region 234 of the oxide 230 can be reduced.

As the conductor 260b, a conductor that can add impurities such as nitrogen to the conductor 260a to improve the conductivity of the conductor 260a may be used. For example, titanium nitride or the like is preferably used for the conductor 260b. Alternatively, the conductor 260b can have a stacked-layer structure of the above-described titanium nitride or the like and tungsten having high conductivity or the like, for example.

In the case where the conductor 205 extends to a region on an outer side of the end portion of the oxide 230 that intersects with the channel width direction as illustrated in FIG. 1(C), the conductor 260 preferably overlaps with the conductor 205 in the region with the insulator 250 placed therebetween. That is, a stacked-layer structure of the conductor 205, the insulator 250, and the conductor 260 is preferably formed outside the side surface of the oxide 230.

With the above structure, in the case where potentials are applied to the conductor 260 and the conductor 205, an electric field generated from the conductor 260 and an electric field generated from the conductor 205 are connected, so that a closed circuit which covers the channel formation region in the oxide 230 can be formed.

That is, the channel formation region in the region 234 can be electrically surrounded by the electric field of the conductor 260 functioning as the first gate electrode and the electric field of the conductor 205 functioning as the second gate electrode.

Furthermore, the insulator 270 functioning as a barrier film may be positioned over the conductor 260b. The insulator 270 is preferably formed using an insulating material having a function of suppressing transmission of oxygen and impurities such as water or hydrogen. For example, an insulator containing an oxide of one or both of aluminum and hafnium can be used. Aluminum oxide, hafnium oxide, an oxide containing aluminum and hafnium (hafnium aluminate), or the like is preferably used for the insulator containing an oxide of one or both of aluminum and hafnium. Thus, oxidation of the conductor 260 can be prevented. This can prevent mixture of impurities such as water or hydrogen into the oxide 230 through the conductor 260 and the insulator 250.

Furthermore, the insulator 271 functioning as a hard mask is preferably positioned over the insulator 270. By provision of the insulator 271, the conductor 260 can be processed to have a side surface that is substantially perpendicular. Specifically, an angle formed by the side surface of the conductor 260 and a surface of the substrate can be greater than or equal to 75° and less than or equal to 100°, preferably greater than or equal to 80° and less than or equal to 95°. When the conductor is processed into such a shape, the insulator 272 that is subsequently formed can be formed into a desired shape.

The insulator 272 functioning as a barrier film is provided in contact with the side surfaces of the insulator 250, the conductor 260, and the insulator 270.

Here, the insulator 272 is preferably formed using an insulating material that has a function of suppressing transmission of oxygen and impurities such as water or hydrogen. For example, an insulator containing an oxide of one or both of aluminum and hafnium can be used. Aluminum oxide, hafnium oxide, an oxide containing aluminum and hafnium (hafnium aluminate), or the like is preferably used for the insulator containing an oxide of one or both of aluminum and hafnium. In this manner, oxygen in the insulator 250 can be prevented from diffusing outward. In addition, impurities such as hydrogen and water can be prevented from entering the oxide 230 through the end portion of the insulator 250 or the like.

By provision of the insulator 272, the top surface and the side surface of the conductor 260 and the side surface of the insulator 250 can be covered with an insulator having a function of suppressing transmission of oxygen and impurities such as water or hydrogen. This can prevent entry of impurities such as water or hydrogen into the oxide 230 through the conductor 260 and the insulator 250. Thus, the insulator 272 functions as a side barrier that protects the side surfaces of the gate electrode and the gate insulating film.

In the case where the transistor is miniaturized and has a channel length of approximately greater than or equal to 10 nm and less than or equal to 30 nm, impurity elements contained in the structure bodies provided in the vicinity of the transistor 200 might be diffused, and the region 231a and the region 231b or the junction region 232a and the junction region 232b might be electrically connected to each other.

In view of the above, when the insulator 272 is formed as in this embodiment, impurities such as hydrogen or water can be prevented from entering the insulator 250 and the conductor 260, and oxygen in the insulator 250 can be prevented from being diffused to the outside. Accordingly, when the voltage applied to the first gate electrode is 0 V, the source region and the drain region can be prevented from being electrically connected to each other directly or through the junction region 232 or the like.

The insulator 274 includes at least a region in contact with the insulator 272, the oxide 230, and the insulator 224. In particular, the insulator 274 preferably includes a region in contact with the region 231 of the oxide 230.

Moreover, the insulator 274 is preferably formed using an insulating material having a function of suppressing transmission of oxygen. For example, as the insulator 274, silicon nitride, silicon nitride oxide, silicon oxynitride, aluminum nitride, aluminum nitride oxide, or the like is preferably used. Such an insulator 274 can prevent oxygen from passing through the insulator 274 and being supplied to oxygen vacancies in the region 231a and the region 231b, so that a reduction in carrier density can be prevented.

Note that in the case where the region 231 and the junction region 232 are provided by deposition of the insulator 274, the insulator 274 preferably includes at least one of hydrogen and nitrogen. When an insulator including impurities such as hydrogen or nitrogen is used as the insulator 274, impurities such as hydrogen or nitrogen are added to the oxide 230, so that the region 231 and the junction region 232 can be formed in the oxide 230.

The insulator 275 is preferably provided over the insulator 274. The insulator 275 is preferably formed using an insulating material having a function of suppressing transmission of impurities such as water or hydrogen and oxygen. As the insulator 275, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example. Such an insulator 275 can prevent oxygen from passing through the insulator 274 and being supplied to oxygen vacancies in the region 231a and the region 231b, so that a reduction in carrier density can be prevented. Furthermore, impurities such as water or hydrogen can be prevented from passing through the insulator 274 and excessively enlarging the region 231a and the region 231b to the region 234 side.

The insulator 280 functioning as the interlayer film is preferably provided over the insulator 275. As in the insulator 224 or the like, the concentration of impurities such as water or hydrogen in the film of the insulator 280 is preferably lowered. The insulator 280 preferably contains excess oxygen. Note that the insulator 280 may have a stacked-layer structure consisting of similar insulators.

The insulator 282 is provided over the insulator 280. An insulating material having a function of suppressing transmission of impurities such as water or hydrogen and oxygen is preferably used for the insulator 282. As the insulator 282, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example. For example, oxygen can be introduced into the insulator 280 by performing deposition by a sputtering method using oxygen. The introduced oxygen serves as excess oxygen in the insulator 280.

The structure of the transistor 200 which is one embodiment of the present invention includes a region where the insulator 280 containing excess oxygen and the insulator 224 are in contact with each other. In other words, the insulator 280 is in contact with the exposed region of the top surface of the insulator 224. Such a structure enables excess oxygen 288 in the insulator 280 to pass through the insulator 224 and diffuse into the oxide 230, so that defects in the oxide 230 can be efficiently repaired. That is, the defects can be repaired and the carrier density can be reduced more easily in the vicinity of the channel formation region (the region 234). In the region 231a and the region 231b, the insulator 274 and the oxide 230 are in contact with each other; thus, a high carrier density state can be kept.

FIG. 11(B) is a drawing showing an extracted part of FIG. 1(B). FIG. 11(B) is a cross-sectional view omitting the insulator 222 and the like in FIG. 1(B). In FIG. 11(B), a dashed line denotes a movement path of the excess oxygen 288. The excess oxygen 288 is diffused to the oxide 230 through the insulator 224.

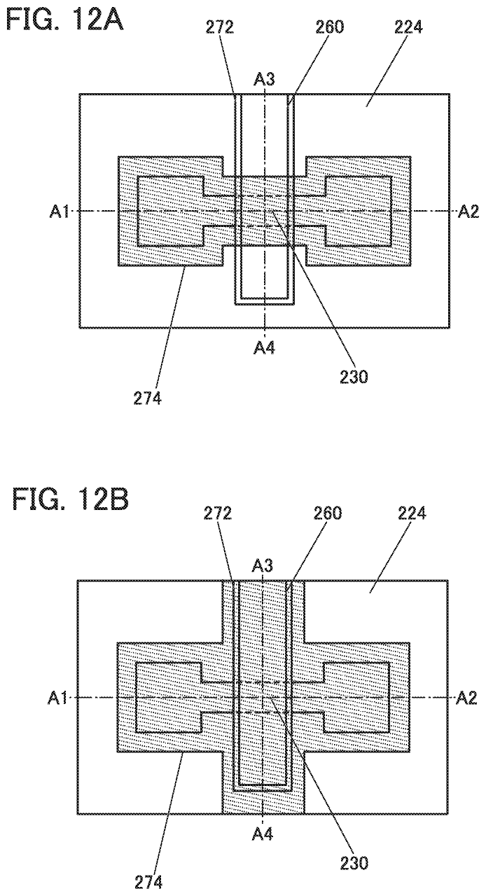

FIGS. 12 to 14 illustrate examples of the shape of the insulator 274 seen from the above. Although FIGS. 12 to 14 are top views of the semiconductor device including the transistor which is one embodiment of the present invention, some components are not illustrated for clarity. The insulator 274 is hatched in FIGS. 12 to 14.

FIG. 12(A) illustrates the shape of the insulator 274 of the transistor 200 seen from the above, where the insulator 274 covers the oxide 230 and part of the conductor 260.

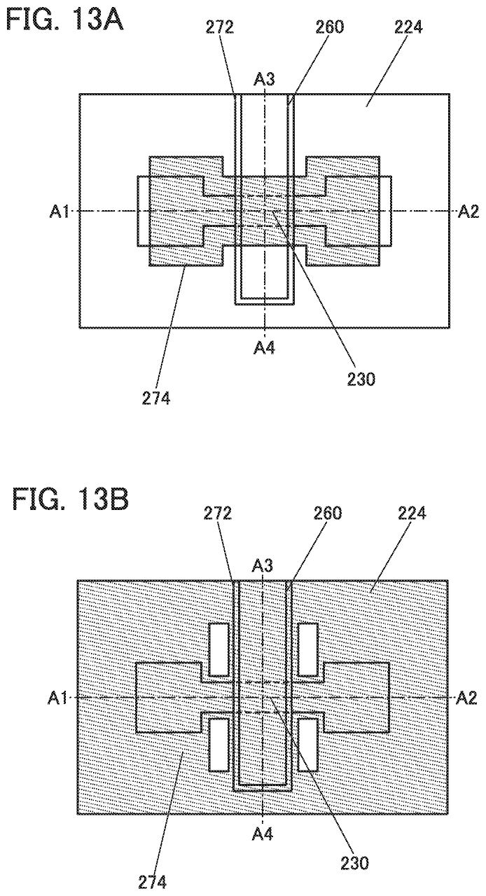

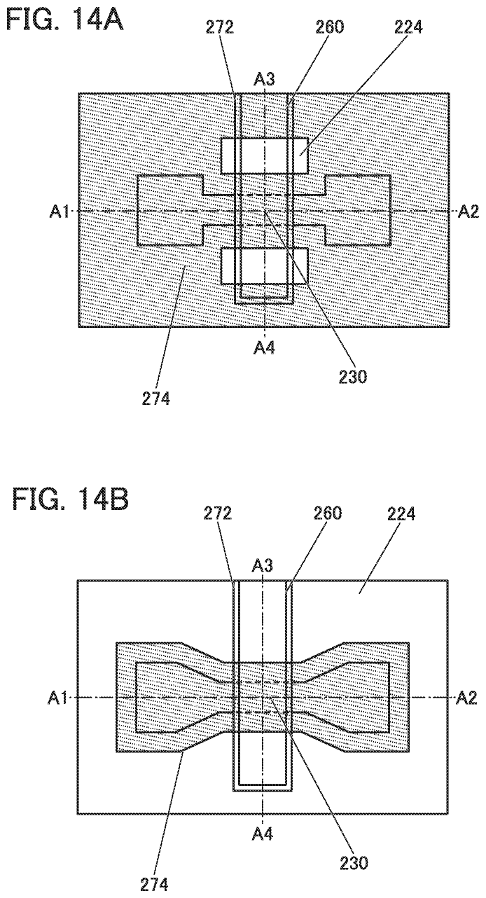

FIG. 12(B) illustrates an example of a shape in which the insulator 274 covers the oxide 230 and the conductor 260. FIG. 13(A) illustrates an example of a shape in which the insulator 274 covers part of the oxide 230 and part of the conductor 260. FIG. 13(B) illustrates an example of a shape in which the insulator 274 covers the oxide 230 and the conductor 260 and partly has openings. The openings include a region where the top surface of the insulator 224 is exposed. FIG. 14(A) illustrates an example of a shape in which the insulator 274 covers the oxide 230 and part of the conductor 260 and partly has openings. The openings include a region where the top surface of the insulator 224 is exposed. FIG. 14(B) illustrates an example in which the insulator 274 covers the oxide 230 and the conductor 260 and the shape of the oxide 230 is different from that of the other examples.

The shapes of the insulator 274 illustrated in FIGS. 12 to 14 are only examples and the shape is not limited thereto. That is, the shape of the insulator 274 seen from the above is a shape in which at least part of the oxide 230 is covered and a region where the top surface of the insulator 224 is exposed is included.

By forming the semiconductor device including the transistor 200 with the above-described structure, the source region and the drain region of the transistor 200 can keep holding high carrier density and a channel formation region can keep holding low carrier density, whereby the semiconductor device can include the transistor with high performance and high reliability.

### Structure Example 2 of Semiconductor Device

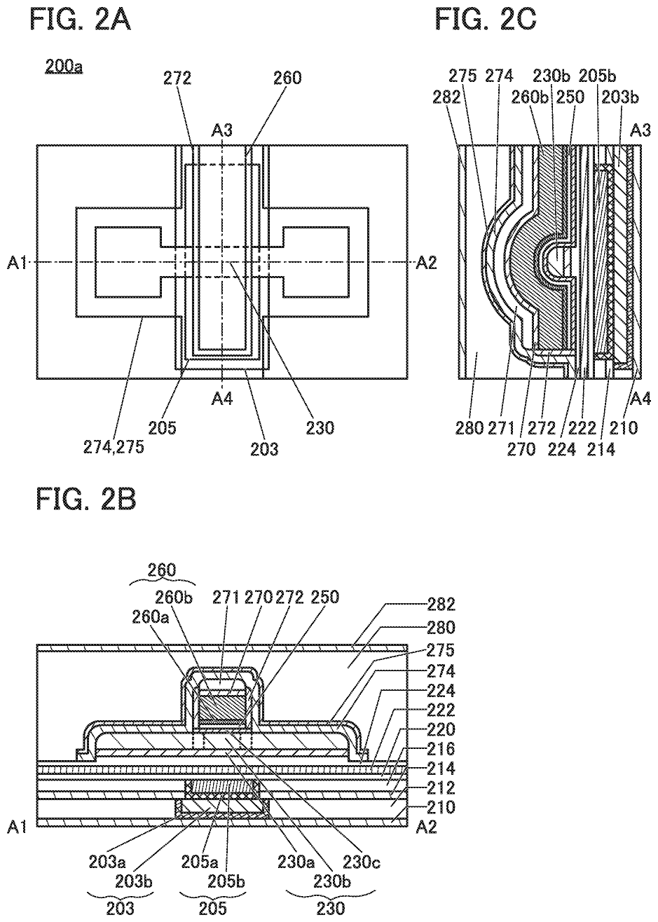

FIG. 2(A), FIG. 2(B), and FIG. 2(C) are a top view and cross-sectional views of a transistor 200a of one embodiment of the present invention and a periphery of the transistor 200a.

FIG. 2(A) is a top view of a semiconductor device including the transistor 200a. FIG. 2(B) and FIG. 2(C) are cross-sectional views of the semiconductor device. Here, FIG. 2(B) is a cross-sectional view of a portion indicated by a dashed-dotted line A1-A2 in FIG. 2(A), and is a cross-sectional view in the channel length direction of the transistor 200a. FIG. 2(C) is a cross-sectional view of a portion indicated by a dashed-dotted line A3-A4 in FIG. 2(A), and is a cross-sectional view in the channel width direction of the transistor 200a. For clarity of the drawing, some components are not illustrated in the top view of FIG. 2(A).

[Transistor 200a]

The transistor 200a is different from the transistor 200 in having a shape in which the insulator 274 covers the oxide 230 and the conductor 260 when seen from the above, as illustrated in FIG. 2(A). That is, the shape of the insulator 274 when seen from the above is as illustrated in FIG. 12(B). The semiconductor device including the transistor 200 illustrated in FIG. 1 can be referred to for the other structures and the effect.

### Structure Example 3 of Semiconductor Device

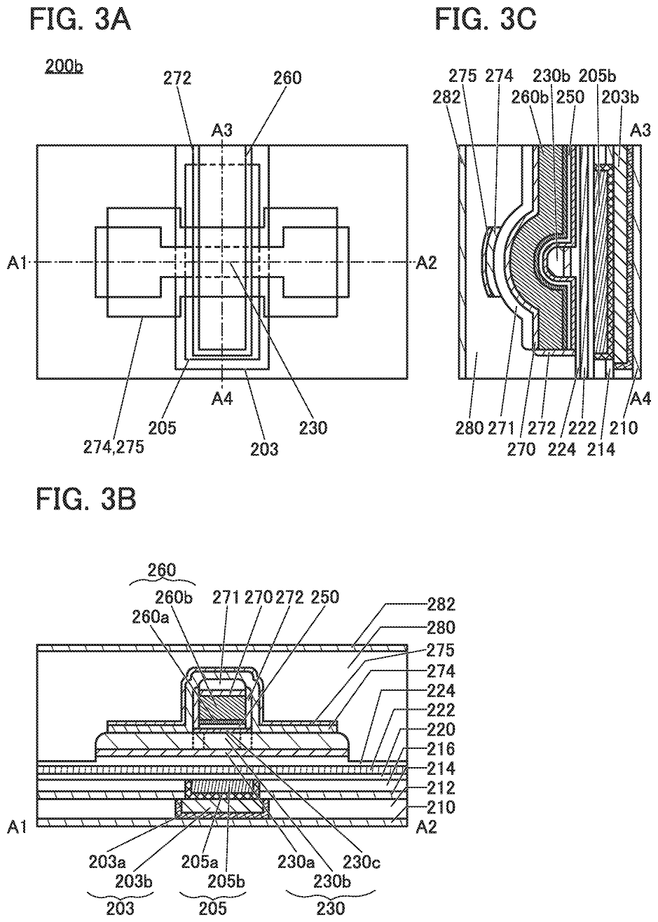

FIG. 3(A), FIG. 3(B), and FIG. 3(C) are a top view and cross-sectional views of a transistor 200b of one embodiment of the present invention and a periphery of the transistor 200b.

FIG. 3(A) is a top view of a semiconductor device including the transistor 200b. FIG. 3(B) and FIG. 3(C) are cross-sectional views of the semiconductor device. Here, FIG. 3(B) is a cross-sectional view of a portion indicated by a dashed-dotted line A1-A2 in FIG. 3(A), and is a cross-sectional view in the channel length direction of the transistor 200b. FIG. 3(C) is a cross-sectional view of a portion indicated by a dashed-dotted line A3-A4 in FIG. 3(A), and is a cross-sectional view in the channel width direction of the transistor 200b. For clarity of the drawing, some components are not illustrated in the top view of FIG. 3(A).

[Transistor 200b]

The transistor 200b is different from the transistor 200 in having a shape in which the insulator 274 covers part of the oxide 230 and part of the conductor 260 when seen from the above, as illustrated in FIG. 3(A). That is, the shape of the insulator 274 when seen from the above is as illustrated in FIG. 13(A).

In FIG. 3(B), the end portions of the insulator 274 and the insulator 275 are positioned over the oxide 230 and on the inner side than the end portion of the oxide 230; however, they may be substantially aligned with the end portion of the oxide 230. Processing the vicinity of the end portion of the oxide 230 at the time of forming the insulator 274 and the insulator 275 can make the end portions of the insulator 274 and the insulator 275 be substantially aligned with the end portion of the oxide 230. The semiconductor device including the transistor 200 illustrated in FIG. 1 can be referred to for the other structures and the effect.

### Structure Example 4 of Semiconductor Device

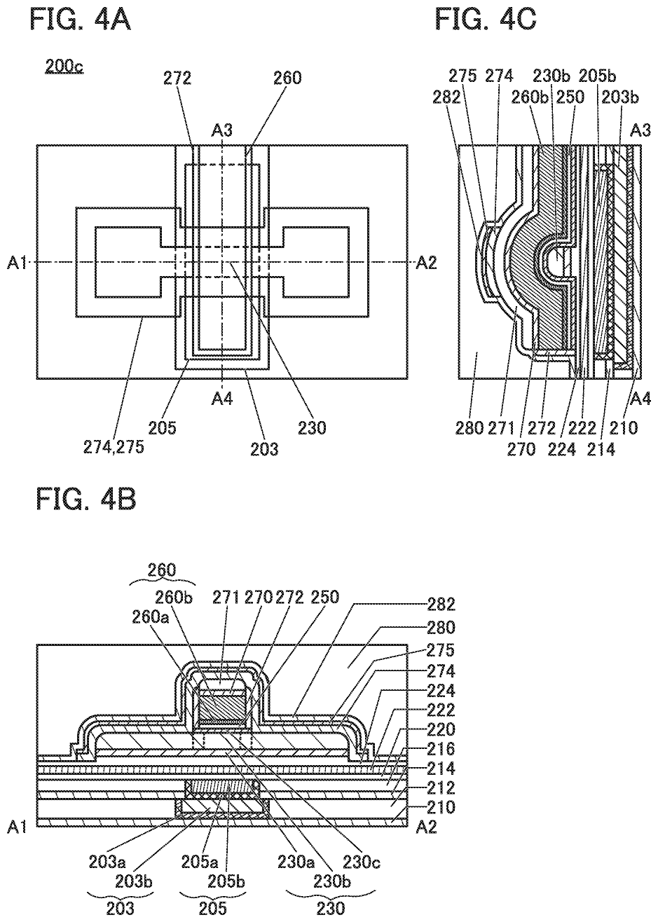

FIG. 4(A), FIG. 4(B), and FIG. 4(C) are a top view and cross-sectional views of a transistor 200c of one embodiment of the present invention and a periphery of the transistor 200c.

FIG. 4(A) is a top view of a semiconductor device including the transistor 200c. FIG. 4(B) and FIG. 4(C) are cross-sectional views of the semiconductor device. Here, FIG. 4(B) is a cross-sectional view of a portion indicated by a dashed-dotted line A1-A2 in FIG. 4(A), and is a cross-sectional view in the channel length direction of the transistor 200c. FIG. 4(C) is a cross-sectional view of a portion indicated by a dashed-dotted line A3-A4 in FIG. 4(A), and is a cross-sectional view in the channel width direction of the transistor 200c. For clarity of the drawing, some components are not illustrated in the top view of FIG. 4(A).

[Transistor 200c]

The transistor 200c is different from the transistor 200 in that the insulator 282 is provided over the insulator 275 and the insulator 280 is provided over the insulator 282 as illustrated in FIG. 4. Since a region where the insulator 282 and the insulator 224 are in contact with each other is included, oxygen can be supplied to the insulator 224 at the time of depositing the insulator 282.

An insulating material having a function of suppressing transmission of impurities such as water or hydrogen and oxygen is preferably used for the insulator 282. For the insulator 282, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example. For example, oxygen can be introduced into the insulator 224 by deposition using oxygen by a sputtering method. The introduced oxygen becomes excess oxygen in the insulator 224 and is diffused into the oxide 230, so that defects in the oxide 230 can be efficiently recovered. That is, the defects can be repaired and the carrier density can be reduced more easily in the vicinity of the channel formation region (the region 234). In the region 231a and the region 231b, the insulator 274 and the oxide 230 are in contact with each other; thus, a high carrier density state can be kept.

One of the examples illustrated in FIGS. 12 to 14 can be applied to the shape of the insulator 274 seen from the above; however, the shape is not limited thereto. That is, the shape of the insulator 274 seen from the above is a shape in which the insulator 274 covers at least part of the oxide 230 and includes a region where the top surface of the insulator 224 is exposed. The semiconductor device including the transistor 200 illustrated in FIG. 1 can be referred to for the other structures and the effect.

### Structure Example 5 of Semiconductor Device

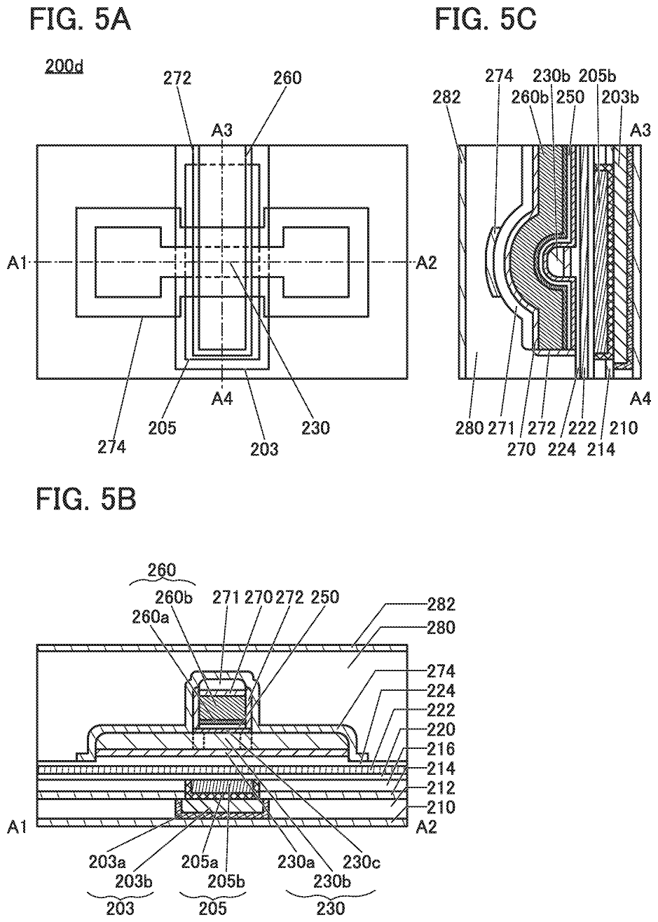

FIG. 5(A), FIG. 5(B), and FIG. 5(C) are a top view and cross-sectional views of a transistor 200d of one embodiment of the present invention and a periphery of the transistor 200d.

FIG. 5(A) is a top view of a semiconductor device including the transistor 200d. FIG. 5(B) and FIG. 5(C) are cross-sectional views of the semiconductor device. Here, FIG. 5(B) is a cross-sectional view of a portion indicated by a dashed-dotted line A1-A2 in FIG. 5(A), and is a cross-sectional view in the channel length direction of the transistor 200d. FIG. 5(C) is a cross-sectional view of a portion indicated by a dashed-dotted line A3-A4 in FIG. 5(A), and is a cross-sectional view in the channel width direction of the transistor 200d. For clarity of the drawing, some components are not illustrated in the top view of FIG. 5(A).

[Transistor 200d]

The transistor 200d is different from the transistor 200 in having a structure that does not include the insulator 275 as illustrated in FIG. 5. When an insulating material having a function of suppressing transmission of oxygen is used for the insulator 274, the insulator 275 need not necessarily be provided over the insulator 274, in some cases. That is, although transmission of excess oxygen contained in the insulator 280 through the insulator 274 is suppressed, the excess oxygen contained in the insulator 280 passes through the insulator 224 in the region where the insulator 280 and the insulator 224 are in contact with each other to diffuse into the oxide 230, so that defects in the oxide 230 can be efficiently recovered. That is, the defects can be repaired and the carrier density can be reduced more easily in the vicinity of the channel formation region (the region 234). In the region 231a and the region 231b, the insulator 274 and the oxide 230 are in contact with each other; thus, a high carrier density state can be kept. This structure is preferable because the number of manufacturing steps of the semiconductor device can be reduced. The semiconductor device including the transistor 200 illustrated in FIG. 1 can be referred to for the other structures and the effect.

### Structure Example 6 of Semiconductor Device

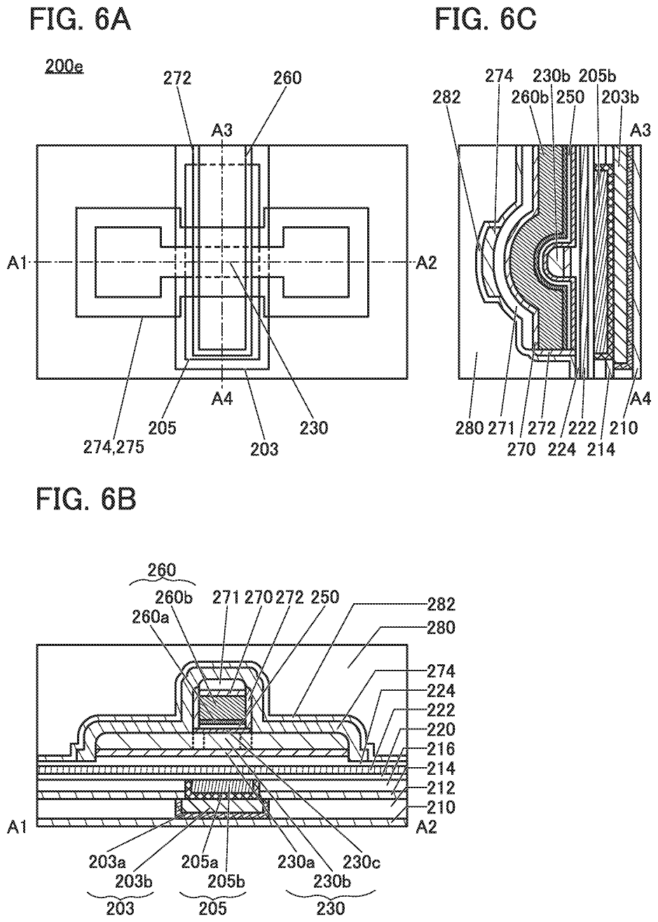

FIG. 6(A), FIG. 6(B), and FIG. 6(C) are a top view and cross-sectional views of a transistor 200e of one embodiment of the present invention and a periphery of the transistor 200e.

FIG. 6(A) is a top view of a semiconductor device including the transistor 200e. FIG. 6(B) and FIG. 6(C) are cross-sectional views of the semiconductor device. Here, FIG. 6(B) is a cross-sectional view of a portion indicated by a dashed-dotted line A1-A2 in FIG. 6(A), and is a cross-sectional view in the channel length direction of the transistor 200e. FIG. 6(C) is a cross-sectional view of a portion indicated by a dashed-dotted line A3-A4 in FIG. 6(A), and is a cross-sectional view in the channel width direction of the transistor 200e. For clarity of the drawing, some components are not illustrated in the top view of FIG. 6(A).

[Transistor 200e]

The transistor 200e is different from the transistor 200 in that the insulator 275 is not included, the insulator 282 is provided over the insulator 274, and the insulator 280 is provided over the insulator 282 as illustrated in FIG. 6. When an insulating material having a function of suppressing transmission of oxygen is used for the insulator 274, the insulator 275 need not necessarily be provided over the insulator 274, in some cases.

Furthermore, the insulator 282 is preferably formed using an insulating material having a function of suppressing transmission of impurities such as water or hydrogen and oxygen. For the insulator 282, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example. For example, oxygen can be introduced into the insulator 224 by deposition using oxygen by a sputtering method. The introduced oxygen becomes excess oxygen in the insulator 224 and is diffused into the oxide 230, so that defects in the oxide 230 can be efficiently recovered. That is, the defects can be repaired and the carrier density can be reduced more easily in the vicinity of the channel formation region (the region 234). In the region 231a and the region 231b, the insulator 274 and the oxide 230 are in contact with each other; thus, a high carrier density state can be kept. The semiconductor device including the transistor 200 illustrated in FIG. 1 can be referred to for the other structures and the effect.

### Structure Example 7 of Semiconductor Device

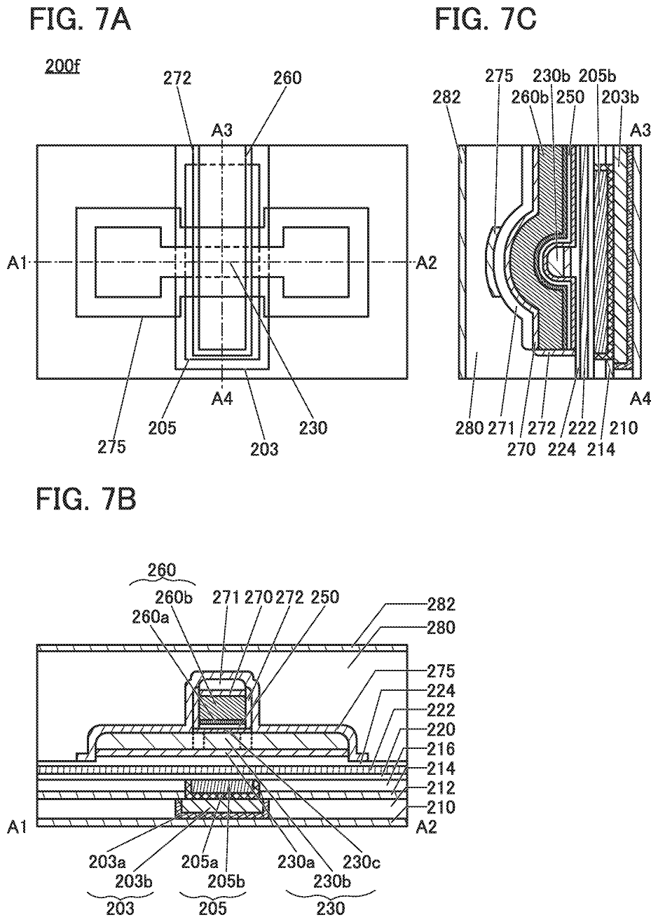

FIG. 7(A), FIG. 7(B), and FIG. 7(C) are a top view and cross-sectional views of a transistor 200f of one embodiment of the present invention and a periphery of the transistor 200f

FIG. 7(A) is a top view of a semiconductor device including the transistor 200f FIG. 7(B) and FIG. 7(C) are cross-sectional views of the semiconductor device. Here, FIG. 7(B) is a cross-sectional view of a portion indicated by a dashed-dotted line A1-A2 in FIG. 7(A), and is a cross-sectional view in the channel length direction of the transistor 200f FIG. 7(C) is a cross-sectional view of a portion indicated by a dashed-dotted line A3-A4 in FIG. 7(A), and is a cross-sectional view in the channel width direction of the transistor 200f For clarity of the drawing, some components are not illustrated in the top view of FIG. 7(A).

[Transistor 200f]

The transistor 200f is different from the transistor 200 in having a structure that does not include the insulator 274 as illustrated in FIG. 7.

In the manufacturing process of the semiconductor device including the transistor 200f, the insulator 250, the conductor 260, the insulator 270, the insulator 271, and the insulator 272 are formed over the oxide 230; an insulator that is a material similar to the insulator 274 is deposited over the oxide 230, the insulator 250, the conductor 260, the insulator 270, the insulator 271, and the insulator 272 to form the region 234, the region 231a, and the region 231b in the oxide 230; and then the insulator is removed to form the insulator 275 over the oxide 230, the insulator 250, the conductor 260, the insulator 270, the insulator 271, and the insulator 272.

Furthermore, the insulator 282 is preferably formed using an insulating material having a function of suppressing transmission of impurities such as water or hydrogen and oxygen. For the insulator 282, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example. For example, oxygen can be introduced into the insulator 280 by deposition using oxygen by a sputtering method. The introduced oxygen becomes excess oxygen in the insulator 280, and the excess oxygen in the insulator 280 passes through the insulator 224 and is diffused into the oxide 230, so that defects in the oxide 230 can be efficiently recovered. That is, the defects can be repaired and the carrier density can be reduced more easily in the vicinity of the channel formation region (the region 234). In the region 231a and the region 231b, the insulator 274 and the oxide 230 are in contact with each other; thus, a high carrier density state can be kept. The insulator 224 is diffused into the oxide 230, so that defects in the oxide 230 can be efficiently recovered. That is, the defects can be repaired and the carrier density can be reduced more easily in the vicinity of the channel formation region (the region 234). When an insulating material having a function of suppressing transmission of oxygen is used for the insulator 275, excess oxygen in the insulator 280 can be prevented from entering the region 231a and the region 231b, so that a high carrier density state can be kept. The semiconductor device including the transistor 200 illustrated in FIG. 1 can be referred to for the other structures and the effect.

### Structure Example 8 of Semiconductor Device

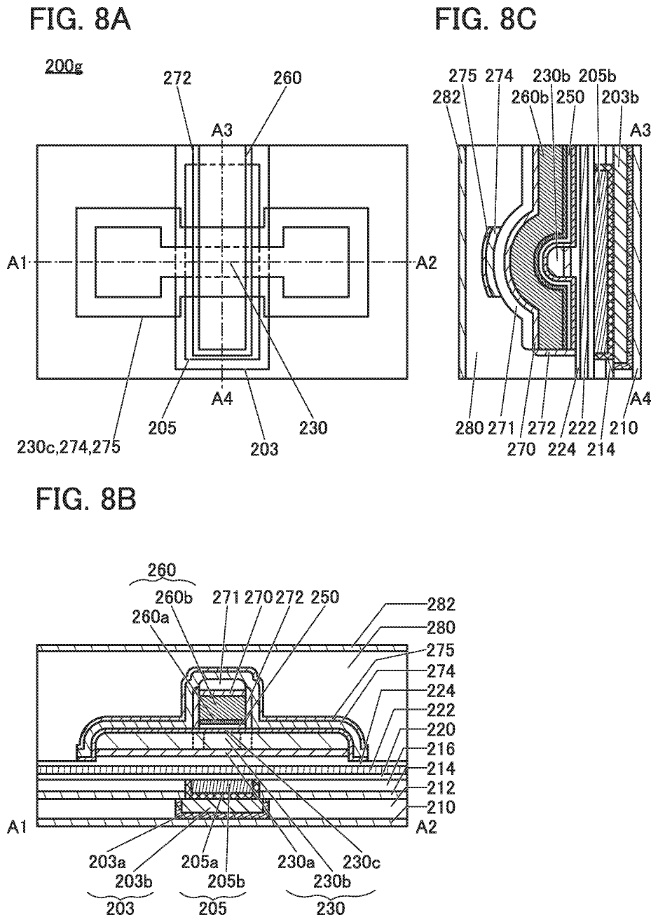

FIG. 8(A), FIG. 8(B), and FIG. 8(C) are a top view and cross-sectional views of a transistor 200g of one embodiment of the present invention and a periphery of the transistor 200g.

FIG. 8(A) is a top view of a semiconductor device including the transistor 200g. FIG. 8(B) and FIG. 8(C) are cross-sectional views of the semiconductor device. Here, FIG. 8(B) is a cross-sectional view of a portion indicated by a dashed-dotted line A1-A2 in FIG. 8(A), and is a cross-sectional view in the channel length direction of the transistor 200g. FIG. 8(C) is a cross-sectional view of a portion indicated by a dashed-dotted line A3-A4 in FIG. 8(A), and is a cross-sectional view in the channel width direction of the transistor 200g. For clarity of the drawing, some components are not illustrated in the top view of FIG. 8(A).

[Transistor 200g]

As illustrated in FIG. 8, the transistor 200g is different from the transistor 200 illustrated in FIG. 1 in the shape of the oxide 230c. In other words, as illustrated in FIG. 8(B), in a cross section in the L length direction of the transistor 200g, the structure of an end portion of the oxide 230c is substantially the same as those of the end portion of the insulator 274 and the end portion of the insulator 275. The oxide 230c, the insulator 274, and the insulator 275 can be formed by one-time photolithography step, which is preferable because the number of manufacturing steps of the semiconductor device can be reduced. The semiconductor device including the transistor 200 illustrated in FIG. 1 can be referred to for the other structures and the effect.

### Structure Example 9 of Semiconductor Device

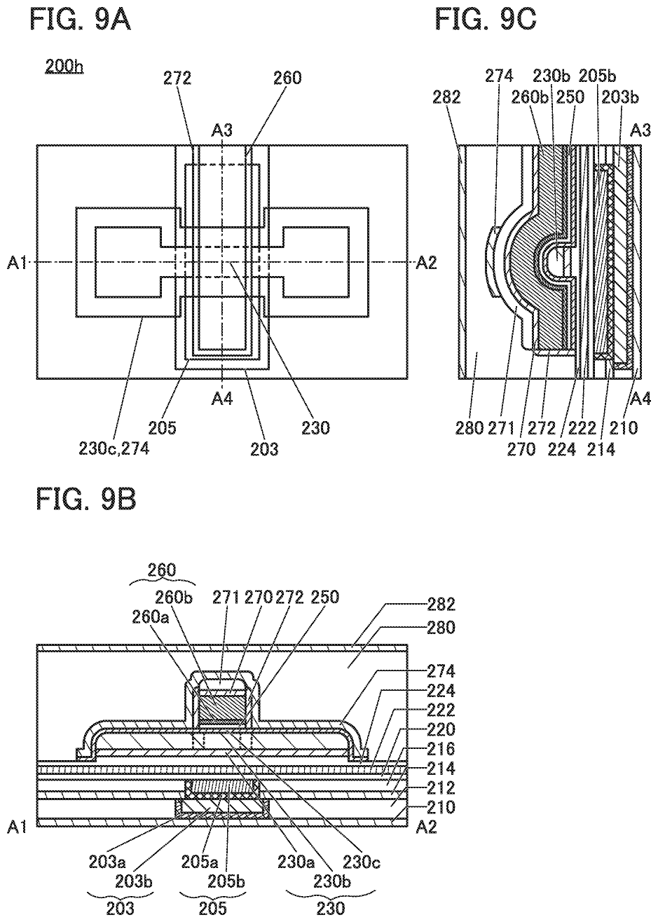

FIG. 9(A), FIG. 9(B), and FIG. 9(C) are a top view and cross-sectional views of a transistor 200h of one embodiment of the present invention and a periphery of the transistor 200h.

FIG. 9(A) is a top view of a semiconductor device including the transistor 200h. FIG. 9(B) and FIG. 9(C) are cross-sectional views of the semiconductor device. Here, FIG. 9(B) is a cross-sectional view of a portion indicated by a dashed-dotted line A1-A2 in FIG. 9(A), and is a cross-sectional view in the channel length direction of the transistor 200h. FIG. 9(C) is a cross-sectional view of a portion indicated by a dashed-dotted line A3-A4 in FIG. 9(A), and is a cross-sectional view in the channel width direction of the transistor 200h. For clarity of the drawing, some components are not illustrated in the top view of FIG. 9(A).

[Transistor 200h]

As illustrated in FIG. 9, the transistor 200h is different from the transistor 200 illustrated in FIG. 1 in having a structure that does not include the insulator 275 and in the shape of the oxide 230c. In other words, as illustrated in FIG. 9(B), the structure of the end portion of the oxide 230c is substantially the same as that of the end portion of the insulator 274 in the cross section in the L length direction of the transistor 200h. The formation of the insulator 275 is omitted and the oxide 230c and the insulator 274 can be formed by one-time photolithography step. Thus, the number of manufacturing steps of the semiconductor device can be reduced, which is preferable. The semiconductor device including the transistor 200 illustrated in FIG. 1 and the semiconductor device including the transistor 200d illustrated in FIG. 5 can be referred to for the other structures and the effect.

### Structure Example 10 of Semiconductor Device

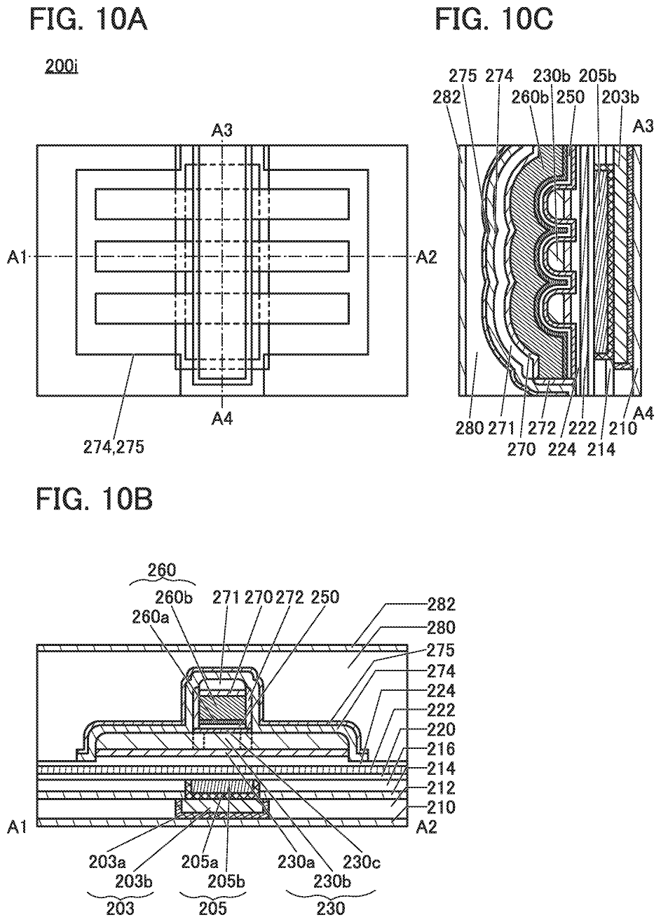

FIG. 10(A), FIG. 10(B), and FIG. 10(C) are a top view and cross-sectional views of a transistor 200i of one embodiment of the present invention and a periphery of the transistor 200i.

FIG. 10(A) is a top view of a semiconductor device including the transistor 200i. FIG. 10(B) is a cross-sectional view of a portion indicated by a dashed-dotted line A1-A2 in FIG. 10(A), and is a cross-sectional view in the channel length direction of the transistor 200i. FIG. 10(C) is a cross-sectional view of a portion indicated by a dashed-dotted line A3-A4 in FIG. 10(A), and is a cross-sectional view in the channel width direction of the transistor 200i. For clarity of the drawing, some components are not illustrated in the top view of FIG. 10(A).

[Transistor 200i]

As illustrated in FIG. 10, the transistor 200i is different from the transistor 200 illustrated in FIGS. 1(A), 1(B), and 1(C) in including a plurality of channel formation regions with respect to one gate electrode. By including the plurality of channel formation regions, the transistor 200i can have a high on-state current. Furthermore, each channel formation region is surrounded by the gate electrode; in other words, an s-channel structure is employed. Thus, a high on-state current can be obtained in each channel formation region. Note that although FIG. 10 illustrates an example including three channel formation regions, the number of channel formation regions is not limited thereto. The structure of the transistor 200 illustrated in FIGS. 1(A), 1(B), and 1(C) can be referred to for the other structures and the effect.

### Structure Example 11 of Semiconductor Device

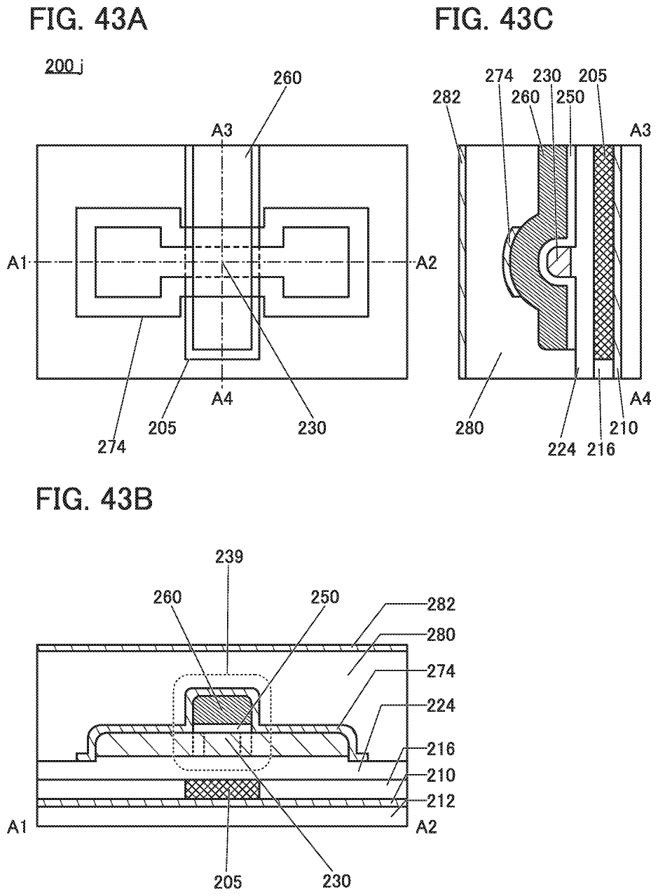

FIG. 43(A), FIG. 43(B), and FIG. 43(C) are a top view and cross-sectional views of a transistor 200j of one embodiment of the present invention and a periphery of the transistor 200j.

FIG. 43(A) is a top view of a semiconductor device including the transistor 200j. FIG. 43(B) and FIG. 43(C) are cross-sectional views of the semiconductor device. Here, FIG. 43(B) is a cross-sectional view of a portion indicated by a dashed-dotted line A1-A2 in FIG. 43(A), and is a cross-sectional view in the channel length direction of the transistor 200j. FIG. 43(C) is a cross-sectional view of a portion indicated by a dashed-dotted line A3-A4 in FIG. 43(A), and is a cross-sectional view in the channel width direction of the transistor 200j. For clarity of the drawing, some components are not illustrated in the top view of FIG. 43(A).

The semiconductor device of one embodiment of the present invention includes the transistor 200j and the insulator 212, the insulator 280, and the insulator 282 that function as interlayer films.

[Transistor 200j]

As illustrated in FIG. 43, the transistor 200j includes the insulator 216 provided over a substrate (not shown), the conductor 205 provided so as to be embedded in the insulator 216, the insulator 224 provided over the insulator 216 and the conductor 205, the oxide 230 provided over the insulator 224, the insulator 250 provided over the oxide 230, the conductor 260 provided over the insulator 250, and the insulator 274 provided in contact with the oxide 230, the side surface of the insulator 250, the side surface of the conductor 260, and the top surface of the conductor 260. The transistor 200j includes a region where the insulator 280 and the insulator 224 are in contact with each other. The above-described structure of the transistor 200 illustrated in FIGS. 1(A), 1(B), and 1(C) can be referred to for the other structures and the effect.

### Structure Example 12 of Semiconductor Device

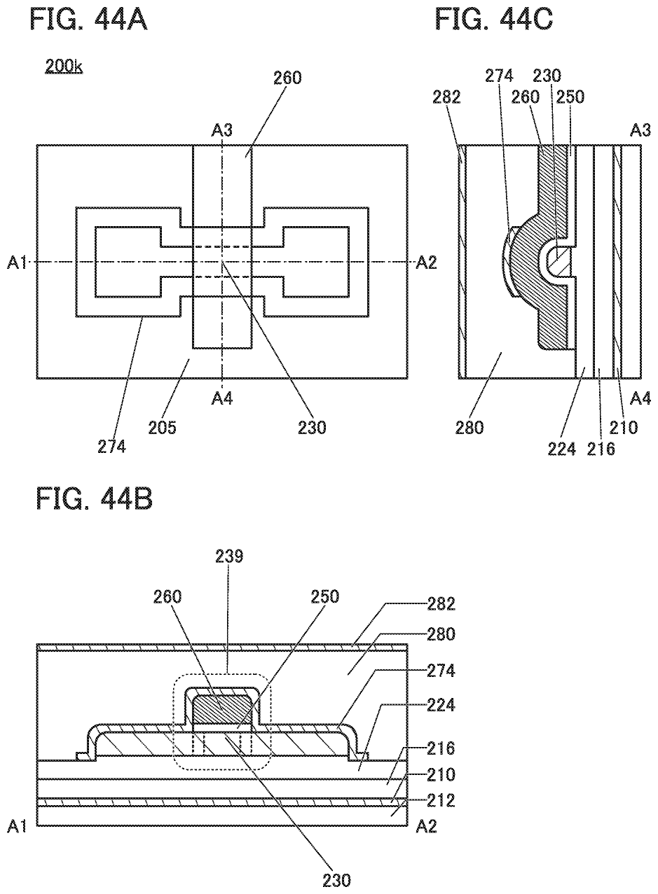

FIG. 44(A), FIG. 44(B), and FIG. 44(C) are a top view and cross-sectional views of a transistor 200k of one embodiment of the present invention and a periphery of the transistor 200k.

FIG. 44(A) is a top view of a semiconductor device including the transistor 200k. FIG. 44(B) and FIG. 44(C) are cross-sectional views of the semiconductor device. Here, FIG. 44(B) is a cross-sectional view of a portion indicated by a dashed-dotted line A1-A2 in FIG. 44(A), and is a cross-sectional view in the channel length direction of the transistor 200k. FIG. 44(C) is a cross-sectional view of a portion indicated by a dashed-dotted line A3-A4 in FIG. 44(A), and is a cross-sectional view in the channel width direction of the transistor 200k. For clarity of the drawing, some components are not illustrated in the top view of FIG. 44(A).

The semiconductor device of one embodiment of the present invention includes the transistor 200k and the insulator 212, the insulator 280, and the insulator 282 that function as interlayer films.

[Transistor 200k]

As illustrated in FIG. 44, the transistor 200k includes the insulator 216 provided over a substrate (not shown), the insulator 224 provided over the insulator 216, the oxide 230 provided over the insulator 224, the insulator 250 provided over the oxide 230, the conductor 260 provided over the insulator 250, and the insulator 274 provided in contact with the oxide 230, the side surface of the insulator 250, the side surface of the conductor 260, and the top surface of the conductor 260. The transistor 200k includes a region where the insulator 280 and the insulator 224 are in contact with each other. That is, the transistor 200k is different from the transistor 200j illustrated in FIGS. 43(A), 43(B), and 43(C) in not including the conductor 205. The structure of the transistor 200j can be referred to for the other structures and the effect.

### Structure Example 13 of Semiconductor Device

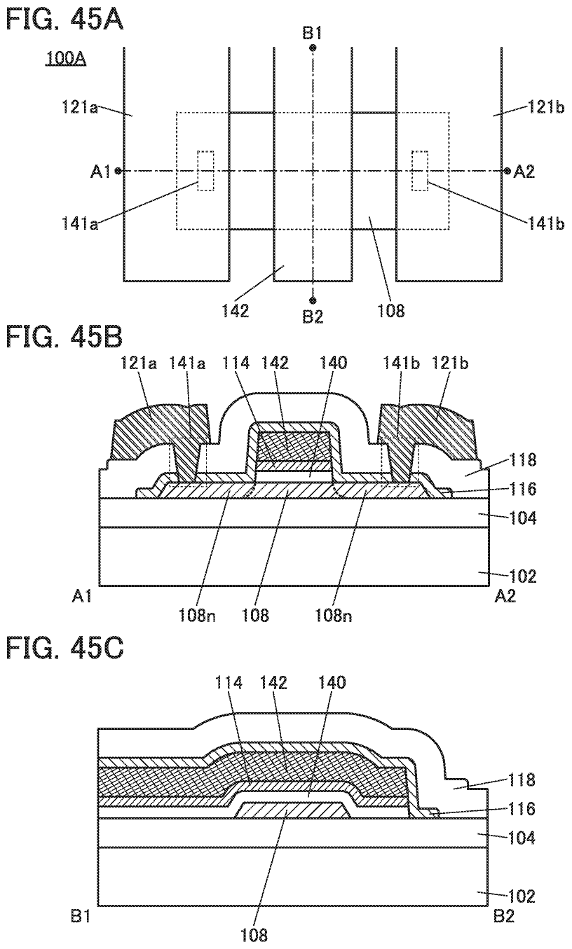

FIG. 45(A), FIG. 45(B), and FIG. 45(C) are a top view and cross-sectional views of a transistor 100A of one embodiment of the present invention and a periphery of the transistor 100A.

FIG. 45(A) is a top view of a semiconductor device including the transistor 100A. FIG. 45(B) and FIG. 45(C) are cross-sectional views of the semiconductor device. Here, FIG. 45(B) is a cross-sectional view of a portion indicated by a dashed-dotted line A1-A2 in FIG. 45(A), and is a cross-sectional view in the channel length direction of the transistor 100A. FIG. 45(C) is a cross-sectional view of a portion indicated by a dashed-dotted line B1-B2 in FIG. 45(A), and is a cross-sectional view in the channel width direction of the transistor 100A. For clarity of the drawing, some components are not illustrated in the top view of FIG. 45(A).

### [Transistor 100A]

The transistor 100A includes an insulating layer 104 over a substrate 102, a semiconductor layer 108 over the insulating layer 104, an insulating layer 140 over the semiconductor layer 108, a metal oxide layer 114 over the insulating layer 140, a conductive layer 142 over the metal oxide layer 114, and an insulating layer 116 over the insulating layer 104, the semiconductor layer 108, and the conductive layer 142. A portion of the semiconductor layer 108 overlapping with the conductive layer 142 functions as a channel formation region.

For the semiconductor layer 108, a material similar to that of the above-described oxide 230 can be used.

As illustrated in FIGS. 45(A), 45(B), and 45(C), the transistor 100A includes an insulating layer 118 over the insulating layer 116, and includes a region where the insulating layer 118 and the insulating layer 104 are in contact with each other. The transistor 100A may further include a conductive layer 121a and a conductive layer 121b that are electrically connected to regions 108n through an opening portion 141a and an opening portion 141b that are provided in the insulating layer 116 and the insulating layer 118.

Note that in this specification and the like, the insulating layer 104 may be referred to as a first insulating film, the insulating layer 140 may be referred to as a second insulating film, the insulating layer 116 may be referred to as a third insulating film, and the insulating layer 118 may be referred to as a fourth insulating film. The conductive layer 142 functions as a gate electrode, the conductive layer 121a functions as a source electrode, and the conductive layer 121b functions as a drain electrode.

The insulating layer 140 functioning as a gate insulating layer includes an excess oxygen region. Since the insulating layer 140 includes the excess oxygen region, excess oxygen can be supplied to the semiconductor layer 108. As a result, oxygen vacancies that might be formed in the semiconductor layer 108 can be filled with excess oxygen, and the semiconductor device having high reliability can be provided.

The metal oxide layer 114 positioned between the insulating layer 140 and the conductive layer 142 functions as a barrier film that prevents oxygen released from the insulating layer 140 from diffusing into the conductive layer 142 side. For the metal oxide layer 114, a material that less easily transmits oxygen than at least the insulating layer 140 can be used, for example.

As the metal oxide layer 114, an insulating material or a conductive material can be used. When the metal oxide layer 114 has an insulating property, the metal oxide layer 114 functions as part of the gate insulating layer. In contrast, when the metal oxide layer 114 has conductivity, the metal oxide layer 114 functions as part of the gate electrode.

In particular, an insulating material having a higher relative permittivity than silicon oxide is preferably used for the metal oxide layer 114. It is particularly preferable to use an aluminum oxide film, a hafnium oxide film, a hafnium aluminate film, or the like.

A structure using a metal oxide film that does not contain nitrogen as its main component, such as an aluminum oxide film or a hafnium oxide film, between the semiconductor layer 108 and the conductive layer 142 functioning as the gate electrode can be employed. Accordingly, the metal oxide layer 114 can have an extremely low content of a nitrogen oxide (NOₓ, where x is larger than 0 and smaller than or equal to 2, preferably larger than or equal to 1 and smaller than or equal to 2; typically NO₂ or NO) that might form a level in the film. Thus, a transistor with excellent electrical characteristics and reliability can be achieved.

An aluminum oxide film, a hafnium oxide film, a hafnium aluminate film, and the like have sufficiently high barrier properties even with a small thickness (e.g., a thickness of approximately 5 nm); thus, such a film can be formed thin, which can increase the productivity. For example, the metal oxide layer 114 can have a thickness more than or equal to 1 nm and less than or equal to 50 nm, preferably more than or equal to 3 nm and less than or equal to 30 nm. Moreover, an aluminum oxide film, a hafnium oxide film, and a hafnium aluminate film have a feature of a higher relative permittivity than that of a silicon oxide film or the like. A thin insulating film with a high relative permittivity can be formed as the metal oxide layer 114; hence, the intensity of a gate electric field applied to the semiconductor layer 108 can be increased compared to the case of using a silicon oxide film or the like. This results in lower driving voltage and lower power consumption.

The metal oxide layer 114 is preferably formed using a sputtering apparatus. For example, when an aluminum oxide film is formed using a sputtering apparatus, formation in an atmosphere containing an oxygen gas enables oxygen to be added to the semiconductor layer 108 in a favorable manner. An aluminum oxide film formed with a sputtering apparatus is preferable because the film density can be increased.

When a conductive material is used for the metal oxide layer 114, an oxide conductive material such as indium oxide or indium tin oxide can be used.

In addition, it is preferable that water or hydrogen be not easily diffused into the metal oxide layer 114. In this case, even when a material into which water or hydrogen is easily diffused is used for the conductive layer 142, the insulating layer 140 or the semiconductor layer 108 can prevent diffusion of water or hydrogen. An aluminum oxide film or a hafnium oxide film is particularly preferable because of their high barrier properties against water or hydrogen.

In order to supply excess oxygen to the semiconductor layer 108, excess oxygen may be supplied to the insulating layer 104 formed below the semiconductor layer 108. In that case, excess oxygen contained in the insulating layer 104 might also be supplied to the regions 108n. It is not desirable that excess oxygen be supplied to the regions 108n because the resistance of the regions 108n is increased. In contrast, in the structure in which the insulating layer 140 formed above the semiconductor layer 108 contains excess oxygen, excess oxygen can be selectively supplied only to a region overlapping with the conductive layer 142.

Here, oxygen vacancies that might be formed in the semiconductor layer 108 will be described.

Oxygen vacancies formed in the semiconductor layer 108 adversely affect the transistor characteristics and therefore cause a problem. For example, when oxygen vacancies are formed in the semiconductor layer 108, the oxygen vacancies are bonded to hydrogen and can serve as carrier supply sources. The carrier supply sources generated in the semiconductor layer 108 cause a change in the electrical characteristics, typically, a shift in the threshold voltage, of the transistor 100A. Therefore, it is preferable that the amount of oxygen vacancies in the semiconductor layer 108 be as small as possible.

In view of this, in one embodiment of the present invention, a structure in which an insulating film in the vicinity of the semiconductor layer 108, specifically the insulating layer 140 formed above the semiconductor layer 108, contains excess oxygen is employed. Oxygen or excess oxygen is transferred from the insulating layer 140 to the semiconductor layer 108, whereby oxygen vacancies in the semiconductor layer 108 can be reduced.

Note that the insulating layer 104 positioned below the semiconductor layer 108 may contain excess oxygen. In that case, excess oxygen is transferred also from the insulating layer 104 to the semiconductor layer 108, whereby the amount of oxygen vacancies in the semiconductor layer 108 can be further reduced.

The insulating layer 118 positioned over the semiconductor layer 108 may contain excess oxygen. Since a region where the insulating layer 118 and the insulating layer 104 are in contact with each other is included, excess oxygen can be transferred from the insulating layer 118 to the semiconductor layer 108 through the insulating layer 104; thus, oxygen vacancies in the semiconductor layer 108 can be further reduced.

Impurities such as hydrogen or moisture entering the semiconductor layer 108 adversely affect the transistor characteristics and therefore cause a problem. Thus, it is preferable that the amount of impurities such as hydrogen or moisture in the semiconductor layer 108 be as small as possible.

It is preferable to use, as the semiconductor layer 108, a metal oxide film in which the impurity concentration is low and the density of defect states is low, in which case the transistor having excellent electrical characteristics can be fabricated. Here, the state in which the impurity concentration is low and the density of defect states is low (the amount of oxygen vacancies is small) is referred to as highly purified intrinsic or substantially highly purified intrinsic. A highly purified intrinsic or substantially highly purified intrinsic metal oxide film has few carrier generation sources, and thus can have a low carrier density. Thus, a transistor in which a channel region is formed in the metal oxide film rarely has electrical characteristics with a negative threshold voltage (also referred to as normally-on). The highly purified intrinsic or substantially highly purified intrinsic metal oxide film has a low density of defect states and accordingly has a low density of trap states in some cases. Furthermore, a highly purified intrinsic or substantially highly purified intrinsic metal oxide film has an extremely low off-state current; even an element having a channel width of 1×10⁶ μm and a channel length of 10 μm can have an off-state current which is lower than or equal to the measurement limit of a semiconductor parameter analyzer, that is, lower than or equal to 1×10⁻¹³ A, at a voltage (drain voltage) between a source electrode and a drain electrode ranging from 1 V to 10 V.

The transistor 100A can be used for a display device. For example, the transistor 100A can be used for a pixel circuit, a gate driver circuit, and a source driver circuit included in the display device.

### <Constituent Material of Semiconductor Device>

Constituent materials that can be used for a semiconductor device are described below.

### <<Substrate>>

As a substrate over which the above-described transistor is formed, for example, an insulator substrate, a semiconductor substrate, or a conductor substrate may be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like, and a compound semiconductor substrate of silicon carbide, silicon germanium, gallium arsenide, indium phosphide, zinc oxide, or gallium oxide. In addition, a semiconductor substrate in which an insulator region is included in the above semiconductor substrate, e.g., an SOI (Silicon On Insulator) substrate and the like are given. Examples of the conductor substrate include a graphite substrate, a metal substrate, an alloy substrate, and a conductive resin substrate. Moreover, a substrate including a metal nitride, a substrate including a metal oxide, and the like are given. Furthermore, an insulator substrate provided with a conductor or a semiconductor, a semiconductor substrate provided with a conductor or an insulator, a conductor substrate provided with a semiconductor or an insulator, and the like are given. Alternatively, any of these substrates provided with an element may be used. Examples of the element provided over the substrate include a capacitor, a resistor, a switching element, a light-emitting element, and a memory element.

Moreover, a flexible substrate may be used as the substrate. Note that as a method of providing a transistor over a flexible substrate, there is a method in which a transistor is fabricated over a non-flexible substrate and then the transistor is separated and transferred to a substrate which is a flexible substrate. In that case, a separation layer is preferably provided between the non-flexible substrate and the transistor. Alternatively, the substrate may have elasticity. The substrate may also have a property of returning to its original shape when bending or pulling is stopped. Alternatively, the substrate may have a property of not returning to its original shape. The substrate includes a region with a thickness of, for example, greater than or equal to 5 μm and less than or equal to 700 μm, preferably greater than or equal to 10 μm and less than or equal to 500 μm, and further preferably greater than or equal to 15 μm and less than or equal to 300 μm. When the substrate has a small thickness, the weight of the semiconductor device including the transistor can be reduced. Moreover, when the substrate has a small thickness, the substrate may have elasticity or a property of returning to its original shape when bending or pulling is stopped, even in the case of using glass or the like. Thus, an impact applied to the semiconductor device over the substrate due to dropping or the like can be reduced. That is, a durable semiconductor device can be provided.

For the substrate which is a flexible substrate, metal, an alloy, a resin, glass, fiber thereof, or the like can be used, for example. As the substrate, a sheet, a film, or a foil containing a fiber may be used. The substrate which is a flexible substrate preferably has a lower coefficient of linear expansion because deformation due to an environment is suppressed. For the substrate which is a flexible substrate, a material whose coefficient of linear expansion is lower than or equal to 1×10⁻³/K, lower than or equal to 5×10⁻⁵/K, or lower than or equal to 1×10⁻⁵/K can be used, for example. Examples of the resin include polyester, polyolefin, polyamide (nylon, aramid, or the like), polyimide, polycarbonate, and acrylic. In particular, aramid is preferable for the substrate which is a flexible substrate because of its low coefficient of linear expansion.

### <<Insulator>>

Examples of an insulator include an oxide, a nitride, an oxynitride, a nitride oxide, a metal oxide, a metal oxynitride, and a metal nitride oxide, each of which has an insulating property.

When a high-k material having a high relative permittivity is used for the insulator functioning as the gate insulator, miniaturization and high integration of the transistor can be achieved. In contrast, when a material having a low relative permittivity is used for the insulator functioning as an interlayer film, the parasitic capacitance that is generated between wirings can be reduced. Accordingly, a material is preferably selected depending on the function of an insulator.

As the insulator having a high relative permittivity, gallium oxide, hafnium oxide, zirconium oxide, an oxide containing aluminum and hafnium, an oxynitride containing aluminum and hafnium, an oxide containing silicon and hafnium, an oxynitride containing silicon and hafnium, a nitride containing silicon and hafnium, or the like can be given.

As the insulator having a low relative permittivity, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be given.

In particular, silicon oxide and silicon oxynitride are thermally stable. Accordingly, a stacked-layer structure which is thermally stable and has a low relative permittivity can be obtained by combination with a resin, for example. Examples of the resin include polyester, polyolefin, polyamide (e.g., nylon or aramid), polyimide, polycarbonate, and acrylic. Furthermore, combination of silicon oxide or silicon oxynitride with an insulator having a high relative permittivity allows the stacked-layer structure to be thermally stable and have a high relative permittivity, for example.

Note that when the transistor including an oxide semiconductor is surrounded by an insulator having a function of suppressing transmission of oxygen and impurities such as hydrogen, the electrical characteristics of the transistor can be stabilized.

As the insulator having a function of suppressing transmission of oxygen and impurities such as hydrogen, for example, a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of suppressing transmission of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

For example, an insulator that has a function of suppressing transmission of oxygen and impurities such as hydrogen may be used as the insulator 210, the insulator 214, and the insulator 222. Note that the insulator 210, the insulator 214, and the insulator 222 preferably contain aluminum oxide, hafnium oxide, or the like.

For example, as the insulating layer 104, the insulating layer 140, the insulator 220, the insulator 224, the insulator 250, and the insulator 274, a single layer or a stacked layer of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, silicon oxide, silicon oxynitride, or silicon nitride is preferably contained.

For example, when a structure is employed in which aluminum oxide, gallium oxide, or hafnium oxide is in contact with the oxide 230 in the insulator 224 and the insulator 250 functioning as gate insulators, silicon contained in silicon oxide or silicon oxynitride can be inhibited from entering the oxide 230. Furthermore, when a structure is employed in which silicon oxide or silicon oxynitride is in contact with the oxide 230 in the insulator 224 and the insulator 250, trap centers are formed at the interface between aluminum oxide, gallium oxide, or hafnium oxide and silicon oxide or silicon oxynitride, in some cases. The trap centers can shift the threshold voltage of the transistor in the positive direction by trapping electrons in some cases.

The insulating layer 118, the insulator 212, the insulator 216, the insulator 271, and the insulator 280 preferably include an insulator with a low relative permittivity. For example, the insulating layer 118, the insulator 212, the insulator 216, the insulator 271, and the insulator 280 preferably include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. Alternatively, each of the insulator 212, the insulator 216, and the insulator 280 preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with resin, the stacked-layer structure can have thermal stability and low relative permittivity. Examples of the resin include polyester, polyolefin, polyamide (e.g., nylon or aramid), polyimide, polycarbonate, and acrylic.

As the insulator 270, the insulator 272, the insulator 275, and the insulator 282, an insulator having a function of suppressing transmission of oxygen and impurities such as hydrogen may be used. For the insulator 270, the insulator 272, the insulator 275, and the insulator 282, a metal oxide such as aluminum oxide, hafnium oxide, magnesium oxide, gallium oxide, germanium oxide, yttrium oxide, zirconium oxide, lanthanum oxide, neodymium oxide, or tantalum oxide; silicon nitride oxide; silicon nitride; or the like may be used, for example.

### <<Conductor>>

As the conductors, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. A semiconductor having a high electric conductivity typified by polycrystalline silicon including an impurity element such as phosphorus, or silicide such as nickel silicide may be used.

A stack of a plurality of conductive layers formed with the above materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. Alternatively, a stacked-layer structure combining a material containing the above metal element, a conductive material containing oxygen, and a conductive material containing nitrogen may be employed.

Note that in the case where an oxide is used for the channel formation region of the transistor, a stacked-layer structure combining a material containing the above metal element and a conductive material containing oxygen is preferably used for the conductor functioning as the gate electrode. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, as the conductor functioning as the gate electrode, a conductive material containing oxygen and a metal element contained in the metal oxide forming a channel. Furthermore, a conductive material containing the above metal element and nitrogen may be used. For example, a conductive material containing nitrogen, such as titanium nitride or tantalum nitride, may be used. Alternatively, an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon is added may be used. Furthermore, indium gallium zinc oxide containing nitrogen may be used. With the use of such a material, hydrogen contained in the metal oxide forming a channel can be captured in some cases. Alternatively, hydrogen entering from an external insulator or the like can be captured in some cases.

As the conductive layer 121a, the conductive layer 121b, the conductive layer 141, the conductor 260a, the conductor 260b, the conductor 203a, the conductor 203b, the conductor 205a, and the conductor 205b, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having a high electric conductivity typified by polycrystalline silicon including an impurity element such as phosphorus, or silicide such as nickel silicide may be used.

### <<Metal Oxide>>

As the semiconductor layer 108 and the oxide 230, a metal oxide functioning as an oxide semiconductor (hereinafter also referred to as an oxide semiconductor) is preferably used. A metal oxide that can be used as the semiconductor layer and the oxide 230 of the present invention is described below.

An oxide semiconductor preferably contains at least indium or zinc. In particular, indium and zinc are preferably contained. Moreover, aluminum, gallium, yttrium, tin, or the like is preferably contained in addition to them. Furthermore, one or more kinds selected from boron, silicon, titanium, iron, nickel, germanium, zirconium, molybdenum, lanthanum, cerium, neodymium, hafnium, tantalum, tungsten, magnesium, and the like may be contained.

Here, the case where the oxide semiconductor is an In-M-Zn oxide that contains indium, an element M, and zinc is considered. Note that the element M is aluminum, gallium, yttrium, tin, or the like. Other elements that can be used as the element M include boron, silicon, titanium, iron, nickel, germanium, zirconium, molybdenum, lanthanum, cerium, neodymium, hafnium, tantalum, tungsten, magnesium, and the like. Note that a plurality of the above-described elements may be combined as the element M.

### [Composition of Metal Oxide]

The composition of a CAC (Cloud-Aligned Composite)-OS that can be used for a transistor disclosed in one embodiment of the present invention is described below.

Note that the terms “CAAC (c-axis aligned crystal)” and “CAC (Cloud-Aligned Composite)” might appear in this specification and the like. CAAC refers to an example of a crystal structure, and CAC refers to an example of a function or a material composition.

A CAC-OS or a CAC-metal oxide has a conducting function in a part of the material and has an insulating function in another part of the material; as a whole, the CAC-OS or the CAC-metal oxide has a function of a semiconductor. In the case where the CAC-OS or the CAC-metal oxide is used in an active layer of a transistor, the conducting function is to allow electrons (or holes) serving as carriers to flow, and the insulating function is to not allow electrons serving as carriers to flow. By the complementary action of the conducting function and the insulating function, the CAC-OS or the CAC-metal oxide can have a switching function (On/Off function). In the CAC-OS or the CAC-metal oxide, separation of the functions can maximize each function.

Furthermore, the CAC-OS or the CAC-metal oxide includes conductive regions and insulating regions. The conductive regions have the above-described conducting function, and the insulating regions have the above-described insulating function. In some cases, the conductive regions and the insulating regions in the material are separated at the nanoparticle level. In some cases, the conductive regions and the insulating regions are unevenly distributed in the material. The conductive regions are observed to be coupled in a cloud-like manner with their boundaries blurred, in some cases.

Furthermore, in the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm, and are dispersed in the material, in some cases.

Furthermore, the CAC-OS or the CAC-metal oxide includes components having different bandgaps. For example, the CAC-OS or the CAC-metal oxide includes a component having a wide gap due to the insulating region and a component having a narrow gap due to the conductive region. When carriers flow in this composition, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or the CAC-metal oxide is used in a channel region of a transistor, high current drive capability in the on state of the transistor, that is, a high on-state current and high field-effect mobility, can be obtained.

In other words, the CAC-OS or the CAC-metal oxide can also be referred to as a matrix composite or a metal matrix composite.

### [Structure of Metal Oxide]

Oxide semiconductors can be classified into a single crystal oxide semiconductor and a non-single-crystal oxide semiconductor. Examples of a non-single-crystal oxide semiconductor include a CAAC-OS (c-axis-aligned crystalline oxide semiconductor), a polycrystalline oxide semiconductor, an nc-OS (nanocrystalline oxide semiconductor), an a-like OS (amorphous-like oxide semiconductor), and an amorphous oxide semiconductor.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) cannot be observed even in the vicinity of distortion in the CAAC-OS. That is, formation of a crystal grain boundary is suppressed by the distortion of a lattice arrangement. This is probably because the CAAC-OS can tolerate distortion owing to a low density of arrangement of oxygen atoms in the a-b plane direction, an interatomic bond length changed by substitution of a metal element, and the like.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M,Zn) layer) are stacked. Note that indium and the element M can be replaced with each other, and when the element M in the (M,Zn) layer is replaced with indium, the layer can also be referred to as an (In,M,Zn) layer. Furthermore, when indium in the In layer is replaced with the element M, the layer can be referred to as an (In,M) layer.

The CAAC-OS is an oxide semiconductor with high crystallinity. On the other hand, a clear crystal grain boundary cannot be observed in the CAAC-OS; thus, it can be said that a reduction in electron mobility due to the crystal grain boundary is unlikely to occur. Furthermore, entry of impurities, formation of defects, or the like might decrease the crystallinity of an oxide semiconductor; thus, it can be said that the CAAC-OS has small amounts of impurities and defects (e.g., oxygen vacancies). Thus, an oxide semiconductor including a CAAC-OS is physically stable. Therefore, the oxide semiconductor including a CAAC-OS is resistant to heat and has high reliability.

In the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor depending on the analysis method.

The a-like OS is an oxide semiconductor having a structure between those of the nc-OS and an amorphous oxide semiconductor. The a-like OS includes a void or a low-density region. That is, the a-like OS has low crystallinity as compared with the nc-OS and the CAAC-OS.

An oxide semiconductor can have various structures which show different properties. Two or more kinds selected from the amorphous oxide semiconductor, the polycrystalline oxide semiconductor, the a-like OS, the nc-OS, and the CAAC-OS may be included in an oxide semiconductor of one embodiment of the present invention.

### [Transistor Containing Oxide Semiconductor]

Next, the case where the oxide semiconductor is used for a transistor will be described.

When the oxide semiconductor is used in a transistor, the transistor can have high field-effect mobility. In addition, the transistor can have high reliability.

An oxide semiconductor with a low carrier density is preferably used for the transistor. In the case where the carrier density of an oxide semiconductor film is reduced, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. For example, the carrier density of an oxide semiconductor is lower than 8×10¹¹/cm³, preferably lower than 1×10¹¹/cm³, further preferably lower than 1×10¹⁰/cm³, and higher than or equal to 1×10⁻⁹/cm³.

A highly purified intrinsic or substantially highly purified intrinsic oxide semiconductor film has a low density of defect states and accordingly has a low density of trap states in some cases.

Furthermore, charges trapped by the trap states in the oxide semiconductor take a long time to disappear and may behave like fixed charges. Thus, a transistor whose channel region is formed in the oxide semiconductor having a high density of trap states has unstable electrical characteristics in some cases.

Thus, in order to stabilize electrical characteristics of the transistor, reducing the impurity concentration in the oxide semiconductor is effective. Furthermore, in order to reduce the impurity concentration in the oxide semiconductor, the impurity concentration in an adjacent film is also preferably reduced. Examples of impurities include hydrogen, nitrogen, an alkali metal, an alkaline earth metal, iron, nickel, and silicon.

### [Impurity]

Here, the influence of each impurity in the oxide semiconductor is described.

When silicon or carbon, which is one of the Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration measured by secondary ion mass spectrometry (SIMS)) are set lower than or equal to 2×10¹⁸ atoms/cm³, preferably lower than or equal to 2×10¹⁷ atoms/cm³.

Furthermore, when the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Accordingly, it is preferable to reduce the concentration of an alkali metal or an alkaline earth metal in the oxide semiconductor. Specifically, the concentration of an alkali metal or an alkaline earth metal in the oxide semiconductor obtained by SIMS is set lower than or equal to 1×10¹⁸ atoms/cm³, preferably lower than or equal to 2×10¹⁶ atoms/cm³.

Furthermore, when containing nitrogen, the oxide semiconductor easily becomes n-type by generation of electrons serving as carriers and an increase of carrier density. As a result, a transistor using an oxide semiconductor containing nitrogen as a semiconductor is likely to have normally-on characteristics. For this reason, nitrogen in the oxide semiconductor is preferably reduced as much as possible; the nitrogen concentration in the oxide semiconductor obtained by SIMS is set, for example, lower than 5×10¹⁹ atoms/cm³, preferably lower than or equal to 5×10¹⁸ atoms/cm³, further preferably lower than or equal to 1×10¹⁸ atoms/cm³, and still further preferably lower than or equal to 5×10¹⁷ atoms/cm³.

Furthermore, hydrogen contained in an oxide semiconductor reacts with oxygen bonded to a metal atom to be water, and thus forms oxygen vacancies in some cases. Entry of hydrogen into the oxygen vacancies generates electrons serving as carriers in some cases. Furthermore, in some cases, bonding of part of hydrogen to oxygen bonded to a metal atom causes generation of an electron serving as a carrier. Thus, a transistor using an oxide semiconductor containing hydrogen tends to have normally-on characteristics. Accordingly, hydrogen in the oxide semiconductor is preferably reduced as much as possible. Specifically, the hydrogen concentration in the oxide semiconductor obtained by SIMS is lower than 1×10²⁰ atoms/cm³, preferably lower than 1×10¹⁹ atoms/cm³, further preferably lower than 5×10¹⁸ atoms/cm³, and still further preferably lower than 1×10¹⁸ atoms/cm³.

When an oxide semiconductor with sufficiently reduced impurities is used for a channel region of a transistor, stable electrical characteristics can be given.

### <Manufacturing Method 1 of Semiconductor Device>

Next, a method for manufacturing a semiconductor device including the transistor 200 of the present invention is described with reference to FIG. 1 and FIG. 15 to FIG. 23. In FIG. 1 and FIG. 15 to FIG. 23, (A) of each drawing shows a top view. (B) of each drawing is a cross-sectional view corresponding to a portion taken along a dashed-dotted line A1-A2 in (A). Furthermore, (C) of each drawing is a cross-sectional view corresponding to a portion taken along a dashed-dotted line A3-A4 in (A).

First, a substrate (not illustrated) is prepared, and the insulator 210 is deposited over the substrate. The insulator 210 can be deposited by a sputtering method, a chemical vapor deposition (CVD) method, a molecular beam epitaxy (MBE) method, a pulsed laser deposition (PLD) method, an ALD method, or the like.

Note that CVD methods can be classified into a plasma enhanced CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas.

By a plasma CVD method, a high-quality film can be obtained at a relatively low temperature. Furthermore, a thermal CVD method is a deposition method that does not use plasma and thus enables less plasma damage to an object. For example, a wiring, an electrode, an element (e.g., transistor or capacitor), or the like included in a semiconductor device might be charged up by receiving electric charges from plasma. In that case, accumulated electric charges might break the wiring, electrode, element, or the like included in the semiconductor device. By contrast, such plasma damage is not caused in the case of using a thermal CVD method that does not use plasma, and thus the yield of a semiconductor device can be increased. In addition, a thermal CVD method does not cause plasma damage during deposition, so that a film with few defects can be obtained.

An ALD method is also a deposition method which enables less plasma damage to an object. An ALD method also does not cause plasma damage during deposition, so that a film with few defects can be obtained.

Unlike in a deposition method in which particles ejected from a target or the like are deposited, a CVD method and an ALD method are deposition methods in which a film is formed by reaction at a surface of an object. Thus, a CVD method and an ALD method are deposition methods that enable favorable step coverage almost regardless of the shape of an object. In particular, an ALD method enables excellent step coverage and excellent thickness uniformity, and thus is suitable for the case of covering a surface of an opening portion with a high aspect ratio, for example. On the other hand, an ALD method has a relatively low deposition rate, and thus is preferably used in combination with another deposition method with a high deposition rate such as a CVD method, in some cases.

A CVD method and an ALD method enable control of the composition of a film to be obtained with a flow rate ratio of the source gases. For example, with a CVD method or an ALD method, a film with a desired composition can be deposited by adjusting the flow rate ratio of the source gases. Moreover, with a CVD method or an ALD method, by changing the flow rate ratio of the source gases during the deposition, a film whose composition is continuously changed can be deposited. In the case of performing deposition while changing the flow rate ratio of the source gases, as compared with the case of performing deposition with the use of a plurality of deposition chambers, time taken for the deposition can be shortened because time taken for transfer and pressure adjustment is omitted. Thus, productivity of semiconductor devices can be improved in some cases.

In this embodiment, as the insulator 210, aluminum oxide is deposited by a sputtering method. The insulator 210 may have a multilayer structure. For example, a structure may be employed in which aluminum oxide is deposited by a sputtering method and another aluminum oxide is deposited over the aluminum oxide by an ALD method. Alternatively, a structure may be employed in which aluminum oxide is deposited by an ALD method and another aluminum oxide is deposited over the aluminum oxide by a sputtering method.

Next, the insulator 212 is deposited over the insulator 210. The insulator 212 can be deposited by a sputtering method, a CVD method, an MBE method, a PLD method, an ALD method, or the like. In this embodiment, as the insulator 212, silicon oxide is deposited by a CVD method.

Then, an opening is formed in the insulator 212 to reach the insulator 210. Examples of the opening include a groove and a slit. A region where the opening is formed is referred to as an opening portion, in some cases. The opening may be formed by wet etching; however, dry etching is preferably used for microfabrication. In addition, as the insulator 210, an insulator functioning as an etching stopper film when the groove is formed by etching the insulator 212 is preferably selected. For example, in the case where a silicon oxide film is used as the insulator 212 in which the groove is to be formed, a silicon nitride film, an aluminum oxide film, or a hafnium oxide film is preferably used as the insulator 210.

After the formation of the opening, a conductive film to be the conductor 203a is deposited. The conductive film desirably includes a conductor having a function of suppressing transmission of oxygen. For example, tantalum nitride, tungsten nitride, titanium nitride, or the like can be used. Alternatively, a stacked-layer film with tantalum, tungsten, titanium, molybdenum, aluminum, copper, or a molybdenum-tungsten alloy can be used. The conductor to be the conductor 203a can be deposited by a sputtering method, a CVD method, an MBE method, a PLD method, an ALD method, or the like.

In this embodiment, tantalum nitride or a film of tantalum nitride and titanium nitride stacked thereover is deposited by a sputtering method as the conductive film to be the conductor 203a. With the use of such a metal nitride as the conductor 203a, even when a metal that easily diffuses, such as copper, is used as the conductor 203b described later, the metal can be prevented from diffusing outward through the conductor 203a.

Next, a conductive film to be the conductor 203b is deposited over the conductive film to be the conductor 203a. The conductive film can be deposited by a sputtering method, a CVD method, an MBE method, a PLD method, an ALD method, or the like. In this embodiment, a low-resistance conductive material such as copper is deposited as the conductive film to be the conductor 203b.

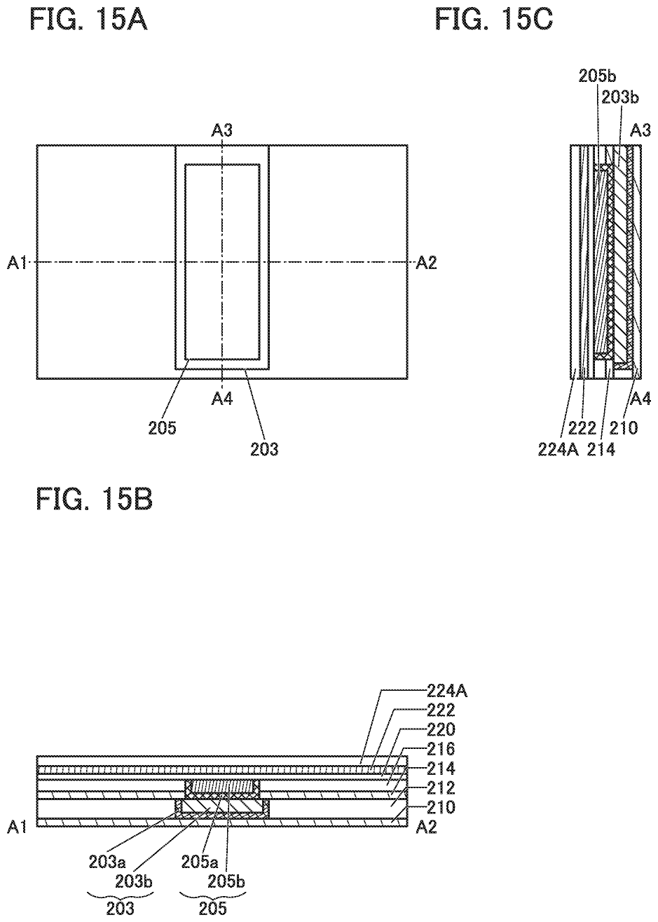

Next, by CMP treatment, the conductive film to be the conductor 203a and the conductive film to be the conductor 203b are partly removed to expose the insulator 212. As a result, the conductive film to be the conductor 203a and the conductive film to be the conductor 203b remain only in the opening portion. Thus, the conductor 203 including the conductor 203a and the conductor 203b, which has a flat top surface, can be formed (see FIG. 15). Note that the insulator 212 is partly removed by the CMP treatment in some cases.

Next, the insulator 214 is formed over the conductor 203. The insulator 214 can be deposited by a sputtering method, a CVD method, an MBE method, a PLD method, an ALD method, or the like. In this embodiment, as the insulator 214, silicon nitride is deposited by a CVD method. As described here, an insulator which does not easily transmit copper, such as silicon nitride, is used as the insulator 214; accordingly, even when a metal that easily diffuses, such as copper, is used as the conductor 203b, the metal can be prevented from diffusing into layers above the insulator 214.

Next, the insulator 216 is deposited over the insulator 214. The insulator 216 can be deposited by a sputtering method, a CVD method, an MBE method, a PLD method, an ALD method, or the like. In this embodiment, as the insulator 216, silicon oxide is deposited by a CVD method.

Next, an opening reaching the conductor 203 is formed in the insulator 214 and the insulator 216. The opening may be formed by wet etching; however, dry etching is preferably used for microfabrication.

After the formation of the opening, a conductive film to be the conductor 205a is deposited. The conductive film to be the conductor 205a desirably includes a conductive material having a function of suppressing transmission of oxygen. For example, tantalum nitride, tungsten nitride, titanium nitride, or the like can be used. Alternatively, a stacked-layer film with tantalum, tungsten, titanium, molybdenum, aluminum, copper, or a molybdenum-tungsten alloy can be used.

The conductive film to be the conductor 205a can be deposited by a sputtering method, a CVD method, an MBE method, a PLD method, an ALD method, or the like.

In this embodiment, tantalum nitride is deposited by a sputtering method as the conductive film to be the conductor 205a.

Next, a conductive film to be the conductor 205b is deposited over the conductive film to be the conductor 205a. The conductive film can be deposited by a sputtering method, a CVD method, an MBE method, a PLD method, an ALD method, or the like.

In this embodiment, as the conductive film to be the conductor 205b, titanium nitride is deposited by a CVD method and tungsten is deposited over the titanium nitride by a CVD method.

Next, by CMP treatment, the conductive film to be the conductor 205a and the conductive film to be the conductor 205b are partly removed to expose the insulator 216. As a result, the conductive films to be the conductor 205a and the conductor 205b remain only in the opening portion. Thus, the conductor 205 including the conductor 205a and the conductor 205b, which has a flat top surface, can be formed (see FIG. 15). Note that the insulator 216 is partly removed by the CMP treatment in some cases.

Next, the insulator 220 is deposited over the insulator 216 and the conductor 205. The insulator 220 can be deposited by a sputtering method, a CVD method, an MBE method, a PLD method, an ALD method, or the like.

Next, the insulator 222 is deposited over the insulator 220. The insulator 222 can be deposited by a sputtering method, a CVD method, an MBE method, a PLD method, an ALD method, or the like.

It is particularly preferable that hafnium oxide be formed as the insulator 222 by an ALD method. Hafnium oxide deposited by an ALD method has a barrier property against oxygen, hydrogen, and water. When the insulator 222 has a barrier property against hydrogen and water, hydrogen and water contained in structure bodies provided around the transistor 200 are not diffused into the transistor 200, and generation of oxygen vacancies in the oxide 230 can be suppressed.

Then, an insulating film 224A is deposited over the insulator 222. The insulating film 224A can be deposited by a sputtering method, a CVD method, an MBE method, a PLD method, an ALD method, or the like (see FIG. 15).

Subsequently, heat treatment is preferably performed. The heat treatment is performed at a temperature higher than or equal to 250° C. and lower than or equal to 650° C., preferably higher than or equal to 300° C. and lower than or equal to 500° C., further preferably higher than or equal to 320° C. and lower than or equal to 450° C. The heat treatment is performed in a nitrogen or inert gas atmosphere or an atmosphere containing an oxidizing gas at 10 ppm or more, 1% or more, or 10% or more. The heat treatment may be performed under a reduced pressure.

Alternatively, the heat treatment may be performed in such a manner that heat treatment is performed in a nitrogen or inert gas atmosphere, and then another heat treatment is performed in an atmosphere containing an oxidizing gas at 10 ppm or more, 1% or more, or 10% or more in order to compensate for released oxygen.

By the above heat treatment, impurities such as hydrogen and water contained in the insulating film 224A can be removed, for example.

Alternatively, in the heat treatment, plasma treatment with oxygen may be performed under a reduced pressure. For the plasma treatment with oxygen, an apparatus including a power source for generating high-density plasma using microwaves is preferably used, for example. Alternatively, a power source for applying an RF (Radio Frequency) to a substrate side may be provided. The use of high-density plasma enables high-density oxygen radicals to be produced, and application of the RF to the substrate side allows oxygen radicals generated by the high-density plasma to be efficiently introduced into the insulating film 224A. Alternatively, after plasma treatment with an inert gas is performed with this apparatus, plasma treatment with oxygen may be performed to compensate for released oxygen. Note that the heat treatment is not necessarily performed in some cases.

The heat treatment can also be performed after the deposition of the insulator 220 and after the deposition of the insulator 222. Although the heat treatment can be performed under the conditions for the above-described heat treatment, heat treatment after the deposition of the insulator 220 is preferably performed in an atmosphere containing nitrogen.

In this embodiment, the heat treatment is performed in a nitrogen atmosphere at a temperature of 400° C. for one hour after deposition of the insulating film 224A.

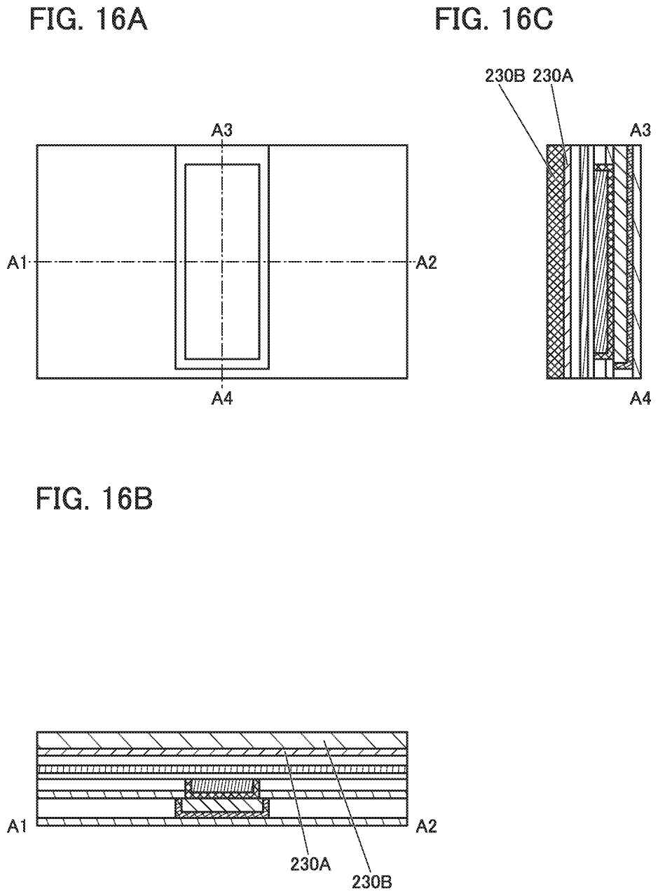

Next, an oxide film 230A to be the oxide 230a, and an oxide film 230B to be the oxide 230b are sequentially deposited over the insulating film 224A (see FIG. 16). Note that the oxide films are preferably deposited successively without exposure to the air. When the oxide films are deposited without exposure to the air, impurities or moisture from the air environment can be prevented from being attached to the oxide film 230A and the oxide film 230B, so that the vicinity of an interface between the oxide film 230A and the oxide film 230B can be kept clean.

The oxide film 230A and the oxide film 230B can be deposited by a sputtering method, a CVD method, an MBE method, a PLD method, an ALD method, or the like.

In the case where the oxide film 230A and the oxide film 230B are deposited by a sputtering method, for example, oxygen or a mixed gas of oxygen and a rare gas is used as a sputtering gas. By increasing the proportion of oxygen in the sputtering gas, excess oxygen in the deposited oxide films can be increased. In the case where the above oxide films are deposited by a sputtering method, the above In-M-Zn oxide target can be used.

In particular, when the oxide film 230A is deposited, part of oxygen contained in the sputtering gas is supplied to the insulating film 224A in some cases. Note that the proportion of oxygen contained in the sputtering gas of the oxide film 230A is preferably 70% or higher, further preferably 80% or higher, and still further preferably 100%.

In the case where the oxide film 230B is formed by a sputtering method, when the proportion of oxygen contained in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor can have relatively high field-effect mobility.

In this embodiment, the oxide film 230A is deposited using a target with In:Ga:Zn=1:3:4 [atomic ratio] by a sputtering method. The oxide film 230B is deposited by a sputtering method using a target with In:Ga:Zn=4:2:4.1 [atomic ratio]. Note that each of the oxide films is preferably formed by appropriate selection of film formation conditions and an atomic ratio according to characteristics required for the oxide 230.

Next, heat treatment may be performed. For the heat treatment, the conditions for the above-described heat treatment can be used. By the heat treatment, impurities such as hydrogen and water contained in the oxide film 230A and the oxide film 230B can be removed, for example. In this embodiment, treatment is performed in a nitrogen atmosphere at a temperature of 400° C. for one hour, and successively another treatment is performed in an oxygen atmosphere at a temperature of 400° C. for one hour.

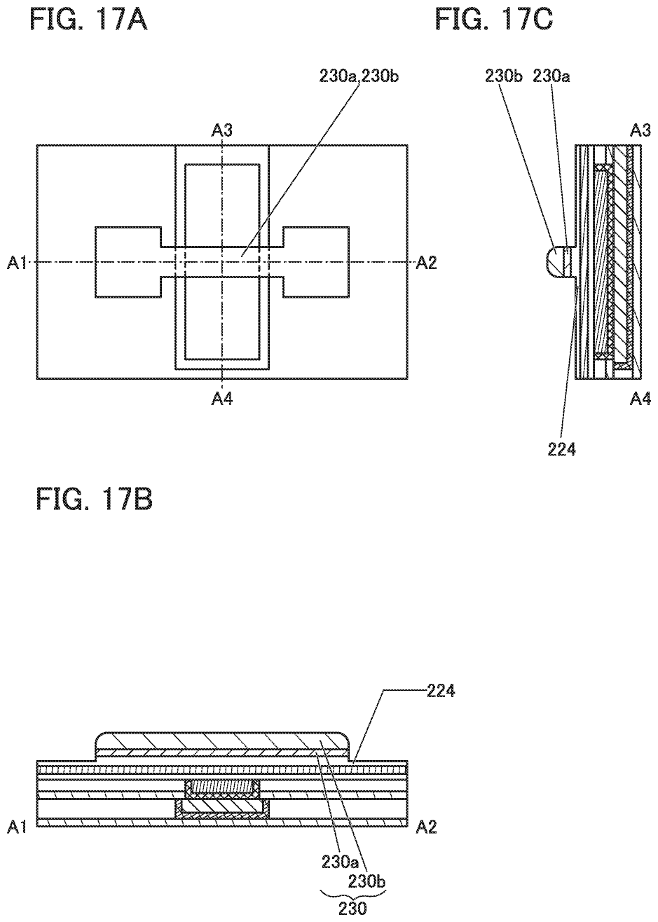

Next, the insulating film 224A, the oxide film 230A, and the oxide film 230B are processed into island shapes to form the insulator 224, the oxide 230a, and the oxide 230b (see FIG. 17). In this step, the insulator 222 can be used as an etching stopper film, for example.

Note that in the above step, the insulating film 224A is not necessarily processed into an island shape. The insulating film 224A may be subjected to half-etching, in which case the insulator 224 is formed to remain under the oxide 230c to be formed in a later step. Note that the insulating film 224A can be processed into an island shape when an insulating film 272A is processed in a later step.

The oxide 230 is formed to at least partly overlap with the conductor 205. It is preferable that the side surface of the oxide 230 be substantially perpendicular to the insulator 222, in which case a smaller area and higher density are achieved when the plurality of transistors 200 is provided. Note that an angle formed by the side surface of the oxide 230 and the top surface of the insulator 222 may be an acute angle. In that case, the angle formed by the side surface of the oxide 230 and the top surface of the insulator 222 is preferably as large as possible.

The oxide 230 has a curved surface between the side surface of the oxide 230 and the top surface of the oxide 230. That is, an end portion of the side surface and an end portion of the top surface are preferably curved (hereinafter also referred to as a rounded shape). The radius of curvature of the curved surface at the end portion of the oxide 230b is greater than or equal to 3 nm and less than or equal to 10 nm, preferably greater than or equal to 5 nm and less than or equal to 6 nm.

Note that when the end portions are not angular, the coverage with films formed in a later film formation process can be improved.

Note that the oxide films may be processed by a lithography method. The processing can be performed by a dry etching method or a wet etching method. The processing by a dry etching method is suitable for microfabrication.

In the lithography method, first, a resist is exposed to light through a mask. Next, a region exposed to light is removed or left using a developing solution, so that a resist mask is formed. Then, etching through the resist mask is conducted, whereby a conductor, a semiconductor, an insulator, or the like can be processed into a desired shape. The resist mask is formed by, for example, exposure of the resist to light using KrF excimer laser light, ArF excimer laser light, EUV (extreme ultraviolet) light, or the like. Alternatively, a liquid immersion technique may be employed in which a portion between a substrate and a projection lens is filled with liquid (e.g., water) to perform light exposure. An electron beam or an ion beam may be used instead of the above-mentioned light. Note that a mask is not necessary in the case of using an electron beam or an ion beam. To remove the resist mask, dry etching treatment such as ashing or wet etching treatment can be performed. Alternatively, wet etching treatment can be performed after dry etching treatment. Further alternatively, dry etching treatment can be performed after wet etching treatment.

A hard mask formed of an insulator or a conductor may be used instead of the resist mask. In the case where a hard mask is used, a hard mask with a desired shape can be formed by forming an insulating film or a conductive film that is the material of the hard mask over the oxide film 230B, forming a resist mask thereover, and then etching the material of the hard mask. The etching of the oxide film 230A and the oxide film 230B may be performed after or without removal of the resist mask. In the latter case, the resist mask may be removed during the etching. The hard mask may be removed by etching after the etching of the oxide films. The hard mask does not need to be removed in the case where the material of the hard mask does not affect the following process or can be utilized in the following process.

As a dry etching apparatus, a capacitively coupled plasma (CCP) etching apparatus including parallel plate type electrodes can be used. The capacitively coupled plasma etching apparatus including the parallel plate type electrodes may have a structure in which a high-frequency power source is applied to one of the parallel plate type electrodes. Alternatively, the capacitively coupled plasma etching apparatus may have a structure in which different high-frequency power sources are applied to one of the parallel plate type electrodes. Alternatively, the capacitively coupled plasma etching apparatus may have a structure in which high-frequency power sources with the same frequency are applied to the parallel plate type electrodes. Alternatively, the capacitively coupled plasma etching apparatus may have a structure in which high-frequency power sources with different frequencies are applied to the parallel plate type electrodes. Alternatively, a dry etching apparatus including a high-density plasma source can be used. As the dry etching apparatus including a high-density plasma source, an inductively coupled plasma (ICP) etching apparatus can be used, for example.

In some cases, the treatment such as dry etching causes the attachment or diffusion of impurities due to an etching gas or the like to a surface or an inside of the oxide 230a, the oxide 230b, or the like. Examples of the impurities include fluorine and chlorine.

In order to remove the impurities, cleaning is performed. Examples of the cleaning method include wet cleaning using a cleaning solution, plasma treatment using plasma, and cleaning by heat treatment, and any of these cleanings may be performed in appropriate combination.

As the wet cleaning, cleaning treatment may be performed using an aqueous solution obtained by diluting an oxalic acid, a phosphoric acid, a hydrofluoric acid, or the like with pure water or carbonated water. Alternatively, ultrasonic cleaning using pure water or carbonated water may be performed. In this embodiment, the ultrasonic cleaning using pure water or carbonated water is performed.

Next, heat treatment may be performed. For the heat treatment, the conditions for the above heat treatment can be used.

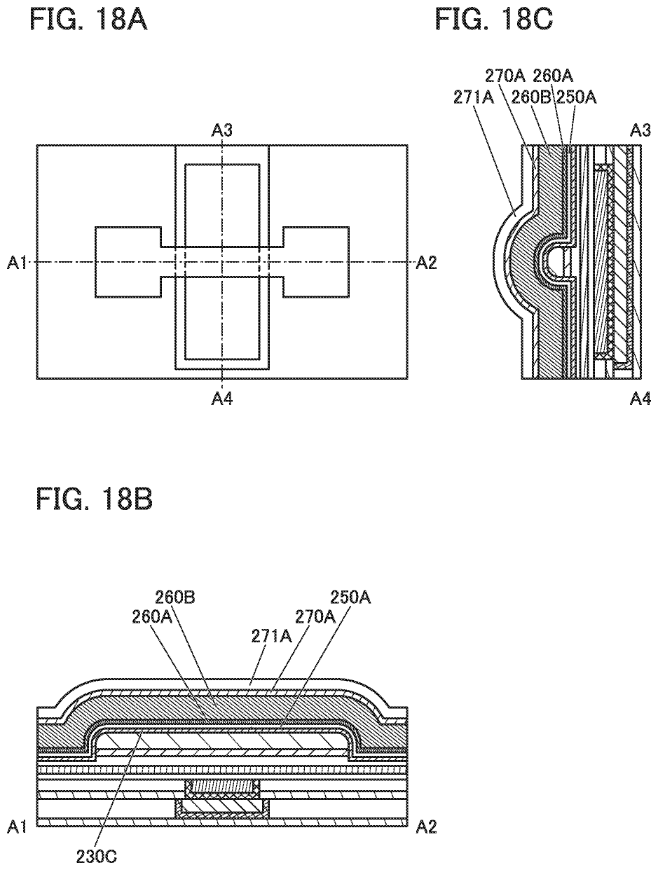

Next, an oxide film 230C to be the oxide 230c, an insulating film 250A, a conductive film 260A, a conductive film 260B, an insulating film 270A, and an insulating film 271A are formed in order over the insulator 224 and the oxide 230b (see FIG. 18).

The oxide film 230C can be deposited by a sputtering method, a CVD method, an MBE method, a PLD method, an ALD method, or the like.

For example, in the case where the oxide film 230C is deposited by a sputtering method, oxygen or a mixed gas of oxygen and a rare gas is used as a sputtering gas. By increasing the proportion of oxygen contained in the sputtering gas, excess oxygen in the deposited oxide film can be increased. In the case where the above oxide film is deposited by a sputtering method, the above In-M-Zn oxide target can be used.

In particular, in the deposition of the oxide film 230C, part of oxygen contained in the sputtering gas is supplied to the oxide 230b and the oxide 230a, in some cases. Note that the proportion of oxygen contained in the sputtering gas of the oxide film 230C is higher than or equal to 70%, preferably higher than or equal to 80%, and further preferably 100%.

In this embodiment, the oxide film 230C is deposited by a sputtering method using a target with In:Ga:Zn=1:3:4 [atomic ratio].

The insulating film 250A can be deposited by a sputtering method, a CVD method, an MBE method, a PLD method, an ALD method, or the like.

Note that oxygen is excited by microwaves to generate high-density oxygen plasma, and the insulating film 250A is exposed to the oxygen plasma, whereby oxygen can be introduced into the insulating film 250A and the oxide 230.

Furthermore, heat treatment may be performed. For the heat treatment, the conditions for the above heat treatment can be used. The heat treatment can reduce the moisture concentration and the hydrogen concentration in the insulating film 250A.

The conductive film 260A can be deposited by a sputtering method, a CVD method, an MBE method, a PLD method, an ALD method, or the like. Here, when an oxide semiconductor that can be used as the oxide 230 is subjected to treatment for reducing resistance, for example, the oxide semiconductor becomes a conductive oxide. Accordingly, an oxide that can be used as the oxide 230 may be deposited as the conductive film 260A and the resistance of the oxide may be reduced in a later step. Note that when an oxide that can be used as the oxide 230 is deposited as the conductive film 260A in an atmosphere containing oxygen by a sputtering method, oxygen can be added to the insulator 250. When oxygen is added to the insulator 250, the added oxygen can be supplied to the oxide 230 through the insulator 250.

The conductive film 260B can be deposited by a sputtering method, a CVD method, an MBE method, a PLD method, an ALD method, or the like. In the case where an oxide semiconductor that can be used as the oxide 230 is used for the conductive film 260A, the conductive film 260B is deposited by a sputtering method, whereby the conductive film 260A can have reduced electric resistance and become a conductor. Such a conductor can be referred to as an OC (Oxide Conductor) electrode. A conductor may be further deposited over the conductor over the OC electrode by a sputtering method or the like.

Subsequently, heat treatment can be performed. For the heat treatment, the conditions for the above heat treatment can be used. Note that the heat treatment does not have to be performed in some cases. In this embodiment, the treatment is performed in a nitrogen atmosphere at a temperature of 400° C. for one hour.

The insulating film 270A can be deposited by a sputtering method, a CVD method, an MBE method, a PLD method, an ALD method, or the like. Here, the thickness of the insulating film 270A is preferably larger than that of the insulating film 272A to be deposited in a later step. In that case, when the insulator 272 is formed in the following process, the insulator 270 can remain easily over the conductor 260.

The insulating film 271A can be deposited by a sputtering method, a CVD method, an MBE method, a PLD method, an ALD method, or the like.

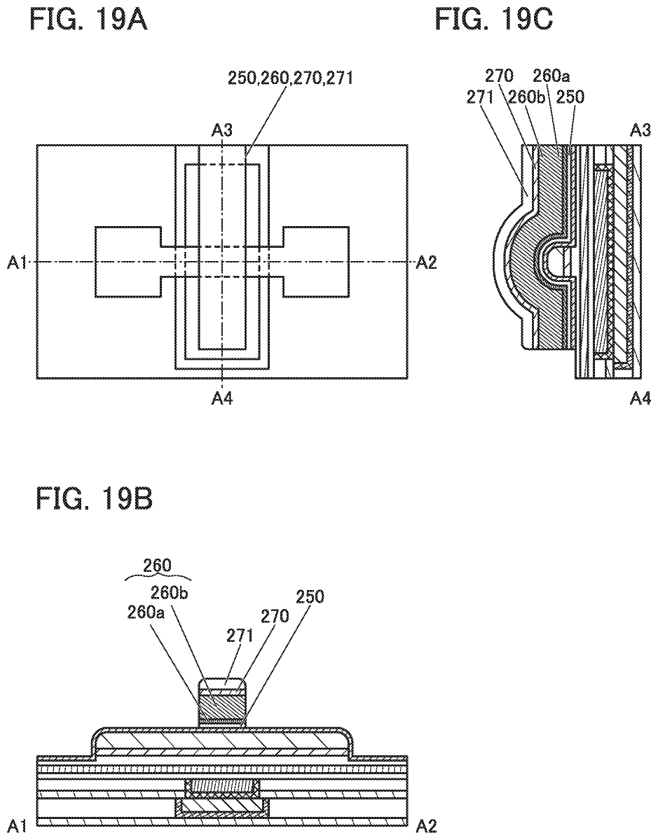

Next, the insulating film 271A is etched to form the insulator 271. Then, using the insulator 271 as an etching mask, the insulating film 250A, the conductive film 260A, the conductive film 260B, and the insulating film 270A are etched to form the insulator 250, the conductor 260 (the conductor 260a and the conductor 260b), and the insulator 270. (see FIG. 19). The insulator 250, the conductor 260a, the conductor 260b, the insulator 270, and the insulator 271 are formed to at least partly overlap with the conductor 205 and the oxide 230.

It is preferable that the side surface of the insulator 250, a side surface of the conductor 260a, a side surface of the conductor 260b, and side surfaces of the insulator 270 and the insulator 271 be substantially on the same surface.

It is preferable that the surface shared by the side surface of the insulator 250, the side surface of the conductor 260a, the side surface of the conductor 260b, and the side surfaces of the insulator 270 and the insulator 271 be substantially perpendicular to the substrate. That is, in a cross section, an angle between the top surface of the oxide 230 and the insulator 250, the conductor 260a, the conductor 260b, the insulator 270, and the insulator 271 is preferably an acute angle and as large as possible. Note that in the cross section, the angle formed by the top surface of the oxide 230 and the side surfaces of the insulator 250, the conductor 260a, the conductor 260b, the insulator 270, and the insulator 271 may be an acute angle. In that case, the angle formed by the top surface of the oxide 230 and the side surfaces of the insulator 250, the conductor 260a, the conductor 260b, the insulator 270, and the insulator 271 is preferably as large as possible.

Note that an upper portion of the oxide 230 in a region not overlapping with the insulator 250 may be etched by the above etching. In that case, the oxide 230 may be thicker in the region overlapping with the insulator 250 than in the region not overlapping with the insulator 250.

Next, the insulating film 272A is deposited to cover the oxide film 230C, the insulator 250, the conductor 260, the insulator 270, and the insulator 271. The insulating film 272A can be deposited by a sputtering method, a CVD method, an MBE method, a PLD method, an ALD method, or the like.

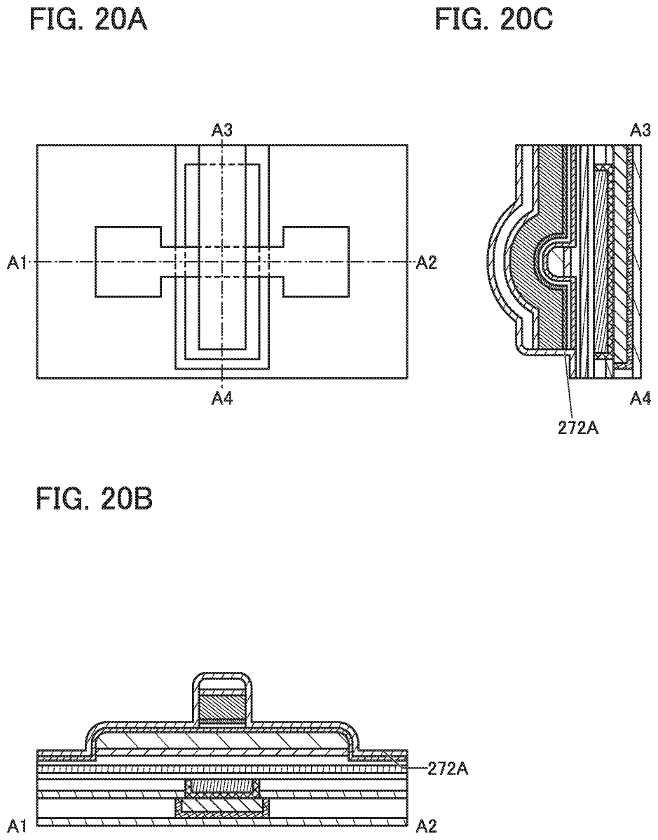

The insulating film 272A may be deposited by an ALD method. When an ALD method is used, the insulating film 272A having good coverage with respect to the side surfaces of the insulator 250, the conductor 260, and the insulator 270 can be deposited (see FIG. 20).

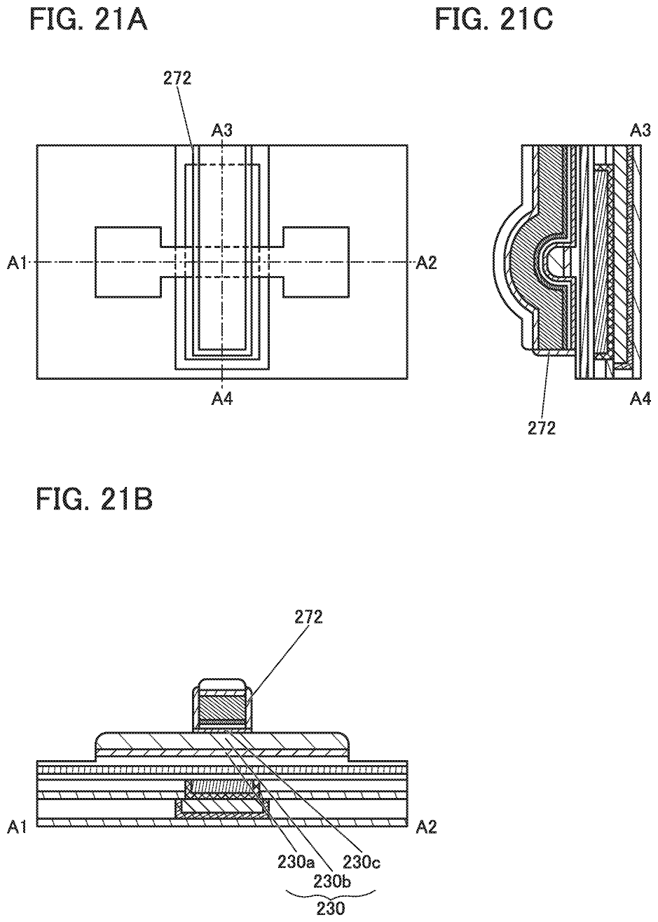

Next, the insulating film 272A is subjected to anisotropic etching treatment to form the insulator 272 in contact with the side surfaces of the insulator 250, the conductor 260, the insulator 270, and the insulator 271. Further, the oxide 230c is formed by processing the oxide film 230C. Dry etching treatment is preferably performed as the anisotropic etching treatment. In this manner, the insulating film 272A deposited on a plane substantially parallel to the substrate surface can be removed, so that the insulator 272 can be formed in a self-aligned manner (see FIG. 21).

Next, the insulating film 274A is deposited to cover the insulator 224, the oxide 230, the insulator 271, and the insulator 272. The insulating film 274A can be deposited by a sputtering method, a CVD method, an MBE method, a PLD method, an ALD method, or the like.

The insulating film 274A is preferably deposited in an atmosphere containing at least one of nitrogen and hydrogen. In the case where the deposition is performed in such an atmosphere, oxygen vacancies are formed mainly in the region of the oxide 230b not overlapping with the insulator 250 and the oxygen vacancies and impurity elements such as nitrogen or hydrogen are bonded to each other, leading to an increase in carrier density. In this manner, the region 231a and the region 231b with reduced resistance can be formed. As the insulating film 274A, for example, silicon nitride or silicon nitride oxide can be used using a CVD method. In this embodiment, silicon nitride oxide is used as the insulating film 274A.

As described above, in the manufacturing method of a semiconductor device described in this embodiment, a source region and a drain region can be formed in a self-aligned manner owing to the deposition of the insulating film 274A, even in a minute transistor whose channel length is approximately 10 nm to 30 nm. Thus, miniaturized or highly integrated semiconductor devices can be manufactured with high yield.

Here, the top surface and side surfaces of the conductor 260 and the side surface of the insulator 250 are covered with the insulator 272 and the insulator 271, whereby impurity elements such as nitrogen or hydrogen can be prevented from entering the conductor 260 and the insulator 250. Thus, impurity elements such as nitrogen or hydrogen can be prevented from entering the region 234 serving as a channel formation region through the 260 and the insulator 250, so that a transistor with good electrical characteristics can be provided.

Plasma treatment may be performed before the insulating film 274A is deposited. The plasma treatment is performed in an atmosphere containing an element that forms the oxygen vacancies or an element bonded to the oxygen vacancies, for example.

Note that a structure in which the region 231a and the region 231b are formed in the oxide 230 only by plasma treatment may be employed.

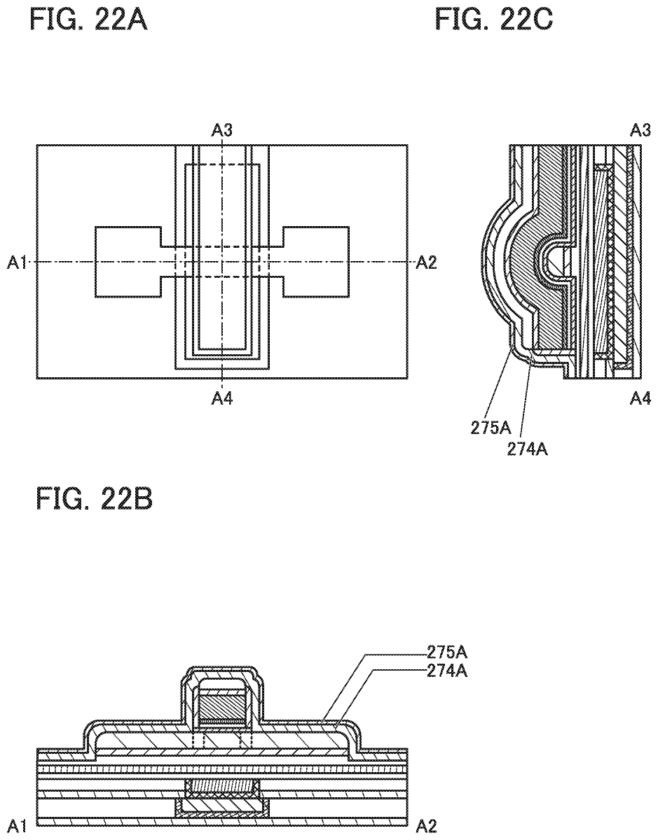

Then, the insulating film 275A is deposited over the insulating film 274A. The insulating film 275A can be deposited by a sputtering method, a CVD method, an MBE method, a PLD method, an ALD method, or the like. In this embodiment, aluminum oxide is deposited by an ALD method. An ALD method enables formation of a film with excellent coverage; accordingly, a film deposited over a region including a step can include a small number of defects such as pinholes and voids (see FIG. 22).

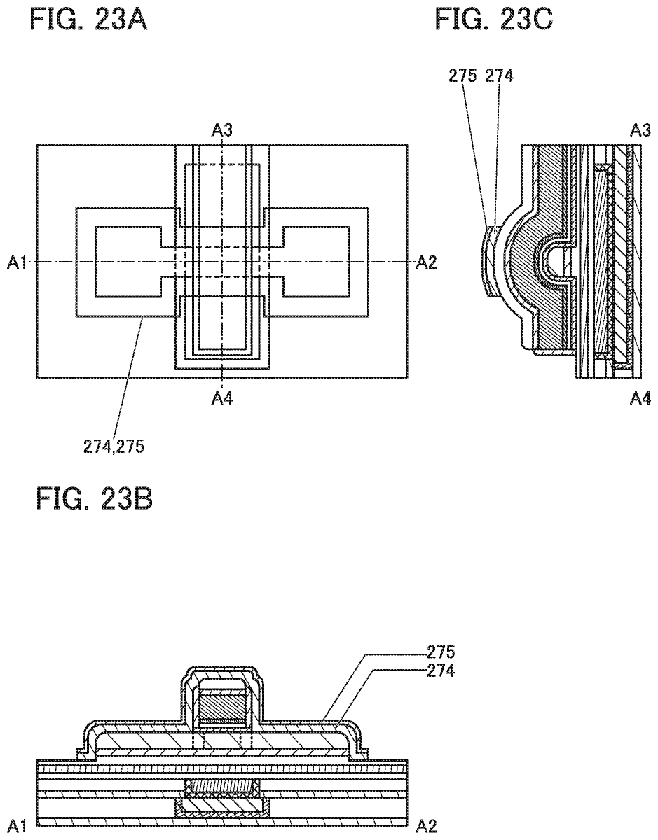

Next, the insulating film 274A and the insulating film 275A are etched by a lithography method, whereby the insulator 274 and the insulator 275 are formed. By the formation of the insulator 274 and the insulator 275, a region where the top surface of the insulator 224 is exposed can be formed (see FIG. 23).

By providing the insulator 275 over the insulator 274 in this manner, oxygen from the outside can be blocked by the insulator 275; accordingly, a decrease in the carrier density of the region 231a and the region 231b can be prevented. Oxygen from the outside passes through the exposed region of the top surface of the insulator 224 and is diffused into the region 234 of the oxide 230 to recover defects in the region 234. Thus, the carrier density of the region 234 can be prevented from increasing.

Examples of the shape seen from the above of the insulator 274 are illustrated in FIGS. 12 to 14; however, the shape is not limited thereto.

Although an example in which the insulator 274 and the insulator 275 are formed by a one-time lithography method is described in this embodiment, the insulator 274 and the insulator 275 may be formed by two-time lithography methods. Specifically, the insulator 274 is formed by a first lithography method, the insulating film 275A is deposited over the insulator 274, and then the insulator 275 is formed by a second lithography method. In that case, by forming the insulator 275 having a shape which covers the insulator 274 when seen from the above, the insulator 275 can be positioned to cover the side surface as well as the top surface of the insulator 274. With such an arrangement, oxygen from the outside can be prevented from entering from the side surface of the insulator 274.

Next, an insulating film to be the insulator 280 is deposited over the insulator 274. The insulating film to be the insulator 280 can be deposited by a sputtering method, a CVD method, an MBE method, a PLD method, an ALD method, or the like. Alternatively, a spin coating method, a dipping method, a droplet discharging method (such as an ink-jet method), a printing method (such as screen printing or offset printing), a doctor knife method, a roll coater method, a curtain coater method, or the like can be used. In this embodiment, silicon oxynitride is used as the insulating film.

Next, the insulating film to be the insulator 280 is partly removed to form the insulator 280. The insulator 280 is preferably formed to have a planar top surface. For example, the top surface of the insulating film to be the insulator 280 may have planarity immediately after the deposition. Alternatively, for example, the insulator 280 may have planarity by removing the insulator and the like from the top surface after the deposition so that the top surface becomes parallel to a reference surface such as a rear surface of the substrate. Such treatment is referred to as planarization treatment. Examples of the planarization treatment include CMP treatment and dry etching treatment. In this embodiment, CMP treatment is used as the planarization treatment. Note that the top surface of the insulator 280 does not necessarily have such planarity.

Next, the insulator 282 is deposited over the insulator 280. The insulator 282 can be deposited by a sputtering method, a CVD method, an MBE method, a PLD method, an ALD method, or the like.

The insulator 282 is preferably deposited by a sputtering method. By using a sputtering method, an excess-oxygen region can be formed easily in the insulator 280 that is in contact with the insulator 282.

Here, during deposition by a sputtering method, ions and sputtered particles exist between a target and a substrate. For example, a potential E₀ is supplied to the target, to which a power source is connected. A potential E₁ such as a ground potential is supplied to the substrate. Note that the substrate may be electrically floating. In addition, there is a region at a potential E₂ between the target and the substrate. The potential relationship is E₂>E₁>E₀.

The ions in plasma are accelerated by a potential difference E₂−E₀ and collide with the target; accordingly, the sputtered particles are ejected from the target. These sputtered particles are attached to a deposition surface and deposited thereover; as a result, a film is formed. Some ions recoil by the target and might, as recoil ions, pass through the formed film and be taken into the insulator 280 in contact with a formation surface. The ions in the plasma are accelerated by a potential difference E₂−E₁ and collide with the deposition surface. Some ions reach the inside of the insulator 280. The ions are taken into the insulator 280; accordingly, a region into which the ions are taken is formed in the insulator 280. That is, an excess-oxygen region is formed in the insulator 280 in the case where the ions include oxygen.

Introduction of excess oxygen into the insulator 280 can form an excess-oxygen region. The excess oxygen in the insulator 280 is supplied to the oxide 230 through the insulator 224 and can fill oxygen vacancies in the oxide 230.

Accordingly, when the deposition in an oxygen gas atmosphere with a sputtering apparatus is performed as means for depositing the insulator 282, oxygen can be introduced into the insulator 280 while the insulator 282 is deposited. When aluminum oxide having a barrier property is used as the insulator 282, for example, excess oxygen introduced into the insulator 280 can be effectively sealed. Alternatively, the insulator 282 may be deposited by depositing aluminum oxide by a sputtering method and then depositing another aluminum oxide over the aluminum oxide by an ALD method, for example. Such a stacked-layer structure allows excess oxygen introduced into the insulator 280 to be effectively sealed (see FIG. 1).

Through the above process, the semiconductor device including the transistor 200 can be manufactured.

According to one embodiment of the present invention, a semiconductor device that can be miniaturized or highly integrated can be provided. According to one embodiment of the present invention, a semiconductor device having good electrical characteristics can be provided. According to one embodiment of the present invention, a semiconductor device with low off-state current can be provided. According to one embodiment of the present invention, a transistor with high on-state current can be provided. According to one embodiment of the present invention, a highly reliable semiconductor device can be provided. According to one embodiment of the present invention, a semiconductor device with reduced power consumption can be provided. According to one embodiment of the present invention, a semiconductor device with high productivity can be provided.

The structures, methods, and the like described above in this embodiment can be used in combination with those described in the other embodiments as appropriate.

### Embodiment 2

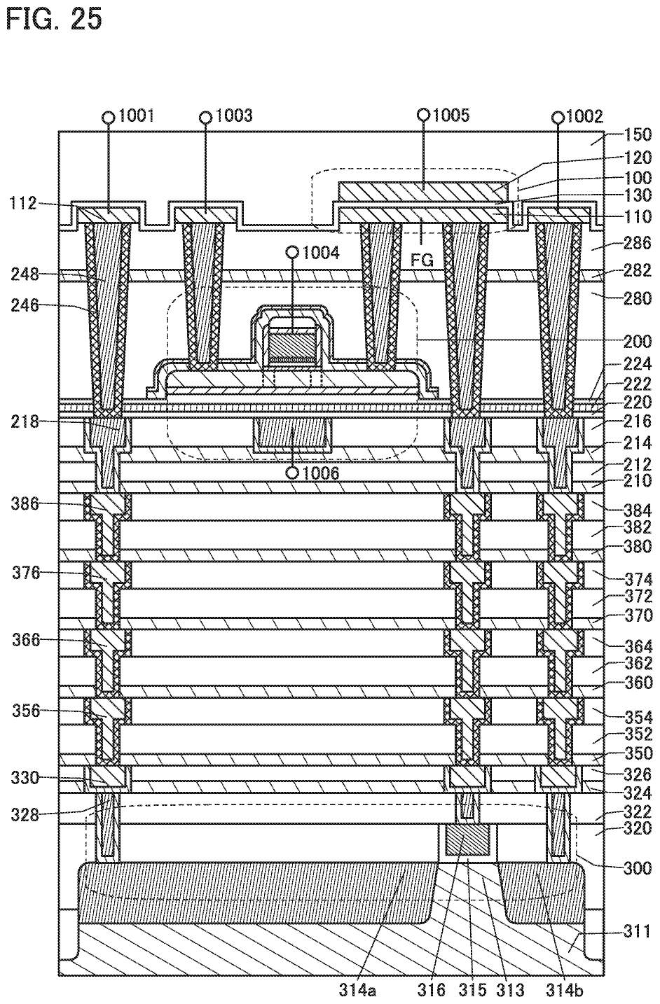

In this embodiment, one embodiment of a semiconductor device will be described with reference to FIG. 25 to FIG. 28.

### <Memory Device 1>

A memory device illustrated in FIG. 25 includes a transistor 300, the transistor 200, and a capacitor 100.

The transistor 200 is a transistor whose channel is formed in a semiconductor layer containing an oxide semiconductor. Since the off-state current of the transistor 200 is low, a memory device including the transistor 200 can retain stored data for a long time. In other words, such a memory device does not require refresh operation or has an extremely low frequency of the refresh operation, which leads to a sufficient reduction in power consumption of the memory device.

In the memory device illustrated in FIG. 25, a wiring 1001 is electrically connected to a source of the transistor 300. A wiring 1002 is electrically connected to a drain of the transistor 300. A wiring 1003 is electrically connected to one of the source and the drain of the transistor 200. A wiring 1004 is electrically connected to a first gate of the transistor 200. A wiring 1006 is electrically connected to a second gate of the transistor 200. A gate of the transistor 300 and the other of the source and the drain of the transistor 200 are electrically connected to one electrode of the capacitor 100. A wiring 1005 is electrically connected to the other electrode of the capacitor 100.

The memory device illustrated in FIG. 25 has a feature that the potential of the gate of the transistor 300 can be retained and thus enables writing, retaining, and reading of data as follows.

Writing and retaining of data are described. First, the potential of the wiring 1004 is set to a potential at which the transistor 200 is brought into a conduction state, so that the transistor 200 is brought into a conduction state. Accordingly, the potential of the wiring 1003 is supplied to a node FG where the gate of the transistor 300 and one electrode of the capacitor 100 are electrically connected to each other. That is, a predetermined charge is supplied to the gate of the transistor 300 (writing). Here, one of two kinds of charges providing different potential levels (hereinafter referred to as a low-level charge and a high-level charge) is supplied. After that, the potential of the wiring 1004 is set to a potential at which the transistor 200 is brought into a non-conduction state, so that the transistor 200 is brought into a non-conduction state. Thus, the charge is retained in the node FG (retaining).

In the case where the off-state current of the transistor 200 is low, the charge of the node FG is retained for a long time.

Next, reading of data is described. An appropriate potential (reading potential) is supplied to the wiring 1005 while a predetermined potential (constant potential) is supplied to the wiring 1001, whereby the potential of the wiring 1002 varies depending on the amount of charge retained in the node FG. This is because in the case of using an n-channel transistor as the transistor 300, an apparent threshold voltage V_{th_H} at the time when a high-level charge is given to the gate of the transistor 300 is lower than an apparent threshold voltage V_{th_L} at the time when a low-level charge is given to the gate of the transistor 300. Here, an apparent threshold voltage refers to the potential of the wiring 1005 which is needed to bring the transistor 300 into a “conduction state”. Thus, the potential of the wiring 1005 is set to a potential V₀ which is between V_{th_H} and V_{th_L}, whereby the charge supplied to the node FG can be determined. For example, in the case where a high-level charge is supplied to the node FG in writing and the potential of the wiring 1005 is V₀ (>V_{th_H}), the transistor 300 is brought into a “conduction state”. Meanwhile, in the case where a low-level charge is supplied to the node FG, the transistor 300 remains in a “non-conduction state” even when the potential of the wiring 1005 is V₀ (<V_{th_L}). Thus, the data retained in the node FG can be read by determining the potential of the wiring 1002.

### <Structure of Memory Device 1>

The memory device of one embodiment of the present invention includes the transistor 300, the transistor 200, and the capacitor 100 as illustrated in FIG. 25. The transistor 200 is provided above the transistor 300, and the capacitor 100 is provided above the transistor 300 and the transistor 200.

The transistor 300 is provided on a substrate 311 and includes a conductor 316, an insulator 315, a semiconductor region 313 that is a part of the substrate 311, and a low-resistance region 314a and a low-resistance region 314b functioning as a source region and a drain region.

The transistor 300 is either a p-channel transistor or an n-channel transistor.

It is preferable that a region of the semiconductor region 313 where a channel is formed, a region in the vicinity thereof, the low-resistance regions 314a and 314b functioning as the source and drain regions, and the like contain a semiconductor such as a silicon-based semiconductor, further preferably single crystal silicon. Alternatively, a material containing Ge (germanium), SiGe (silicon germanium), GaAs (gallium arsenide), GaAlAs (gallium aluminum arsenide), or the like may be contained. Silicon whose effective mass is adjusted by applying stress to the crystal lattice and thereby changing the lattice spacing may be contained. Alternatively, the transistor 300 may be an HEMT (High Electron Mobility Transistor) with GaAs and GaAlAs, or the like.

The low-resistance region 314a and the low-resistance region 314b contain an element which imparts n-type conductivity, such as arsenic or phosphorus, or an element which imparts p-type conductivity, such as boron, in addition to the semiconductor material used for the semiconductor region 313.

The conductor 316 functioning as a gate electrode can be formed using a semiconductor material such as silicon containing the element which imparts n-type conductivity, such as arsenic or phosphorus, or the element which imparts p-type conductivity, such as boron, or using a conductive material such as a metal material, an alloy material, or a metal oxide material.

Note that since the work function of a conductor depends on a material of the conductor, the threshold voltage can be adjusted by changing the material of the conductor. Specifically, it is preferable to use a material such as titanium nitride or tantalum nitride for the conductor. Furthermore, in order to ensure the conductivity and embeddability, it is preferable to use a stacked layer of metal materials such as tungsten and aluminum for the conductor. It is particularly preferable to use tungsten in terms of heat resistance.

Note that the transistor 300 illustrated in FIG. 25 is only an example and the structure is not limited thereto; a transistor appropriate for a circuit configuration or a driving method can be used.

An insulator 320, an insulator 322, an insulator 324, and an insulator 326 are stacked sequentially to cover the transistor 300.

The insulator 320, the insulator 322, the insulator 324, and the insulator 326 can be formed using, for example, silicon oxide, silicon oxynitride, silicon nitride oxide, silicon nitride, aluminum oxide, aluminum oxynitride, aluminum nitride oxide, or aluminum nitride.

The insulator 322 may function as a planarization film for eliminating a level difference caused by the transistor 300 or the like underlying the insulator 322. For example, the top surface of the insulator 322 may be planarized by planarization treatment using a chemical mechanical polishing (CMP) method or the like to improve planarity.

The insulator 324 is preferably formed using a film having a barrier property that prevents hydrogen or impurities from the substrate 311, the transistor 300, or the like from diffusing to a region where the transistor 200 is provided.

For the film having a barrier property against hydrogen, silicon nitride formed by a CVD method can be used, for example. The diffusion of hydrogen to a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which a small amount of hydrogen is released.

The amount of released hydrogen can be measured by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm², in the TDS analysis at a film surface temperature of 50° C. to 500° C., for example.

Note that the relative permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 or less times that of the insulator 324, further preferably 0.6 or less times that of the insulator 324. In the case where a material with a low relative permittivity is used for an interlayer film, the parasitic capacitance between wirings can be reduced.

A conductor 328, a conductor 330, and the like that are electrically connected to the capacitor 100 or the transistor 200 are embedded in the insulator 320, the insulator 322, the insulator 324, and the insulator 326. Note that the conductor 328 and the conductor 330 function as a plug or a wiring. A plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and another part of the conductor functions as a plug.

As a material for each of plugs and wirings (e.g., the conductor 328 and the conductor 330), a single layer or a stacked layer of a conductive material such as a metal material, an alloy material, a metal nitride material, or a metal oxide material can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, in FIG. 25, an insulator 350, an insulator 352, and an insulator 354 are stacked sequentially. Furthermore, a conductor 356 is formed in the insulator 350, the insulator 352, and the insulator 354. The conductor 356 functions as a plug or a wiring. Note that the conductor 356 can be provided using a material similar to those for the conductor 328 and the conductor 330.

Note that the insulator 350 is preferably formed using an insulator having a barrier property against hydrogen, as with the insulator 324, for example. Furthermore, the conductor 356 preferably contains a conductor having a barrier property against hydrogen. In particular, the conductor having a barrier property against hydrogen is formed in an opening portion of the insulator 350 having a barrier property against hydrogen. In such a structure, the transistor 300 and the transistor 200 can be separated by a barrier layer, so that the diffusion of hydrogen from the transistor 300 to the transistor 200 can be prevented.

Note that as the conductor having a barrier property against hydrogen, tantalum nitride is preferably used, for example. The use of a stack including tantalum nitride and tungsten having high conductivity can inhibit the diffusion of hydrogen from the transistor 300 while the conductivity of a wiring is ensured. In that case, the tantalum nitride layer having a barrier property against hydrogen preferably has a structure in which the tantalum nitride layer is in contact with the insulator 350 having a barrier property against hydrogen.

A wiring layer may be provided over the insulator 354 and the conductor 356. For example, in FIG. 25, an insulator 360, an insulator 362, and an insulator 364 are stacked sequentially. Furthermore, a conductor 366 is formed in the insulator 360, the insulator 362, and the insulator 364. The conductor 366 functions as a plug or a wiring. Note that the conductor 366 can be provided using a material similar to those for the conductor 328 and the conductor 330.

Note that for example, as the insulator 360, an insulator having a barrier property against hydrogen is preferably used, like the insulator 324. Furthermore, the conductor 366 preferably contains a conductor having a barrier property against hydrogen. In particular, the conductor having a barrier property against hydrogen is formed in an opening portion of the insulator 360 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 364 and the conductor 366. For example, in FIG. 25, an insulator 370, an insulator 372, and an insulator 374 are stacked sequentially. Furthermore, a conductor 376 is formed in the insulator 370, the insulator 372, and the insulator 374. The conductor 376 functions as a plug or a wiring. Note that the conductor 376 can be formed using a material similar to those for the conductor 328 and the conductor 330.

Note that the insulator 370 is preferably formed using an insulator having a barrier property against hydrogen, as with the insulator 324, for example. Furthermore, the conductor 376 preferably contains a conductor having a barrier property against hydrogen. In particular, the conductor having a barrier property against hydrogen is formed in an opening portion of the insulator 370 having a barrier property against hydrogen. In such a structure, the transistor 300 and the transistor 200 can be separated by a barrier layer, so that the diffusion of hydrogen from the transistor 300 to the transistor 200 can be prevented.

A wiring layer may be provided over the insulator 374 and the conductor 376. For example, in FIG. 25, an insulator 380, an insulator 382, and an insulator 384 are stacked sequentially. Furthermore, a conductor 386 is formed in the insulator 380, the insulator 382, and the insulator 384. The conductor 386 functions as a plug or a wiring. Note that the conductor 386 can be formed using a material similar to those for the conductor 328 and the conductor 330.

Note that the insulator 380 is preferably formed using an insulator having a barrier property against hydrogen, as with the insulator 324, for example. Furthermore, the conductor 386 preferably contains a conductor having a barrier property against hydrogen. In particular, the conductor having a barrier property against hydrogen is formed in an opening portion of the insulator 380 having a barrier property against hydrogen. In such a structure, the transistor 300 and the transistor 200 can be separated by a barrier layer, so that the diffusion of hydrogen from the transistor 300 to the transistor 200 can be prevented.

The insulator 210, the insulator 212, the insulator 214, and the insulator 216 are stacked sequentially over the insulator 384. A substance having a barrier property against oxygen or hydrogen is preferably used for one of the insulators 210, 212, 214, and 216.

For example, the insulator 210 and the insulator 214 are preferably formed using a film having a barrier property that prevents hydrogen or impurities from diffusing from the substrate 311, a region where the transistor 300 is provided, or the like to a region where the transistor 200 is provided. Therefore, a material similar to that for the insulator 324 can be used.

For the film having a barrier property against hydrogen, silicon nitride formed by a CVD method can be used, for example. The diffusion of hydrogen to a semiconductor element including an oxide semiconductor, such as the transistor 200, degrades the characteristics of the semiconductor element in some cases. Therefore, a film that prevents hydrogen diffusion is preferably provided between the transistor 200 and the transistor 300. The film that prevents hydrogen diffusion is specifically a film from which a small amount of hydrogen is released.

For the film having a barrier property against hydrogen used for the insulator 210 and the insulator 214, for example, a metal oxide such as aluminum oxide, hafnium oxide, or tantalum oxide is preferably used.

In particular, aluminum oxide has an excellent blocking effect that prevents permeation of both oxygen and impurities such as hydrogen and moisture which cause a change in electrical characteristics of the transistor. Accordingly, the use of aluminum oxide can prevent the entry of impurities such as hydrogen and moisture into the transistor 200 during and after a manufacturing process of the transistor. In addition, release of oxygen from the oxide contained in the transistor 200 can be prevented. Therefore, aluminum oxide is suitably used for a protective film of the transistor 200.

The insulator 212 and the insulator 216 can be formed using a material similar to that for the insulator 320, for example. In the case where a material with a relatively low relative permittivity is used for an interlayer film, the parasitic capacitance between wirings can be reduced. A silicon oxide film, a silicon oxynitride film, or the like can be used for the insulator 212 and the insulator 216, for example.

A conductor 218, a conductor (the conductor 205) included in the transistor 200, and the like are embedded in the insulator 210, the insulator 212, the insulator 214, and the insulator 216. Note that the conductor 218 functions as a plug or a wiring that is electrically connected to the capacitor 100 or the transistor 300. The conductor 218 can be provided using a material similar to those for the conductor 328 and the conductor 330.

In particular, part of the conductor 218 that is in contact with the insulator 210 and the insulator 214 is preferably a conductor having a barrier property against oxygen, hydrogen, and water. In such a structure, the transistor 300 and the transistor 200 can be separated by a layer having a barrier property against oxygen, hydrogen, and water. As a result, the diffusion of hydrogen from the transistor 300 to the transistor 200 can be prevented.

The transistor 200 is provided over the insulator 216. Note that the structure of the transistor of the semiconductor device described in the above embodiment can be used as the structure of the transistor 200. Note that the transistor 200 in FIG. 25 is only an example and the structure of the transistor 200 is not limited to that illustrated in FIG. 25; a transistor appropriate for a circuit configuration or a driving method can be used.

The insulator 280 is provided over the transistor 200.

An insulator 282 is provided over the insulator 280. A substance having a barrier property against oxygen or hydrogen is preferably used for the insulator 282. Thus, the insulator 282 can be formed using a material similar to that used for forming the insulator 214. For the insulator 282, a metal oxide such as aluminum oxide, hafnium oxide, or tantalum oxide is preferably used, for example.

In particular, aluminum oxide has an excellent blocking effect that prevents permeation of both oxygen and impurities such as hydrogen and moisture which cause a change in electrical characteristics of the transistor. Accordingly, the use of aluminum oxide can prevent the entry of impurities such as hydrogen and moisture into the transistor 200 in and after a manufacturing process of the transistor. In addition, release of oxygen from the oxide contained in the transistor 200 can be prevented. Therefore, aluminum oxide is suitably used for a protective film of the transistor 200.

An insulator 286 is provided over the insulator 282. The insulator 286 can be formed using a material similar to that used for forming the insulator 320. In the case where a material with a relatively low relative permittivity is used for an interlayer film, the parasitic capacitance between wirings can be reduced. For example, a silicon oxide film, a silicon oxynitride film, or the like can be used for the insulator 286.

A conductor 246, a conductor 248, and the like are embedded in the insulator 220, the insulator 222, the insulator 224, the insulator 280, the insulator 282, and the insulator 286.

The conductor 246 and the conductor 248 function as plugs or wirings that are electrically connected to the capacitor 100, the transistor 200, or the transistor 300. The conductor 246 and the conductor 248 can be provided using a material similar to those of the conductor 328 and the conductor 330.

In addition, the capacitor 100 is provided above the transistor 200. The capacitor 100 includes a conductor 110, a conductor 120, and an insulator 130.

A conductor 112 may be provided over the conductor 246 and the conductor 248. The conductor 112 functions as a plug or a wiring that is electrically connected to the capacitor 100, the transistor 200, or the transistor 300. The conductor 110 functions as the electrode of the capacitor 100. The conductor 112 and the conductor 110 can be formed at the same time.

The conductor 112 and the conductor 110 can be formed using a metal film containing an element selected from molybdenum, titanium, tantalum, tungsten, aluminum, copper, chromium, neodymium, and scandium; a metal nitride film containing any of the above elements as its component (a tantalum nitride film, a titanium nitride film, a molybdenum nitride film, or a tungsten nitride film); or the like. Alternatively, it is possible to use a conductive material such as an indium tin oxide, an indium oxide containing tungsten oxide, an indium zinc oxide containing tungsten oxide, an indium oxide containing titanium oxide, an indium tin oxide containing titanium oxide, an indium zinc oxide, or an indium tin oxide to which silicon oxide is added.

The conductor 112 and the conductor 110 each have a single-layer structure in FIG. 25; however, the structure is not limited thereto, and a stacked-layer structure of two or more layers may be used. For example, between a conductor having a barrier property and a conductor having high conductivity, a conductor which is highly adhesive to the conductor having a barrier property and the conductor having high conductivity may be formed.

As a dielectric of the capacitor 100, the insulator 130 is provided over the conductor 112 and the conductor 110. The insulator 130 can be provided to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

A material with high dielectric strength, such as silicon oxynitride, is preferably used for the insulator 130, for example. In the capacitor 100 having such a structure, the dielectric strength can be increased and the electrostatic breakdown of the capacitor 100 can be prevented because of the insulator 130.

Over the insulator 130, the conductor 120 is provided so as to overlap with the conductor 110. Note that the conductor 120 can be formed using a conductive material such as a metal material, an alloy material, or a metal oxide material. It is preferable to use a high-melting-point material which has both heat resistance and conductivity, such as tungsten or molybdenum, and it is particularly preferable to use tungsten. In the case where the conductor 120 is formed concurrently with another component such as a conductor, Cu (copper), Al (aluminum), or the like which is a low-resistance metal material can be used.

An insulator 150 is provided over the conductor 120 and the insulator 130. The insulator 150 can be provided using a material similar to that of the insulator 320. The insulator 150 may function as a planarization film that covers an uneven shape thereunder.

With the use of the structure, a change in electrical characteristics can be prevented and reliability can be improved in a semiconductor device including a transistor including an oxide semiconductor. A transistor including an oxide semiconductor with a high on-state current can be provided. A transistor including an oxide semiconductor with a low off-state current can be provided. A semiconductor device with low power consumption can be provided.

### <Memory Device 2>

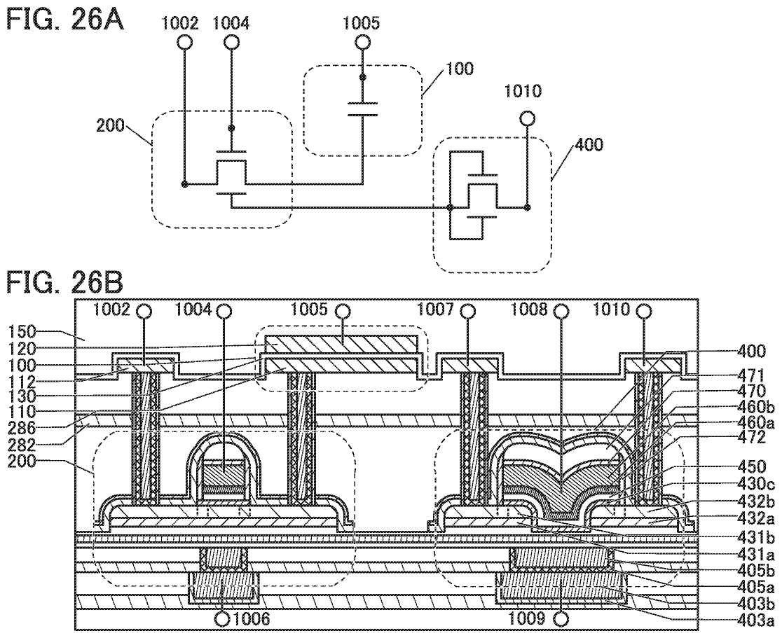

A semiconductor device illustrated in FIG. 26 is a memory device including a transistor 400, the transistor 200, and the capacitor 100. One embodiment of the memory device is described below with reference to FIG. 26.

FIG. 26(A) is a circuit diagram showing an example of the connection relationship of the transistor 200, the transistor 400, and the capacitor 100 in the semiconductor device described in this embodiment. FIG. 26(B) is a cross-sectional view of the semiconductor device in which the wirings 1004 to 1010 and the like correspond to those in FIG. 26(A).

As illustrated in FIG. 26, in the transistor 200, the gate is electrically connected to the wiring 1004, one of the source and the drain is electrically connected to the wiring 1002, and the other of the source and the drain is electrically connected to one electrode of the capacitor 100. The other electrode of the capacitor 100 is electrically connected to the wiring 1005. A drain of the transistor 400 is electrically connected to the wiring 1010. As illustrated in FIG. 26(B), the second gate of the transistor 200 and a source, a first gate, and a second gate of the transistor 400 are electrically connected through the wiring 1006, the wiring 1007, the wiring 1008, and the wiring 1009.

The on/off state of the transistor 200 can be controlled by application of a potential to the wiring 1004. When the transistor 200 is in an on state to apply a potential to the wiring 1002, charges can be supplied to the capacitor 100 through the transistor 200. At this time, by making the transistor 200 in an off state, the charges supplied to the capacitor 100 can be held. By application of a given potential to the wiring 1005, the potential of a connection portion between the transistor 200 and the capacitor 100 can be controlled by capacitive coupling. For example, when a ground potential is applied to the wiring 1005, the charges are held easily. Furthermore, by application of a negative potential to the wiring 1010, the negative potential is applied to the second gate of the transistor 200 through the transistor 400, whereby the threshold voltage of the transistor 200 can be higher than 0 V, the off-state current can be reduced, and the drain current when the voltage applied to the first gate is 0 V can be noticeably reduced.

With a structure in which the first gate and the second gate of the transistor 400 are diode-connected to the source, and a source of the transistor 400 and the second gate of the transistor 200 are connected, the voltage applied to the second gate of the transistor 200 can be controlled by the wiring 1010. When the negative potential of the second gate of the transistor 200 is held, the voltage between the first gate and the source of the transistor 400 and the voltage between the second gate and the source of the transistor 400 are each 0 V. Since the drain current of the transistor 400 when the voltage applied to the first gate is 0 V is extremely small and the threshold voltage of the transistor 400 is higher than that of the transistor 200, the structure allows the negative potential of the second gate of the transistor 200 to be held for a long time without supply of power to the transistor 400.

Moreover, the negative potential of the second gate of the transistor 200 is held, in which case the drain current of the transistor 200 when the voltage applied to the first gate is 0 V can be noticeably reduced even without supply of power to the transistor 200. In other words, the charges can be held in the capacitor 100 for a long time even without supply of power to the transistor 200 and the transistor 400. For example, with the use of the semiconductor device as a memory element, memory can be retained for a long time without power supply. Therefore, a memory device with a low refresh frequency or a memory device that does not need refresh operation can be provided.

Note that the connection relationship of the transistor 200, the transistor 400, and the capacitor 100 is not limited to that illustrated in FIGS. 26(A) and 26(B). The connection relationship can be modified as appropriate in accordance with a necessary circuit configuration.

### <Structure of Memory Device 2>

FIG. 26(B) is a cross-sectional view of a memory device including the capacitor 100, the transistor 200, and the transistor 400. Note that in the memory device illustrated in FIG. 26, components having the same functions as the components in the semiconductor device and the memory device described in the above embodiment and <Structure of memory device 1> are denoted by the same reference numerals.

The memory device of one embodiment of the present invention includes the transistor 200, the transistor 400, and the capacitor 100 as illustrated in FIG. 26. The transistor 200 and the transistor 400 are provided in the same layer, and the capacitor 100 is provided above the transistor 200 and the transistor 400.

Note that the capacitor and the transistor included in the semiconductor device and the memory device described in the above embodiment and with reference to FIG. 25 can be used as the transistor 200. Note that the capacitor 100, the transistor 200, and the transistor 400 illustrated in FIG. 26 are only examples and the structures of those are not limited to the structures illustrated in FIG. 26; a transistor appropriate for a circuit configuration or a driving method can be used.

The transistor 400 and the transistor 200 are formed in the same layer and thus can be fabricated in parallel. The transistor 400 includes a conductor 460 (a conductor 460a and a conductor 460b) functioning as a first gate electrode, a conductor 405 (a conductor 405a and a conductor 405b) functioning as a second gate electrode, insulators 470 and 472 in contact with the conductor 460, an insulator 450 functioning as gate insulating layer, an oxide 430c including a region where a channel is formed, oxides 431a and 431b functioning as one of a source and a drain, and oxides 432a and 432b functioning as the other of the source and the drain. The conductor 405 functioning as a second gate electrode is electrically connected to a conductor 403 (a conductor 403a and a conductor 403b) functioning as a wiring.

In the transistor 400, the conductor 405 is in the same layer as the conductor 205. The oxides 431a and 432a are in the same layer as the oxide 230a, and the oxides 431b and 432b are in the same layer as the oxide 230b. The oxide 430c is in the same layer as the oxide 230c. The insulator 450 is in the same layer as the insulator 250. The conductor 460 is in the same layer as the conductor 260. The insulator 470 is in the same layer as the insulator 270. The insulator 472 is in the same layer as the insulator 272.

In the oxide 430c functioning as an active layer of the transistor 400, oxygen vacancies and impurities such as water or hydrogen are reduced, as in the oxide 230 or the like. Accordingly, the threshold voltage of the transistor 400 can be higher than 0 V, the off-state current can be reduced, and the drain current when the voltage applied to the second gate electrode and the voltage applied to the first gate electrode are 0 V can be extremely low.

With the use of the structure, a change in electrical characteristics can be prevented and reliability can be improved in a semiconductor device including a transistor including an oxide semiconductor. The power consumption of a semiconductor device including a transistor including an oxide semiconductor can be reduced. A semiconductor device including a transistor including an oxide semiconductor can be miniaturized or highly integrated. A miniaturized or highly integrated semiconductor device can be provided with high productivity.

### <Memory Device 3>

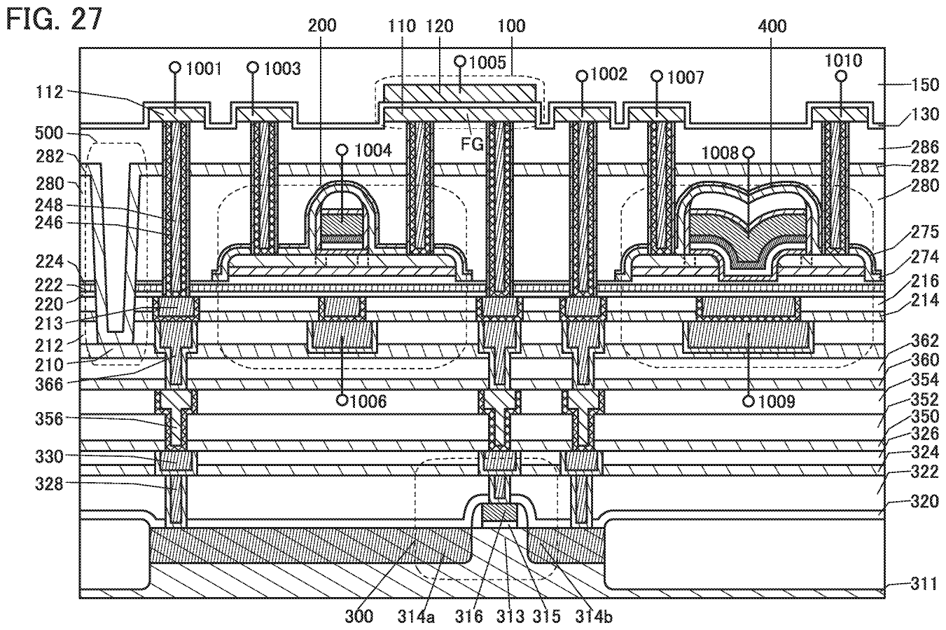

A semiconductor device illustrated in FIG. 27 is a memory device including the transistor 300, the transistor 200, the transistor 400, and the capacitor 100. One embodiment of the memory device is described below with reference to FIG. 27.

The transistor 200 is a transistor in which a channel is formed in a semiconductor layer containing an oxide semiconductor, and can be the transistor described in the above embodiment.

Since the transistor described in the above embodiment can be formed with high yield even when it is miniaturized, the transistor 200 can be miniaturized. The use of such a transistor in a memory device allows miniaturization or high integration of the memory device. Since the off-state current of the transistor described in the above embodiment is low, a memory device including the transistor can retain stored data for a long time. In other words, such a memory device does not require refresh operation or has an extremely low frequency of the refresh operation, which leads to a sufficient reduction in power consumption of the memory device.

In FIG. 27, the wiring 1001 is electrically connected to a source of the transistor 300. The wiring 1002 is electrically connected to a drain of the transistor 300. The wiring 1003 is electrically connected to one of a source and a drain of the transistor 200. The wiring 1004 is electrically connected to the first gate of the transistor 200. The wiring 1006 is electrically connected to the second gate of the transistor 200. A gate of the transistor 300 and the other of the source and the drain of the transistor 200 are electrically connected to one electrode of the capacitor 100. The wiring 1005 is electrically connected to the other electrode of the capacitor 100.

The wiring 1007 is electrically connected to the source of the transistor 400. The wiring 1008 is electrically connected to a first gate of the transistor 400, the wiring 1009 is electrically connected to a second gate of the transistor 400, and the wiring 1010 is electrically connected to the drain of the transistor 400. The wiring 1006, the wiring 1007, the wiring 1008, and the wiring 1009 are electrically connected to each other.

The semiconductor device illustrated in FIG. 27 has a feature that the potential of the gate of the transistor 300 can be retained and thus enables writing, retaining, and reading of data as follows. The description of the memory device 1 illustrated in FIG. 25 can be referred to for the writing and retaining of data in the semiconductor device illustrated in FIG. 27.

### <Structure of Memory Device 3>

FIG. 27 is a cross-sectional view of a memory device including the capacitor 100, the transistor 200, the transistor 300, and the transistor 400. Note that in the memory device illustrated in FIG. 27, components having the same functions as the components in the semiconductor device and the memory device described in the above embodiment, <Structure of memory device 1>, and <Structure of memory device 2> are denoted by the same reference numerals.

The memory device of one embodiment of the present invention includes the transistor 300, the transistor 200, the transistor 400, and the capacitor 100 as illustrated in FIG. 27. The transistor 200 and the transistor 400 are provided above the transistor 300, and the capacitor 100 is provided above the transistor 300, the transistor 200, and the transistor 400.

Note that the capacitor and the transistor included in the semiconductor device and the memory device described in the above embodiment and with reference to FIG. 25 to FIG. 26 can be used as the capacitor 100, the transistor 200, the transistor 300, and the transistor 400. Note that the capacitor 100, the transistor 300, the transistor 200, and the transistor 400 illustrated in FIG. 27 are only examples and the structures of those are not limited to the structures illustrated in FIG. 27; a transistor appropriate for a circuit configuration or a driving method can be used.

With the use of the structure, a change in electrical characteristics can be prevented and reliability can be improved in a semiconductor device including a transistor including an oxide semiconductor. The power consumption of a semiconductor device including a transistor including an oxide semiconductor can be reduced. A semiconductor device including a transistor including an oxide semiconductor can be miniaturized or highly integrated. A miniaturized or highly integrated semiconductor device can be provided with high productivity.

### <Structure of Memory Cell Array>

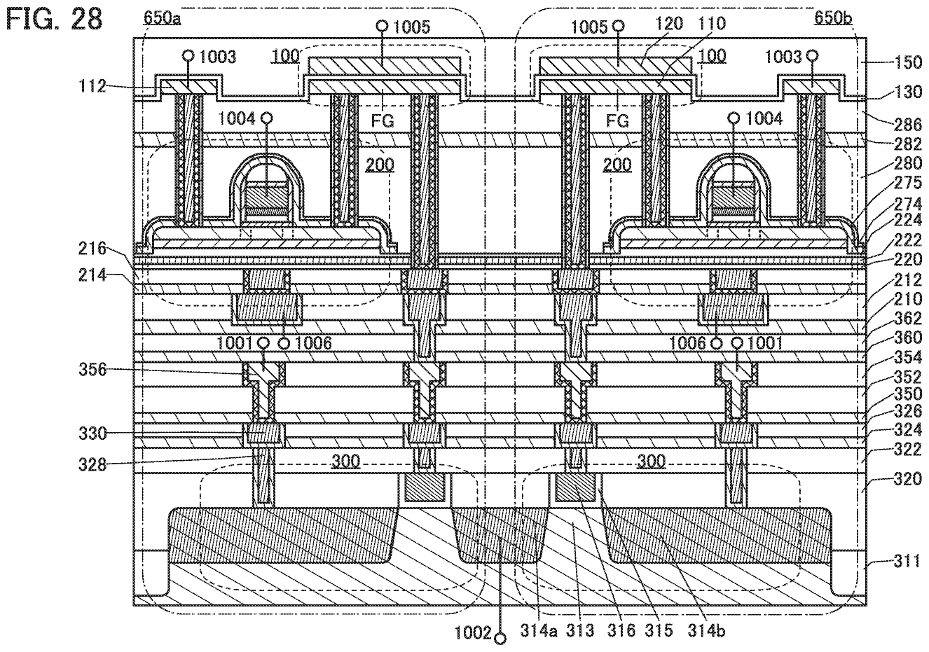

FIG. 28 illustrates an example of a memory cell array of this embodiment. When the transistors 200 are arranged as memory cells in a matrix, a memory cell array can be formed.

The memory device illustrated in FIG. 28 is a semiconductor device constituting a memory cell array in which the memory devices illustrated in FIG. 25 and FIG. 27 are arranged in a matrix. Note that one transistor 400 can control the back-gate voltages of the plurality of transistors 200. For this reason, the number of provided transistors 400 is preferably smaller than the number of transistors 200.

Accordingly, in FIG. 28, the transistor 400 illustrated in FIG. 27 is omitted. FIG. 28 is a cross-sectional view that illustrates part of a row in which the memory devices illustrated in FIG. 25 and FIG. 27 are arranged in a matrix.

The structure of the transistor 300 in FIG. 28 is different from that of the transistor 300 in FIG. 27. In the transistor 300 illustrated in FIG. 28, the semiconductor region 313 (part of the substrate 311) in which the channel is formed has a protruding shape. Furthermore, the conductor 316 is provided so as to cover the top and side surfaces of the semiconductor region 313 with the insulator 315 positioned therebetween. Note that the conductor 316 may be formed using a material for adjusting the work function. The transistor 300 is also referred to as FIN-type transistors because they each utilize a protruding portion of the semiconductor substrate. An insulator functioning as a mask for forming the protruding portion may be provided in contact with the top portion of the protruding portion. Although the case where the protruding portion is formed by processing part of the semiconductor substrate is described here, a semiconductor film having a protruding shape may be formed by processing an SOI substrate.

In the memory device illustrated in FIG. 28, a memory cell 650a and a memory cell 650b are arranged adjacent to each other. The transistor 300, the transistor 200, and the capacitor 100 are included and electrically connected to the wiring 1001, the wiring 1002, the wiring 1003, the wiring 1004, the wiring 1005, and the wiring 1006 in the memory cell 650a and the memory cell 650b. Also in the memory cells 650a and 650b, a node where a gate of the transistor 300 and one electrode of the capacitor 100 are electrically connected to each other is referred to as the node FG. Note that the wiring 1002 is shared by the memory cell 650a and the memory cell 650b adjacent to each other.

Note that in the case where memory cells are arranged in an array, data of a desired memory cell needs to be read at the time of reading. For example, in the case where a memory cell array has a NOR-type structure, only data of a desired memory cell can be read by bringing the transistors 300 of memory cells from which data is not read into a non-conduction state. In that case, a potential at which the transistor 300 is brought into a “non-conduction state” regardless of the charge supplied to the node FG, that is, a potential lower than V_{th_H} is supplied to the wiring 1005 connected to the memory cells from which data is not read. Alternatively, in the case where a memory cell array has a NAND-type structure, for example, only data of a desired memory cell can be read by bringing the transistors 300 of memory cells from which data is not read into a conduction state. In that case, a potential at which the transistor 300 is brought into a “conduction state” regardless of the charge supplied to the node FG, that is, a potential higher than V_{th_L} is supplied to the wiring 1005 connected to the memory cells from which data is not read.

With the use of the structure, a change in electrical characteristics can be prevented and reliability can be improved in a semiconductor device including a transistor including an oxide semiconductor. The power consumption of a semiconductor device including a transistor including an oxide semiconductor can be reduced. A semiconductor device including a transistor including an oxide semiconductor can be miniaturized or highly integrated. A miniaturized or highly integrated semiconductor device can be provided with high productivity.

As described above, the compositions, structures, methods, and the like described in this embodiment can be combined with any of the compositions, structures, methods, and the like described in the other embodiments as appropriate.

### Embodiment 3

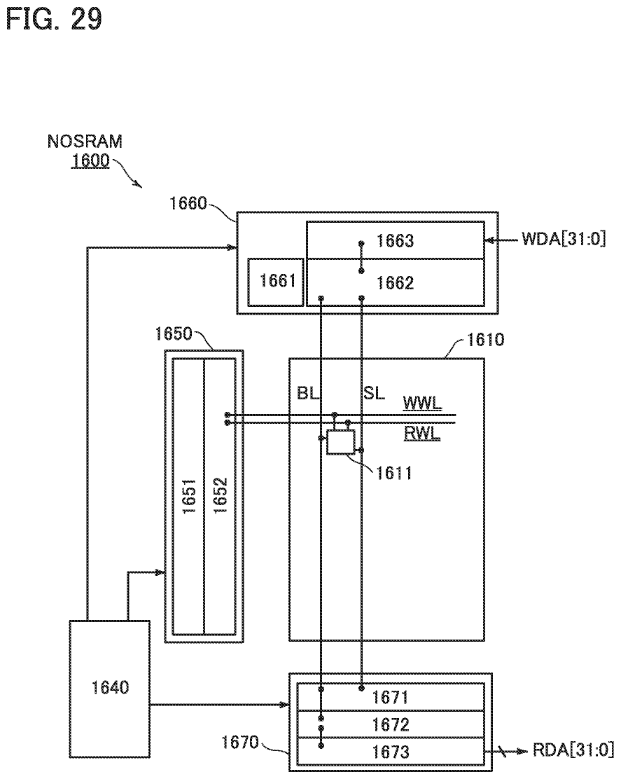

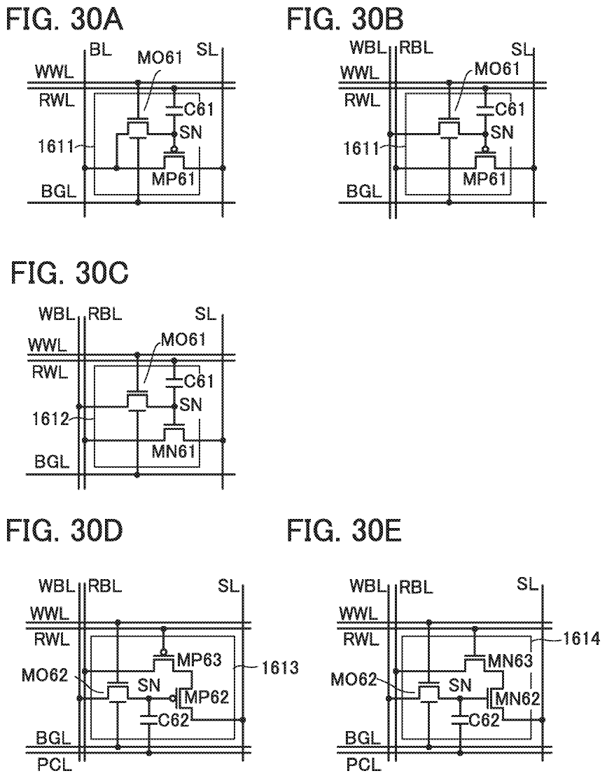

In this embodiment, a NOSRAM is described as an example of a memory device of one embodiment of the present invention, which includes a capacitor and a transistor using an oxide as a semiconductor (hereinafter referred to as an OS transistor) with reference to FIG. 29 and FIG. 30. A NOSRAM (registered trademark) is an abbreviation of “Nonvolatile Oxide Semiconductor RAM”, which indicates RAM including a gain cell (2T or 3T) memory cell. Note that hereinafter, a memory device using an OS transistor, such as the NOSRAM, is referred to as an OS memory in some cases.

A memory device in which OS transistors are used in memory cells (hereinafter referred to as an “OS memory”) is used in the NOSRAM. The OS memory is a memory including at least a capacitor and an OS transistor that controls charging and discharging of the capacitor. Since the OS transistor is a transistor with an extremely low off-state current, the OS memory has excellent retention characteristics and thus can function as a nonvolatile memory.

### <<NOSRAM>>

FIG. 29 shows a configuration example of the NOSRAM. A NOSRAM 1600 shown in FIG. 29 includes a memory cell array 1610, a controller 1640, a row driver 1650, a column driver 1660, and an output driver 1670. Note that the NOSRAM 1600 is a multilevel NOSRAM in which one memory cell stores multilevel data.

The memory cell array 1610 includes a plurality of memory cells 1611, a plurality of word lines WWL and RWL, a bit line BL, and a source line SL. The word line WWL is a write word line, and the word line RWL is a read word line. In the NOSRAM 1600, one memory cell 1611 stores 3-bit (8-level) data.

The controller 1640 controls the NOSRAM 1600 as a whole and writes data WDA[31:0] and reads out data RDA[31:0]. The controller 1640 processes command signals from the outside (e.g., a chip enable signal and a write enable signal) to generate control signals for the row driver 1650, the column driver 1660, and the output driver 1670.

The row driver 1650 has a function of selecting a row to be accessed. The row driver 1650 includes a row decoder 1651 and a word line driver 1652.

The column driver 1660 drives the source line SL and the bit line BL. The column driver 1660 includes a column decoder 1661, a write driver 1662, and a DAC (digital-analog converter circuit) 1663.

The DAC 1663 converts 3-bit digital data into an analog voltage. The DAC 1663 converts 32-bit data WDA[31:0] into an analog voltage per 3 bits.

The write driver 1662 has a function of precharging the source line SL, a function of bringing the source line SL into an electrically floating state, a function of selecting the source line SL, a function of inputting a writing voltage generated by the DAC 1663 to the selected source line SL, a function of precharging the bit line BL, a function of bringing the bit line BL into an electrically floating state, and the like.

The output driver 1670 includes a selector 1671, an ADC (analog-digital converter circuit) 1672, and an output buffer 1673. The selector 1671 selects the source line SL to be accessed and transmits a voltage of the selected source line SL to the ADC 1672. The ADC 1672 has a function of converting an analog voltage into 3-bit digital data. The voltage of the source line SL is converted into 3-bit data in the ADC 1672, and the output buffer 1673 retains the data output from the ADC 1672.

### <Memory Cell>

FIG. 30(A) is a circuit diagram showing a configuration example of the memory cell 1611. The memory cell 1611 is a 2T gain cell, and the memory cell 1611 is electrically connected to the word lines WWL and RWL, the bit line BL, the source line SL, and a wiring BGL. The memory cell 1611 includes a node SN, an OS transistor MO61, a transistor MP61, and a capacitor C61. The OS transistor MO61 is a write transistor. The transistor MP61 is a read transistor and is formed using a p-channel Si transistor, for example. The capacitor C61 is a storage capacitor for retaining the voltage of the node SN. The node SN is a data retaining node and corresponds to a gate of the transistor MP61 here.

The write transistor of the memory cell 1611 is formed using the OS transistor MO61; thus, the NOSRAM 1600 can retain data for a long time.

In the example of FIG. 30(A), a write bit line and a read bit line are a common bit line; however, as shown in FIG. 30(B), a write bit line WBL and a read bit line RBL may be provided.

FIG. 30(C) to FIG. 30(E) show other configuration examples of the memory cell. FIG. 30(C) to FIG. 30(E) show examples where the write bit line and the read bit line are provided; however, as shown in FIG. 30(A), a bit line shared in writing and reading may be provided.

A memory cell 1612 shown in FIG. 30(C) is a modification example of the memory cell 1611 where the read transistor is changed into an n-channel transistor (MN61). The transistor MN61 may be an OS transistor or a Si transistor.

In the memory cells 1611 and 1612, the OS transistor MO61 may be an OS transistor with no back gate.

A memory cell 1613 shown in FIG. 30(D) is a 3T gain cell and is electrically connected to the word lines WWL and RWL, the bit lines WBL and RBL, the source line SL, the wiring BGL, and a wiring PCL. The memory cell 1613 includes the node SN, an OS transistor MO62, a transistor MP62, a transistor MP63, and a capacitor C62. The OS transistor MO62 is a write transistor. The transistor MP62 is a read transistor and the transistor MP63 is a selection transistor.

The memory cell 1614 shown in FIG. 30(E) is a modification example of the memory cell 1613 where the read transistor and the selection transistor are changed into n-channel transistors (MN62 and MN63). Each of the transistors MN62 and MN63 may be an OS transistor or a Si transistor.

The OS transistors provided in the memory cells 1611 to 1614 may each be a transistor with no back gate or a transistor with a back gate.

There is theoretically no limitation on the number of rewriting operations of the NOSRAM 1600 because data is rewritten by charging and discharging of the capacitors C61 and C62, and data can be written and read with low energy. Furthermore, since data can be retained for a long time, the refresh rate can be reduced.

In the case where the semiconductor device described in any of the above embodiments is used for the memory cells 1611, 1612, 1613, and 1614, the transistor 200 can be used as the OS transistors MO61 and MO62, the capacitor 100 can be used as the capacitors C61 and C62, and the transistor 300 can be used as the transistors MP61 and MN62.

This embodiment can be implemented in appropriate combination with the structures described in the other embodiments and the like.

### Embodiment 4

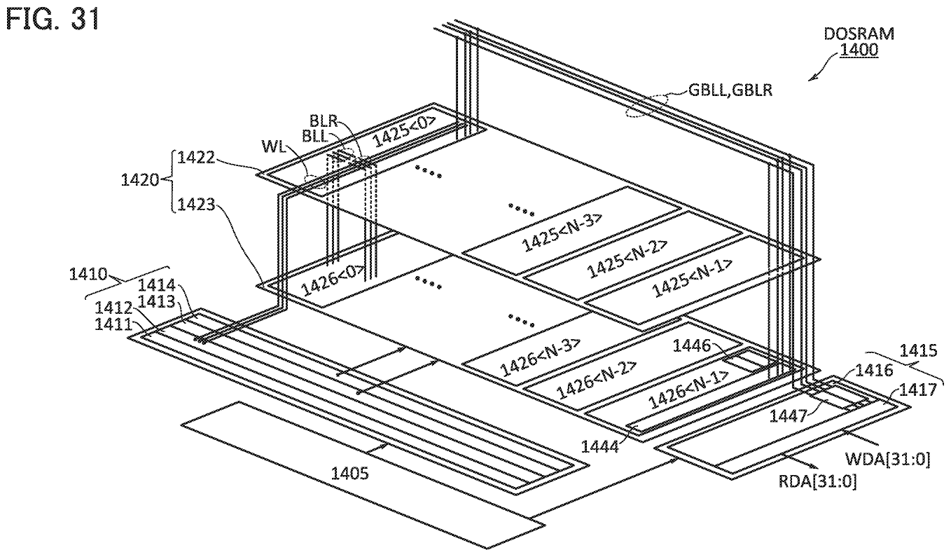

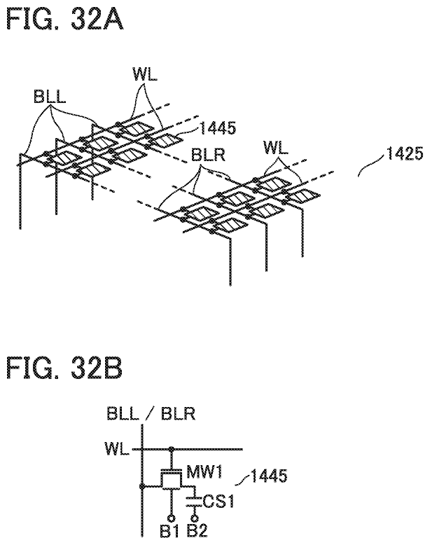

In this embodiment, a DOSRAM is described as another example of the memory device of one embodiment of the present invention, which includes an OS transistor and a capacitor, with reference to FIG. 31 and FIG. 32. A DOSRAM (registered trademark) is an abbreviation of “Dynamic Oxide Semiconductor RAM,” which is a RAM including a 1T (transistor) 1C (capacitor) memory cell. As in the NOSRAM, an OS memory is used in the DOSRAM.

### <<DOSRAM 1400>>

FIG. 31 shows a configuration example of a DOSRAM. As shown in FIG. 31, a DOSRAM 1400 includes a controller 1405, a row circuit 1410, a column circuit 1415, and a memory cell and sense amplifier array 1420 (hereinafter referred to as an “MC-SA array 1420”).

The row circuit 1410 includes a decoder 1411, a word line driver circuit 1412, a column selector 1413, and a sense amplifier driver circuit 1414. The column circuit 1415 includes a global sense amplifier array 1416 and an input/output circuit 1417. The global sense amplifier array 1416 includes a plurality of global sense amplifiers 1447. The MC-SA array 1420 includes a memory cell array 1422, a sense amplifier array 1423, and global bit lines GBLL and GBLR.

### (MC-SA Array 1420)

The MC-SA array 1420 has a stacked-layer structure where the memory cell array 1422 is stacked over the sense amplifier array 1423. The global bit lines GBLL and GBLR are stacked over the memory cell array 1422. The DOSRAM 1400 adopts, as the bit-line structure, a hierarchical bit line structure hierarchized with local bit lines and global bit lines.

The memory cell array 1422 includes N local memory cell arrays 1425<0> to 1425<N−1> (N is an integer greater than or equal to 2). FIG. 32(A) shows a configuration example of the local memory cell array 1425. The local memory cell array 1425 includes a plurality of memory cells 1445, a plurality of word lines WL, and a plurality of bit lines BLL and BLR. In the example of FIG. 32(A), the local memory cell array 1425 has an open bit-line architecture but may have a folded bit-line architecture.

FIG. 32(B) shows a circuit configuration example of the memory cell 1445. The memory cell 1445 includes a transistor MW1, a capacitor CS1, terminals B1 and B2. The transistor MW1 has a function of controlling charging and discharging of the capacitor CS1. A gate of the transistor MW1 is electrically connected to the word line, a first terminal of the transistor MW1 is electrically connected to the bit line, and a second terminal of the transistor MW1 is electrically connected to a first terminal of the capacitor CS1. A second terminal of the capacitor CS1 is electrically connected to the terminal B2. A constant voltage (e.g., a low power supply voltage) is input to the terminal B2.

In the case where the semiconductor device described in any of the above embodiments is used in the memory cell 1445, the transistor 200 can be used as the transistor MW1, and the capacitor 100 can be used as the capacitor CS1.

The transistor MW1 includes a back gate, and the back gate is electrically connected to the terminal B1. This makes it possible to change the threshold voltage of the transistor MW1 with a voltage of the terminal B1. For example, the voltage of the terminal B1 may be a fixed voltage (e.g., a negative constant voltage), or the voltage of the terminal B1 may be changed in response to the operation of the DOSRAM 1400.

The back gate of the transistor MW1 may be electrically connected to the gate, the first terminal, or the second terminal of the transistor MW1. Alternatively, the back gate is not necessarily provided in the transistor MW1.

The sense amplifier array 1423 includes N local sense amplifier arrays 1426<0> to 1426<N−1>. The local sense amplifier array 1426 includes one switch array 1444 and a plurality of sense amplifiers 1446. A bit line pair is electrically connected to the sense amplifier 1446. The sense amplifier 1446 has a function of precharging the bit line pair, a function of amplifying a voltage difference between the bit line pair, and a function of retaining the voltage difference. The switch array 1444 has a function of selecting a bit line pair and bringing the selected bit line pair and a global bit line pair into a conduction state.

Here, the bit line pair refers to two bit lines which are compared by the sense amplifier at the same time. The global bit line pair refers to two global bit lines which are compared by the global sense amplifier at the same time. The bit line pair can be referred to as a pair of bit lines, and the global bit line pair can be referred to as a pair of global bit lines. Here, the bit line BLL and the bit line BLR form one bit line pair. The global bit line GBLL and the global bit line GBLR form one global bit line pair. In the following description, the expressions “bit line pair (BLL, BLR)” and “global bit line pair (GBLL, GBLR)” are also used.

### (Controller 1405)

The controller 1405 has a function of controlling the overall operation of the DOSRAM 1400. The controller 1405 has a function of performing logic operation on a command signal that is input from the outside and determining an operation mode, a function of generating control signals for the row circuit 1410 and the column circuit 1415 so that the determined operation mode is executed, a function of retaining an address signal that is input from the outside, and a function of generating an internal address signal.

### (Row Circuit 1410)

The row circuit 1410 has a function of driving the MC-SA array 1420. The decoder 1411 has a function of decoding an address signal. The word line driver circuit 1412 generates a selection signal for selecting the word line WL of a target row that is to be accessed.

The column selector 1413 and the sense amplifier driver circuit 1414 are circuits for driving the sense amplifier array 1423. The column selector 1413 has a function of generating a selection signal for selecting the bit line of a target column that is to be accessed. With the selection signal from the column selector 1413, the switch array 1444 of each local sense amplifier array 1426 is controlled. With the control signal from the sense amplifier driver circuit 1414, the plurality of local sense amplifier arrays 1426 are independently driven.

### (Column Circuit 1415)

The column circuit 1415 has a function of controlling the input of data signals WDA[31:0], and a function of controlling the output of data signals RDA[31:0]. The data signals WDA[31:0] are write data signals, and the data signals RDA[31:0] are read data signals.

The global sense amplifier 1447 is electrically connected to the global bit line pair (GBLL, GBLR). The global sense amplifier 1447 has a function of amplifying a voltage difference between the global bit line pair (GBLL, GBLR), and a function of retaining the voltage difference. Data is written to and read from the global bit line pair (GBLL, GBLR) by the input/output circuit 1417.

The write operation of the DOSRAM 1400 is briefly described. Data is written to the global bit line pair by the input/output circuit 1417. The data of the global bit line pair is retained by the global sense amplifier array 1416. By the switch array 1444 of the local sense amplifier array 1426 specified by an address signal, the data of the global bit line pair is written to the bit line pair of a target column. The local sense amplifier array 1426 amplifies the written data and retains the amplified data. In the specified local memory cell array 1425, the word line WL of a target row is selected by the row circuit 1410, and the data retained at the local sense amplifier array 1426 is written to the memory cell 1445 of the selected row.

The read operation of the DOSRAM 1400 is briefly described. One row of the local memory cell array 1425 is specified by an address signal. In the specified local memory cell array 1425, the word line WL of a target row is in a selected state, and data of the memory cell 1445 is written to the bit line. The local sense amplifier array 1426 detects a voltage difference between the bit line pair of each column as data, and retains the data. Among the data retained at the local sense amplifier array 1426, the data of a column specified by the address signal is written to the global bit line pair by the switch array 1444. The global sense amplifier array 1416 detects and retains the data of the global bit line pair. The data retained at the global sense amplifier array 1416 is output to the input/output circuit 1417. Thus, the read operation is completed.

There is theoretically no limitation on the number of rewriting operations of the DOSRAM 1400 because data is rewritten by charging and discharging of the capacitor CS1; and data can be written and read with low energy. In addition, the memory cell 1445 has a simple circuit configuration, and thus the capacity can be easily increased.

The transistor MW1 is an OS transistor. The extremely low off-state current of the OS transistor can inhibit charge leakage from the capacitor CS1. Therefore, the retention time of the DOSRAM 1400 is much longer than that of a DRAM. This allows less frequent refresh, which can reduce power needed for refresh operations. Thus, the DOSRAM 1400 is suitable for a memory device that rewrites a large volume of data with a high frequency, for example, a frame memory used for image processing.

Since the MC-SA array 1420 has a stacked-layer structure, the bit line can be shortened to a length that is close to the length of the local sense amplifier array 1426. A shorter bit line results in smaller bit line capacitance, which can reduce the storage capacitance of the memory cell 1445. In addition, providing the switch array 1444 in the local sense amplifier array 1426 can reduce the number of long bit lines. For the reasons described above, a driving load during access to the DOSRAM 1400 is reduced, enabling a reduction in power consumption.

This embodiment can be implemented in appropriate combination with the structures described in the other embodiments and the like.

### Embodiment 5

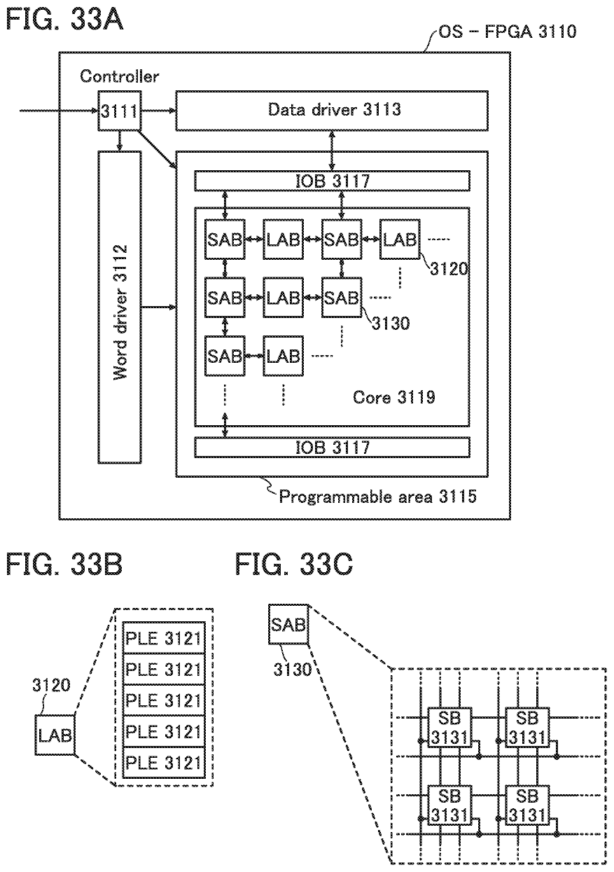

In this embodiment, an FPGA (field-programmable gate array) is described as an example of a semiconductor device of one embodiment of the present invention in which an OS transistor and a capacitor are used, with reference to FIG. 33 to FIG. 36. In the FPGA of this embodiment, an OS memory is used for a configuration memory and a register. Here, such an FPGA is referred to as an “OS-FPGA”.

### <<OS-FPGA>>

FIG. 33(A) illustrates a configuration example of an OS-FPGA. An OS-FPGA 3110 illustrated in FIG. 33(A) is capable of NOFF (normally-off) computing that executes context switching by a multi-context configuration and fine-grained power gating in each PLE. The OS-FPGA 3110 includes a controller 3111, a word driver 3112, a data driver 3113, and a programmable area 3115.

The programmable area 3115 includes two input/output blocks (IOBs) 3117 and a core 3119. The IOB 3117 includes a plurality of programmable input/output circuits. The core 3119 includes a plurality of logic array blocks (LABs) 3120 and a plurality of switch array blocks (SABs) 3130. The LAB 3120 includes a plurality of PLEs 3121. FIG. 33(B) illustrates an example in which the LAB 3120 includes five PLEs 3121. As illustrated in FIG. 33(C), the SAB 3130 includes a plurality of switch blocks (SBs) 3131 arranged in an array. The LAB 3120 is connected to the LABs 3120 in four directions (on the left, right, top, and bottom sides) through its input terminals and the SABs 3130.

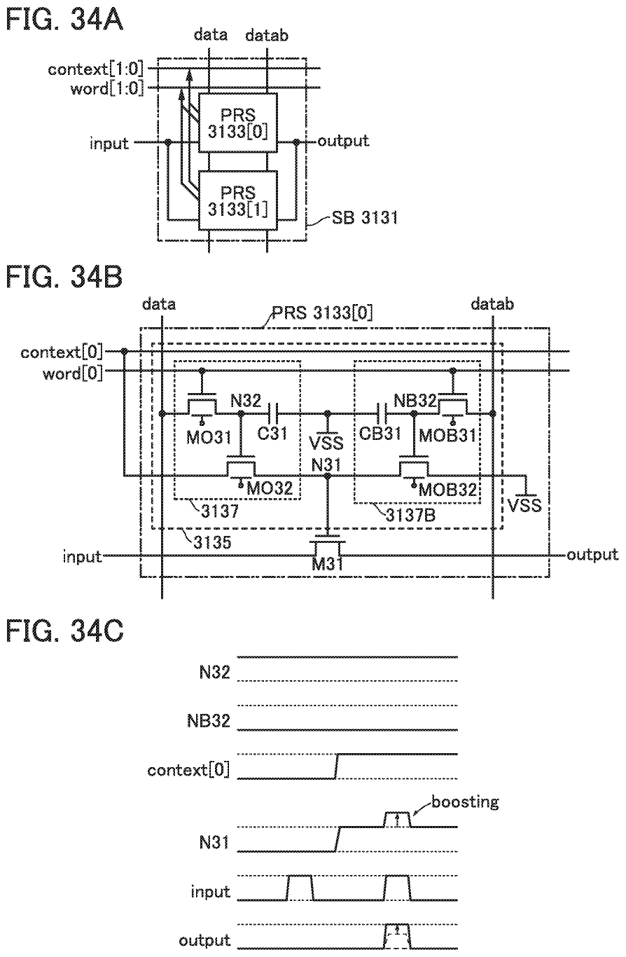

The SB 3131 is described with reference to FIG. 34(A) to FIG. 34(C). To the SB 3131 illustrated in FIG. 34(A), data, datab, signals context[1:0], and signals word[1:0] are input. The data and the datab are configuration data, and the logics of the data and the datab have a complementary relationship. The number of contexts in the OS-FPGA 3110 is two, and the signals context[1:0] are context selection signals. The signals word[1:0] are word line selection signals, and wirings to which the signals word[1:0] are input are each a word line.

The SB 3131 includes PRSs (programmable routing switches) 3133[0] and 3133[1]. The PRSs 3133[0] and 3133[1] each include a configuration memory (CM) that can store complementary data. Note that in the case where the PRS 3133[0] and the PRS 3133[1] are not distinguished from each other, they are each referred to as a PRS 3133. The same applies to other elements.

FIG. 34(B) illustrates a circuit configuration example of the PRS 3133[0]. The PRS 3133[0] and the PRS 3133[1] have the same circuit configuration. Different context selection signals and different word line selection signals are input to the PRS 3133[0] and the PRS 3133[1]. The signals context[0] and word[0] are input to the PRS 3133[0], and the signals context[1] and word[1] are input to the PRS 3133[1]. For example, in the SB 3131, when the signal context[0] becomes “H”, the PRS 3133[0] is activated.

The PRS 3133[0] includes a CM 3135 and a Si transistor M31. The Si transistor M31 is a pass transistor that is controlled by the CM 3135. The CM 3135 includes memory circuits 3137 and 3137B. The memory circuits 3137 and 3137B have the same circuit configuration. The memory circuit 3137 includes a capacitor C31 and OS transistors MO31 and MO32. The memory circuit 3137B includes a capacitor CB31 and OS transistors MOB31 and MOB32.

In the case where the semiconductor device described in any of the above embodiments is used in the SAB 3130, the transistor 200 can be used as the OS transistors MO31 and MOB31, and the capacitor 100 can be used as the capacitors C31 and CB31.

The OS transistors MO31, MO32, MOB31, and MOB32 include a back gate, and each of these back gates are electrically connected to a power supply line that supplies a fixed voltage.

A gate of the Si transistor M31, a gate of the OS transistor MO32, and a gate of the OS transistor MOB32 correspond to a node N31, a node N32, and a node NB32, respectively. The nodes N32 and NB32 are each a charge retention node of the CM 3135. The OS transistor MO32 controls the conduction state between the node N31 and a signal line for the signal context[0]. The OS transistor MOB32 controls the conduction state between the node N31 and a low-potential power supply line VSS.

Logics of data retained at the memory circuits 3137 and 3137B have a complementary relationship. Thus, either the OS transistor MO32 or the OS transistor MOB32 is turned on.

The operation example of the PRS 3133[0] is described with reference to FIG. 34(C). In the PRS 3133[0], to which configuration data has already been written, the node N32 is at “H”, whereas the node NB32 is at “L”.

The PRS 3133[0] is inactive while the signal context[0] is at “L”. During this period, even when an input terminal (input) of the PRS 3133[0] is transferred to “H”, the gate of the Si transistor M31 is kept at “L” and an output terminal (output) of the PRS 3133[0] is also kept at “L”.

The PRS 3133[0] is active while the signal context[0] is at “H”. When the signal context[0] is transferred to “H”, the gate of the Si transistor M31 is transferred to “H” by the configuration data stored in the CM 3135.

While the PRS 3133[0] is active, when the input terminal is transferred to “H”, the gate voltage of the Si transistor M31 is increased by boosting because the OS transistor MO32 of the memory circuit 3137 is a source follower. As a result, the OS transistor MO32 of the memory circuit 3137 loses the driving capability, and the gate of the Si transistor M31 is brought into a floating state.

In the PRS 3133 with a multi-context function, the CM 3135 also has a function of a multiplexer.

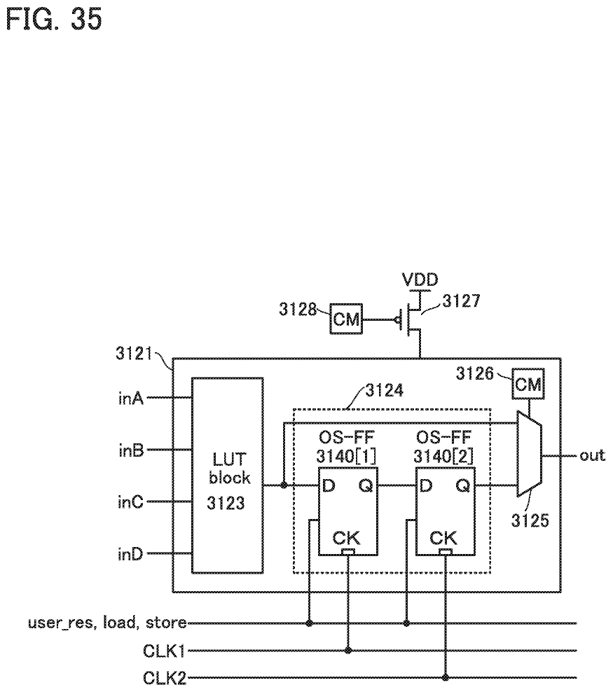

FIG. 35 illustrates a configuration example of the PLE 3121. The PLE 3121 includes a lookup table block (LUT block) 3123, a register block 3124, a selector 3125, and a CM 3126. The LUT block 3123 is configured to select and output data in the LUT block in accordance with inputs inA, inB, inC, and inD. The selector 3125 selects an output of the LUT block 3123 or an output of the register block 3124 in accordance with the configuration data stored in the CM 3126.

The PLE 3121 is electrically connected to a power supply line for a voltage VDD through a power switch 3127. Whether the power switch 3127 is turned on or off is determined in accordance with the configuration data stored in a CM 3128. Providing the power switch 3127 for each PLE 3121 enables fine-grained power gating. The PLE 3121 that is not used after context switching can be power gated owing to the fine-grained power gating function; thus, standby power can be effectively reduced.

The register block 3124 is formed by nonvolatile registers to achieve NOFF computing. The nonvolatile registers in the PLE 3121 are each a flip-flop provided with an OS memory (hereinafter referred to as an [OS-FF]).

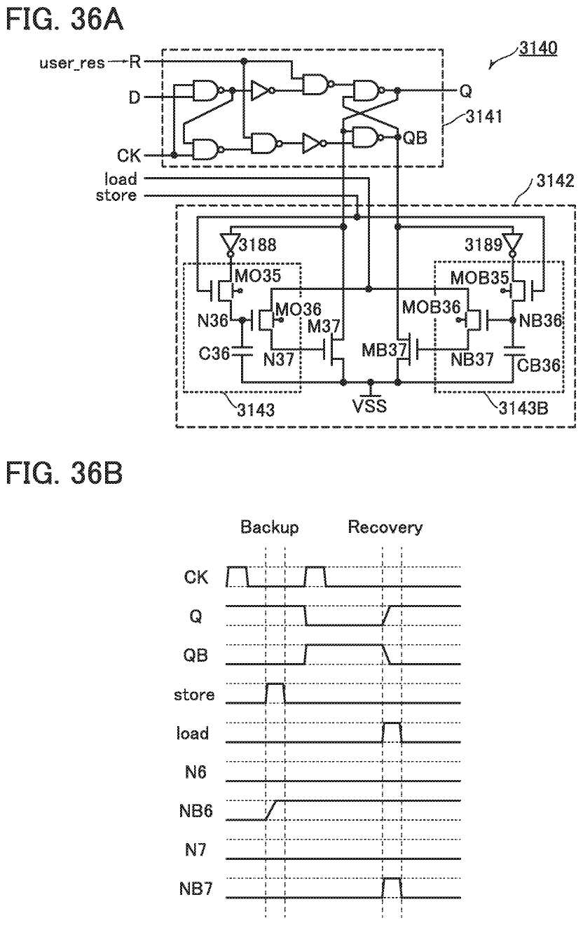

The register block 3124 includes OS-FFs 3140[1] and 3140[2]. Signals user_res, load, and store are input to the OS-FFs 3140[1] and 3140[2]. A clock signal CLK1 is input to the OS-FF 3140[1] and a clock signal CLK2 is input to the OS-FF 3140[2]. FIG. 36(A) illustrates a configuration example of the OS-FF 3140.

The OS-FF 3140 includes an FF 3141 and a shadow register 3142. The FF 3141 includes nodes CK, R, D, Q, and QB. A clock signal is input to the node CK. The signal user_res is input to the node R. The signal user_res is a reset signal. The node D is a data input node, and the node Q is a data output node. The logics of the node Q and the node QB have a complementary relationship.

The shadow register 3142 functions as a backup circuit of the FF 3141. The shadow register 3142 backs up data of the nodes Q and QB in accordance with the signal store and writes back the backed up data to the nodes Q and QB in accordance with the signal load.

The shadow register 3142 includes inverter circuits 3188 and 3189, Si transistors M37 and MB37, and memory circuits 3143 and 3143B. The memory circuits 3143 and 3143B have the same circuit configuration as the memory circuit 3137 of the PRS 3133. The memory circuit 3143 includes a capacitor C36 and OS transistors MO35 and MO36. The memory circuit 3143B includes a capacitor CB36 and OS transistors MOB35 and MOB36. Nodes N36 and NB36 correspond to gates of the OS transistors MO36 and MOB36, and are each a charge retention node. Nodes N37 and NB37 correspond to gates of the Si transistors M37 and MB37.

In the case where the semiconductor device described in any of the above embodiments is used in the LAB 3120, the transistor 200 can be used as the OS transistors MO35 and MOB35, and the capacitor 100 can be used as the capacitors C36 and CB36.

The OS transistors MO35, MO36, MOB35, and MOB36 each include a back gate, and each of these back gates is electrically connected to a power supply line that supplies a fixed voltage.

An example of an operation method of the OS-FF 3140 is described with reference to FIG. 36(B).

### (Backup)

When the signal store at “H” is input to the OS-FF 3140, the shadow register 3142 backs up the data of the FF 3141. The node N36 becomes “L” when the data of the node Q is written thereto, and the node NB36 becomes “H” when the data of the node QB is written thereto. After that, power gating is performed and the power switch 3127 is turned off. Although the data of the nodes Q and QB of the FF 3141 are lost, the shadow register 3142 retains the backed up data even when power is off

### (Recovery)

The power switch 3127 is turned on to supply power to the PLE 3121. After that, when the signal load at “H” is input to the OS-FF 3140, the shadow register 3142 writes back the backed up data to the FF 3141. The node N37 is kept at “L” because the node N36 is at “L”, and the node NB37 becomes “H” because the node NB36 is at “H”. Thus, the node Q becomes “H” and the node QB becomes “L”. That is, the OS-FF 3140 returns to a state at the backup operation.

A combination of the fine-grained power gating and backup/recovery operation of the OS-FF 3140 allows power consumption of the OS-FPGA 3110 to be effectively reduced.

As an error that might occur in a memory circuit, a soft error due to the entry of radiation is given. The soft error is a phenomenon in which a malfunction such as inversion of data stored in a memory is caused by electron-hole pair generation when a transistor is irradiated with a rays emitted from a material of a memory or a package or the like, secondary cosmic ray neutrons generated by nuclear reaction of primary cosmic rays entering the Earth's atmosphere from outer space with nuclei of atoms existing in the atmosphere, or the like. An OS memory using an OS transistor has a high soft-error tolerance. Therefore, the OS-FPGA 3110 with high reliability can be provided when an OS memory is included therein.

This embodiment can be implemented in appropriate combination with the structures described in the other embodiments and the like.

### Embodiment 6

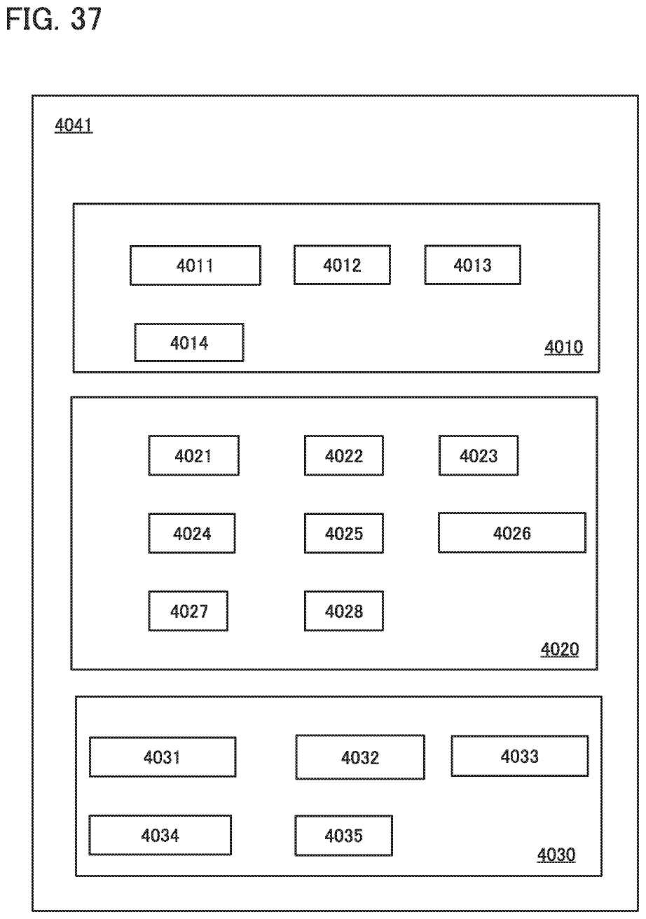

In this embodiment, an AI system in which the semiconductor device of any of the above embodiments is used is described with reference to FIG. 37.

FIG. 37 is a block diagram illustrating a structure example of an AI system 4041. The AI system 4041 includes an arithmetic portion 4010, a control portion 4020, and an input/output portion 4030.

The arithmetic portion 4010 includes an analog arithmetic circuit 4011, a DOSRAM 4012, a NOSRAM 4013, and an FPGA 4014. The DOSRAM 1400, the NOSRAM 1600, and the OS-FPGA 3110 described in the above embodiments can be used as the DOSRAM 4012, the NOSRAM 4013, and the FPGA 4014, respectively.

The control portion 4020 includes a CPU (Central Processing Unit) 4021, a GPU (Graphics Processing Unit) 4022, a PLL (Phase Locked Loop) 4023, an SRAM (Static Random Access Memory) 4024, a PROM (Programmable Read Only Memory) 4025, a memory controller 4026, a power supply circuit 4027, and a PMU (Power Management Unit) 4028.

The input/output portion 4030 includes an external memory control circuit 4031, an audio codec 4032, a video codec 4033, a general-purpose input/output module 4034, and a communication module 4035.

The arithmetic portion 4010 can execute learning or inference by a neural network.

The analog arithmetic circuit 4011 includes an A/D (analog/digital) converter circuit, a D/A (digital/analog) converter circuit, and a product-sum operation circuit.

The analog arithmetic circuit 4011 is preferably formed using an OS transistor. The analog arithmetic circuit 4011 using an OS transistor includes an analog memory and can execute a product-sum operation necessary for the learning or inference with low power consumption.

The DOSRAM 4012 is a DRAM formed using an OS transistor, and is a memory that temporarily stores digital data sent from the CPU 4021. The DOSRAM 4012 includes a memory cell including an OS transistor and a read circuit portion including a Si transistor. Because the memory cell and the read circuit portion can be provided in different layers that are stacked, the entire circuit area of the DOSRAM 4012 can be small.

In the calculation with the neural network, the number of input data exceeds 1000 in some cases. In the case where the input data are stored in an SRAM, the input data have to be stored piece by piece because of the circuit area limitation and small storage capacity of the SRAM. The DOSRAM 4012 has a larger storage capacity than an SRAM because the memory cells can be highly integrated even in a limited circuit area. Therefore, the DOSRAM 4012 can efficiently store the input data.

The NOSRAM 4013 is a nonvolatile memory using an OS transistor. The NOSRAM 4013 consumes less power in writing data than the other nonvolatile memories such as a flash memory, a ReRAM (Resistive Random Access Memory), and an MRAM (Magnetoresistive Random Access Memory). Furthermore, unlike a flash memory and a ReRAM in which elements deteriorate by data writing, the NOSRAM has no limitation on the number of times of data writing.

Furthermore, the NOSRAM 4013 can store multilevel data of two or more bits as well as one-bit binary data. The multilevel data storage in the NOSRAM 4013 leads to a reduction in the memory cell area per bit.

Furthermore, the NOSRAM 4013 can store analog data as well as digital data. Thus, the analog arithmetic circuit 4011 can use the NOSRAM 4013 as an analog memory. The NOSRAM 4013 can store analog data as it is, and thus a D/A converter circuit and an A/D converter circuit are unnecessary. Therefore, the area of a peripheral circuit for the NOSRAM 4013 can be reduced. In this specification, analog data refers to data having a resolution of three bits (eight levels) or more. The above-described multilevel data is included in the analog data in some cases.

Data and parameters used in the neural network calculation can be once stored in the NOSRAM 4013. The data and parameters may be stored in a memory provided outside the AI system 4041 via the CPU 4021; however, the NOSRAM 4013 provided inside the AI system 4041 can store the data and parameters more quickly with lower power consumption. Furthermore, the NOSRAM 4013 enables a longer bit line than the DOSRAM 4012 and thus can have an increased storage capacity.

The FPGA 4014 is an FPGA using an OS transistor. With the use of the FPGA 4014, the AI system 4041 can establish a connection of a neural network such as a deep neural network (DNN), a convolutional neural network (CNN), a recurrent neural network (RNN), an autoencoder, a deep Boltzmann machine (DBM), or a deep belief network (DBN) described later, with a hardware. Establishing the connection of the neural network with a hardware enables higher speed performance.

The FPGA 4014 is an OS-FPGA. An OS-FPGA can have a smaller memory area than an FPGA including an SRAM. Thus, adding a context switching function only causes a small increase in area. Moreover, an OS-FPGA can transmit data and parameters at high speed by boosting.

In the AI system 4041, the analog arithmetic circuit 4011, the DOSRAM 4012, the NOSRAM 4013, and the FPGA 4014 can be provided on one die (chip). Thus, the AI system 4041 can execute calculation of the neural network quickly with low power consumption. In addition, the analog arithmetic circuit 4011, the DOSRAM 4012, the NOSRAM 4013, and the FPGA 4014 can be fabricated through the same manufacturing process. Therefore, the AI system 4041 can be fabricated at low cost.

Note that the arithmetic portion 4010 does not necessarily include all of the following: the DOSRAM 4012, the NOSRAM 4013, and the FPGA 4014. One or more memories selected from the DOSRAM 4012, the NOSRAM 4013, and the FPGA 4014 are provided in accordance with a problem that is desired to be solved by the AI system 4041.

The AI system 4041 can execute a method such as a deep neural network (DNN), a convolutional neural network (CNN), a recurrent neural network (RNN), an autoencoder, a deep Boltzmann machine (DBM), or a deep belief network (DBN) in accordance with the problem that is desired to be solved. The PROM 4025 can store a program for executing at least one of these methods. Furthermore, part or the whole of the program may be stored in the NOSRAM 4013.

Most of the existing programs used as libraries are premised on processing with a GPU. Therefore, the AI system 4041 preferably includes the GPU 4022. The AI system 4041 can execute the bottleneck product-sum operation among all the product-sum operations used for learning and inference in the arithmetic portion 4010, and execute the other product-sum operations in the GPU 4022. In this manner, the learning and inference can be executed at high speed.

The power supply circuit 4027 generates not only a low power supply potential for a logic circuit but also a potential for an analog operation. The power supply circuit 4027 may use an OS memory. When a reference potential is stored in the OS memory, the power consumption of the power supply circuit 4027 can be reduced.

The PMU 4028 has a function of temporarily stopping the power supply to the AI system 4041.

The CPU 4021 and the GPU 4022 preferably include OS memories as registers. By including the OS memories, the CPU 4021 and the GPU 4022 can retain data (logic values) in the OS memories even when power supply is stopped. As a result, the AI system 4041 can save the power.

The PLL 4023 has a function of generating a clock. The AI system 4041 performs an operation on the basis of the clock generated by the PLL 4023. The PLL 4023 preferably includes an OS memory. By including the OS memory, the PLL 4023 can retain an analog potential with which the clock oscillation cycle is controlled.

The AI system 4041 may store data in an external memory such as a DRAM. For this reason, the AI system 4041 preferably includes the memory controller 4026 functioning as an interface with the external DRAM. Furthermore, the memory controller 4026 is preferably positioned near the CPU 4021 or the GPU 4022. Thus, data transmission can be performed at high speed.

Some or all of the circuits illustrated in the control portion 4020 can be formed on the same die as the arithmetic portion 4010. Thus, the AI system 4041 can execute the neural network calculation at high speed with low power consumption.

Data used for the neural network calculation is stored in an external storage device (such as an HDD (Hard Disk Drive) or an SDD (Solid State Drive)) in many cases. Therefore, the AI system 4041 preferably includes the external memory control circuit 4031 functioning as an interface with the external storage device.

Because the neural network often deals with audio and video for learning and inference, the AI system 4041 includes the audio codec 4032 and the video codec 4033. The audio codec 4032 encodes and decodes audio data, and the video codec 4033 encodes and decodes video data.

The AI system 4041 can perform learning or inference using data obtained from an external sensor. For this reason, the AI system 4041 includes the general-purpose input/output module 4034. The general-purpose input/output module 4034 includes a USB (Universal Serial Bus), an I2C (Inter-Integrated Circuit), or the like, for example.

The AI system 4041 can perform learning or inference using data obtained via the Internet. For this reason, the AI system 4041 preferably includes the communication module 4035.

The analog arithmetic circuit 4011 may use a multi-level flash memory as an analog memory. However, the flash memory has a limitation on the number of rewriting times. In addition, the multi-level flash memory is extremely difficult to embed (to form the arithmetic circuit and the memory on the same die).

Alternatively, the analog arithmetic circuit 4011 may use a ReRAM as an analog memory. However, the ReRAM has a limitation on the number of rewriting times and also has a problem in storage accuracy. Moreover, the ReRAM is a two-terminal element, and thus has a complicated circuit design for separating data writing and data reading.

Further alternatively, the analog arithmetic circuit 4011 may use an MRAM as an analog memory. However, the MRAM has a problem in storage accuracy because of its low magnetoresistive ratio.

In consideration of the above, the analog arithmetic circuit 4011 preferably uses an OS memory as an analog memory.

This embodiment can be implemented in appropriate combination with the structures described in the other embodiments and the like.

### Embodiment 7

### <Application Example of AI System>

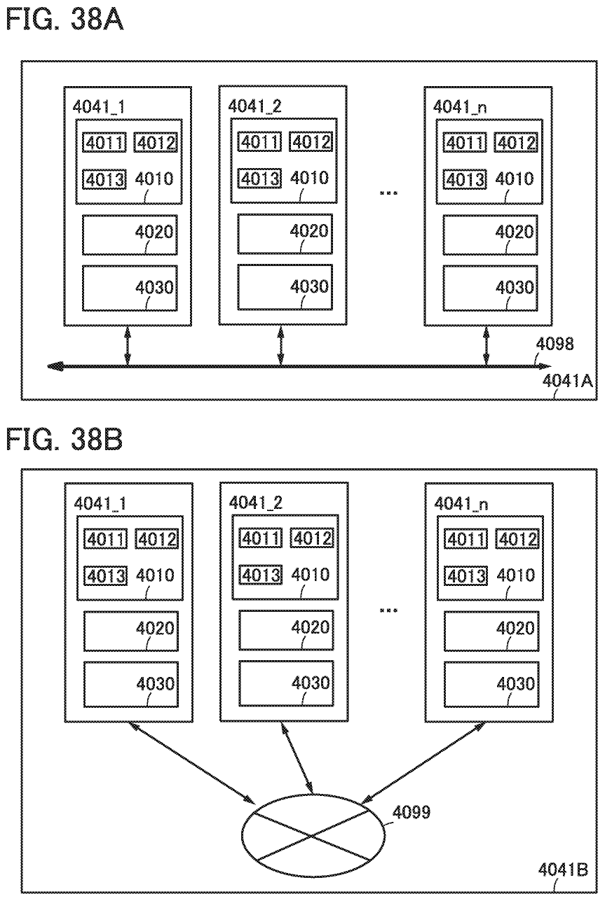

In this embodiment, application examples of the AI system described in the above embodiment are described with reference to FIG. 38.

FIG. 38(A) is an AI system 4041A in which the AI systems 4041 described with FIG. 37 are arranged in parallel and a signal can be transmitted between the systems via a bus line.

The AI system 4041A illustrated in FIG. 38(A) includes a plurality of AI systems 4041_1 to 4041_n (n is a natural number). The AI system 4041_1 to the AI system 4041_n are connected to each other via a bus line 4098.

FIG. 38(B) is an AI system 4041B in which the AI systems 4041 described with FIG. 35 are arranged in parallel as in FIG. 38(A) and a signal can be transmitted between the systems via a network.

The AI system 4041B illustrated in FIG. 38(B) includes the plurality of AI systems 4041_1 to 4041_n. The AI system 4041_1 to the AI system 4041_n are connected to each other via a network 4099.

A structure may be employed in which a communication module is provided in each of the AI system 4041_1 to the AI system 4041_n to perform wireless or wired communication via the network 4099. A communication module can perform communication via an antenna. For example, the communication can be performed in such a manner that an electronic device is connected to a computer network such as the Internet that is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network). In the case of performing wireless communication, it is possible to use, as a communication protocol or a communication technology, a communications standard such as LTE (Long Term Evolution), GSM (Global System for Mobile Communication: registered trademark), EDGE (Enhanced Data Rates for GSM Evolution), CDMA 2000 (Code Division Multiple Access 2000), or W-CDMA (registered trademark), or a communications standard developed by IEEE such as Wi-Fi (registered trademark), Bluetooth (registered trademark), or ZigBee (registered trademark).

With the structure illustrated in FIG. 38(A) or 38(B), analog signals obtained with external sensors or the like can be processed by different AI systems. For example, biological information such as brain waves, a pulse, blood pressure, and body temperature is obtained with a variety of sensors such as a brain wave sensor, a pulse wave sensor, a blood pressure sensor, and a temperature sensor, and analog signals can be processed by different AI systems. When the signal processing or learning is performed by different AI systems, the amount of information processed by each AI system can be reduced. Accordingly, the signal processing or learning can be performed with a smaller amount of arithmetic processing. As a result, recognition accuracy can be increased. The information obtained with each AI system is expected to enable instant understanding of collective biological information that irregularly changes.

This embodiment can be implemented in appropriate combination with the structures described in the other embodiments and the like.

### Embodiment 8

In this embodiment, an example of an IC incorporating the AI system described in the above embodiment is described.

In the AI system described in the above embodiment, a digital processing circuit such as a CPU that includes a Si transistor, an analog arithmetic circuit that uses an OS transistor, an OS-FPGA, and an OS memory such as a DOSRAM or a NOSRAM can be integrated into one die.

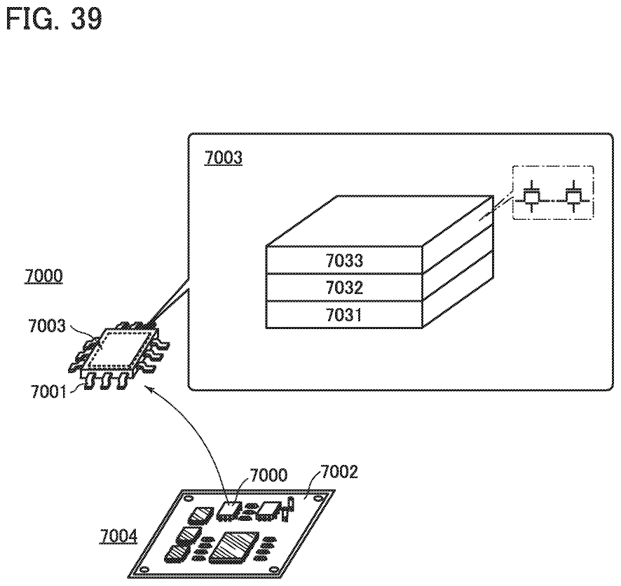

FIG. 39 illustrates the example of the IC incorporating the AI system. An AI system IC 7000 illustrated in FIG. 39 includes a lead 7001 and a circuit portion 7003. The AI system IC 7000 is mounted on a printed circuit board 7002, for example. A plurality of such IC chips are combined and electrically connected to each other on the printed circuit board 7002; thus, a board on which electronic components are mounted (a circuit board 7004) is completed. In the circuit portion 7003, the various circuits described in the above embodiment are provided on one die. The circuit portion 7003 has a stacked-layer structure, for example, as illustrated in FIG. 25 in the above embodiment, which is broadly divided into a Si transistor layer 7031, a wiring layer 7032, and an OS transistor layer 7033. Since the OS transistor layer 7033 can be provided to be stacked over the Si transistor layer 7031, the size of the AI system IC 7000 can be easily reduced.

Although a QFP (Quad Flat Package) is used as a package of the AI system IC 7000 in FIG. 39, the embodiment of the package is not limited thereto.

The digital processing circuit such as a CPU, the analog arithmetic circuit that uses an OS transistor, the OS-FPGA, and the OS memory such as a DOSRAM or a NOSRAM can all be formed in the Si transistor layer 7031, the wiring layer 7032, and the OS transistor layer 7033. In other words, elements included in the AI system can be formed through the same manufacturing process. Thus, the number of steps in the manufacturing process of the IC described in this embodiment does not need to be increased even when the number of elements is increased, and accordingly the AI system can be incorporated at low cost.

This embodiment can be implemented in appropriate combination with the structures described in the other embodiments and the like.

### Embodiment 9

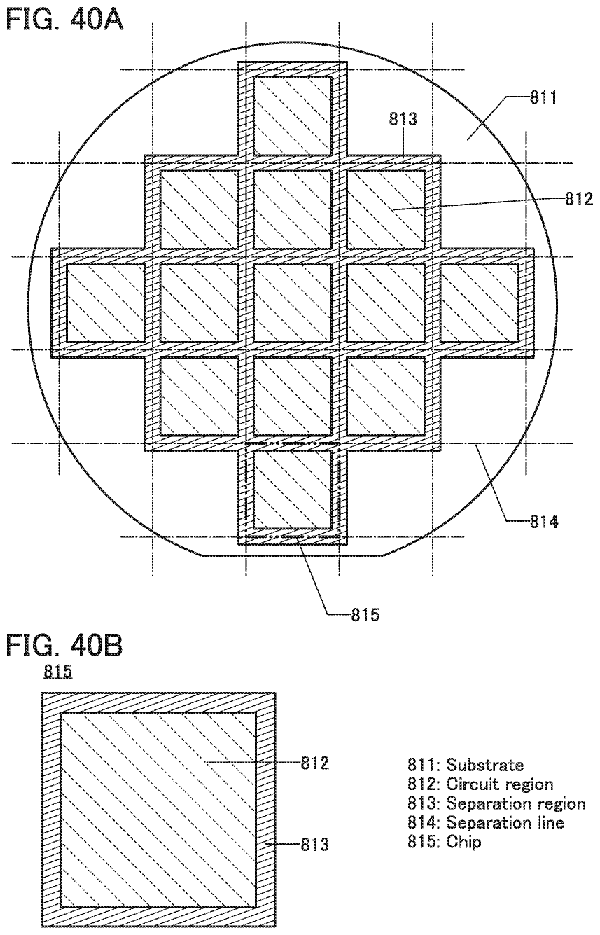

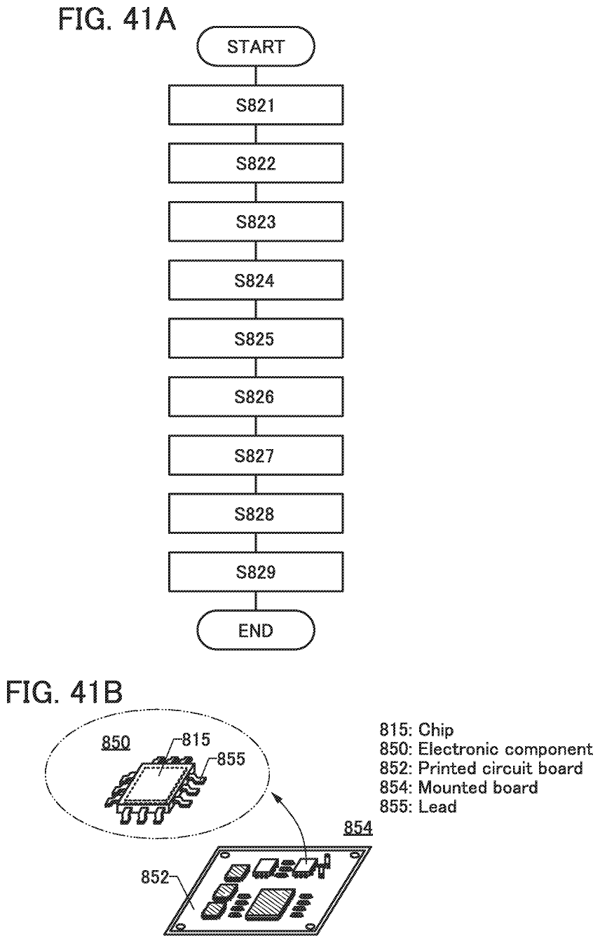

In this embodiment, one embodiment of a semiconductor device is described with reference to FIG. 40 and FIG. 41.

### <Semiconductor Wafer and Chip>

FIG. 40(A) is a top view of a substrate 811 before dicing treatment is performed. As the substrate 811, a semiconductor substrate (also referred to as a “semiconductor wafer”) can be used, for example. A plurality of circuit regions 812 are provided over the substrate 811. A semiconductor device and the like of one embodiment of the present invention can be provided in the circuit region 812.

The plurality of circuit regions 812 are each surrounded by a separation region 813. Separation lines (also referred to as “dicing lines”) 814 are set at a position overlapping with the separation regions 813. The substrate 811 is cut along the separation lines 814, whereby chips 815 including the circuit regions 812 can be cut out. FIG. 40(B) illustrates an enlarged view of the chip 815.

In addition, a conductive layer, a semiconductor layer, or the like may be provided in the separation regions 813. Providing a conductive layer, a semiconductor layer, or the like in the separation regions 813 relieves ESD that might be caused in a dicing step, preventing a decrease in the yield due to the dicing step. Moreover, a dicing step is generally performed while pure water whose specific resistance is decreased by dissolution of a carbonic acid gas or the like is supplied to a cut portion, in order to cool down a substrate, remove swarf, and prevent electrification, for example. Providing a conductive layer, a semiconductor layer, or the like in the separation regions 813 allows a reduction in the usage of the pure water. Therefore, the manufacturing cost of semiconductor devices can be reduced. Thus, the productivity of semiconductor devices can be improved.

### <Electronic Component>

An example of an electronic component using the chip 815 is described with reference to FIG. 41(A) and FIG. 41(B). Note that the electronic component is also referred to as a semiconductor package or an IC package. The electronic component has a plurality of standards, names, and the like depending on a terminal extraction direction, a terminal shape, and the like.

The electronic component is completed when the semiconductor device described in the above embodiment is combined with components other than the semiconductor device in an assembly process (post-process).

The post-process is described with reference to a flow chart of FIG. 41(A). After the semiconductor device and the like of one embodiment of the present invention are formed over the substrate 811 in a pre-process, a “back surface grinding step” for grinding a back surface (a surface where the semiconductor device and the like are not formed) of the substrate 811 is performed (Step S821). When the substrate 811 is thinned by the grinding, the size of the electronic component can be reduced.

Next, a “dicing step” for dividing the substrate 811 into a plurality of chips 815 is performed (Step S822). Then, a “die bonding step” for individually bonding the divided chips 815 to a lead frame is performed (Step S823). To bond the chip 815 and a lead frame in the die bonding step, a method such as resin bonding or tape-automated bonding is selected as appropriate depending on products. Note that the chip 815 may be bonded to an interposer substrate instead of the lead frame.

Next, a “wire bonding step” for electrically connecting a lead of the lead frame and an electrode on the chip 815 through a metal wire is performed (Step S824). As the metal wire, a silver wire, a gold wire, or the like can be used. In addition, ball bonding or wedge bonding can be used as the wire bonding, for example.

The wire-bonded chip 815 is subjected to a “sealing step (molding step)” for sealing the chip with an epoxy resin or the like (Step S825). Through the sealing step, the inside of the electronic component is filled with a resin, so that a wire for connecting the chip 815 to the lead can be protected from external mechanical force, and deterioration of characteristics (decrease in reliability) due to moisture, dust, or the like can be reduced.

Subsequently, a “lead plating step” for plating the lead of the lead frame is performed (Step S826). This plate processing prevents corrosion of the lead and enables more reliable soldering at the time of mounting the electronic component on a printed circuit board in a later step. Then, a “formation step” for cutting and processing the lead is performed (Step S827).

Next, a “marking step” for printing (marking) a surface of the package is performed (Step S828). Then, after a “testing step” (Step S829) for checking the quality of an external shape, the presence of malfunction, and the like, the electronic component is completed.

FIG. 41(B) illustrates a perspective schematic view of the completed electronic component. FIG. 41(B) illustrates a perspective schematic view of a QFP (Quad Flat Package) as an example of the electronic component. An electronic component 850 illustrated in FIG. 41(B) includes a lead 855 and the chip 815. The electronic component 850 may include a plurality of chips 815.

The electronic component 850 in FIG. 41(B) is mounted on a printed circuit board 852, for example. A plurality of such electronic components 850 are combined and electrically connected to each other on the printed circuit board 852; thus, a board on which the electronic components are mounted (a mounted board 854) is completed. The completed mounted board 854 is used for an electronic device or the like.

This embodiment can be implemented in appropriate combination with the structures described in the other embodiments and the like.

### Embodiment 10

### <Electronic Device>

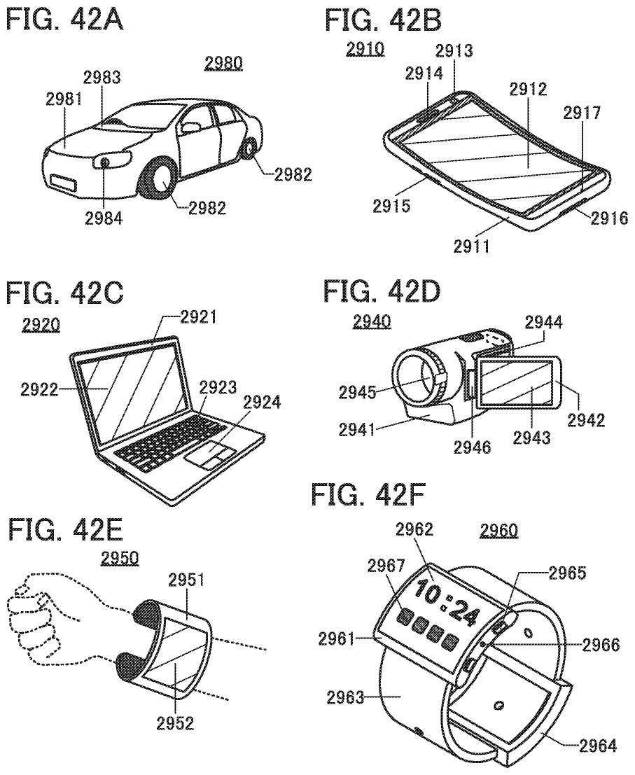

A semiconductor device of one embodiment of the present invention can be used for a variety of electronic devices. FIG. 42 illustrates specific examples of electronic devices including the semiconductor device of one embodiment of the present invention.

FIG. 42(A) is an external view illustrating an example of a car. A car 2980 includes a car body 2981, wheels 2982, a dashboard 2983, lights 2984, and the like. The car 2980 also includes an antenna, a battery, and the like.

An information terminal 2910 illustrated in FIG. 42(B) includes a housing 2911, a display portion 2912, a microphone 2917, a speaker portion 2914, a camera 2913, an external connection portion 2916, an operation switch 2915, and the like. A display panel and a touch screen that use a flexible substrate are provided in the display portion 2912. In the housing 2911 of the information terminal 2910, an antenna, a battery, and the like are provided. The information terminal 2910 can be used as, for example, a smartphone, a mobile phone, a tablet information terminal, a tablet personal computer, or an e-book reader.

A notebook personal computer 2920 illustrated in FIG. 42(C) includes a housing 2921, a display portion 2922, a keyboard 2923, a pointing device 2924, and the like. In the housing 2921 of the notebook personal computer 2920, an antenna, a battery, and the like are provided.

A video camera 2940 illustrated in FIG. 42(D) includes a housing 2941, a housing 2942, a display portion 2943, operation switches 2944, a lens 2945, a joint 2946, and the like. The operation switches 2944 and the lens 2945 are provided for the housing 2941, and the display portion 2943 is provided for the housing 2942. In the housing 2941 of the video camera 2940, an antenna, a battery, and the like are provided. The housing 2941 and the housing 2942 are connected to each other with the joint 2946, and the angle between the housing 2941 and the housing 2942 can be changed with the joint 2946. The orientation of an image on the display portion 2943 may be changed and display and non-display of an image can be switched depending on the angle of the housing 2942 with respect to the housing 2941.

FIG. 42(E) illustrates an example of a bangle-type information terminal. An information terminal 2950 includes a housing 2951, a display portion 2952, and the like. In the housing 2951 of the information terminal 2950, an antenna, a battery, and the like are provided. The display portion 2952 is supported by the housing 2951 having a curved surface. A display panel formed with a flexible substrate is provided in the display portion 2952, whereby the information terminal 2950 can be a user-friendly information terminal that is flexible and lightweight.

FIG. 42(F) illustrates an example of a watch-type information terminal. An information terminal 2960 includes a housing 2961, a display portion 2962, a band 2963, a buckle 2964, an operation switch 2965, an input output terminal 2966, and the like. In the housing 2961 of the information terminal 2960, an antenna, a battery, and the like are provided. The information terminal 2960 is capable of executing a variety of applications such as mobile phone calls, e-mailing, viewing and editing texts, music reproduction, Internet communication, and a computer game.

The display surface of the display portion 2962 is curved, and images can be displayed on the curved display surface. In addition, the display portion 2962 includes a touch sensor, and operation can be performed by touching the screen with a finger, a stylus, or the like. For example, by touching an icon 2967 displayed on the display portion 2962, application can be started. With the operation switch 2965, a variety of functions such as time setting, power on/off, on/off of wireless communication, setting and cancellation of a silent mode, and setting and cancellation of a power saving mode can be performed. For example, the functions of the operation switch 2965 can be set by setting the operation system incorporated in the information terminal 2960.

The information terminal 2960 can execute near field communication conformable to a communication standard. For example, mutual communication with a headset capable of wireless communication enables hands-free calling. Moreover, the information terminal 2960 includes the input output terminal 2966, and data can be directly transmitted to and received from another information terminal via a connector. In addition, charging via the input output terminal 2966 is possible. Note that the charging operation may be performed by wireless power feeding without through the input output terminal 2966.

A memory device including the semiconductor device of one embodiment of the present invention can hold control data, a control program, or the like of the above electronic device for a long time. With the use of the semiconductor device of one embodiment of the present invention, a highly reliable electronic device can be achieved.

This embodiment can be implemented in an appropriate combination with any of the structures described in the other embodiments and the like.

### Embodiment 11

In this embodiment, examples of a display device that includes any of the transistors described in the above embodiment will be described.

### [Structure Examples]

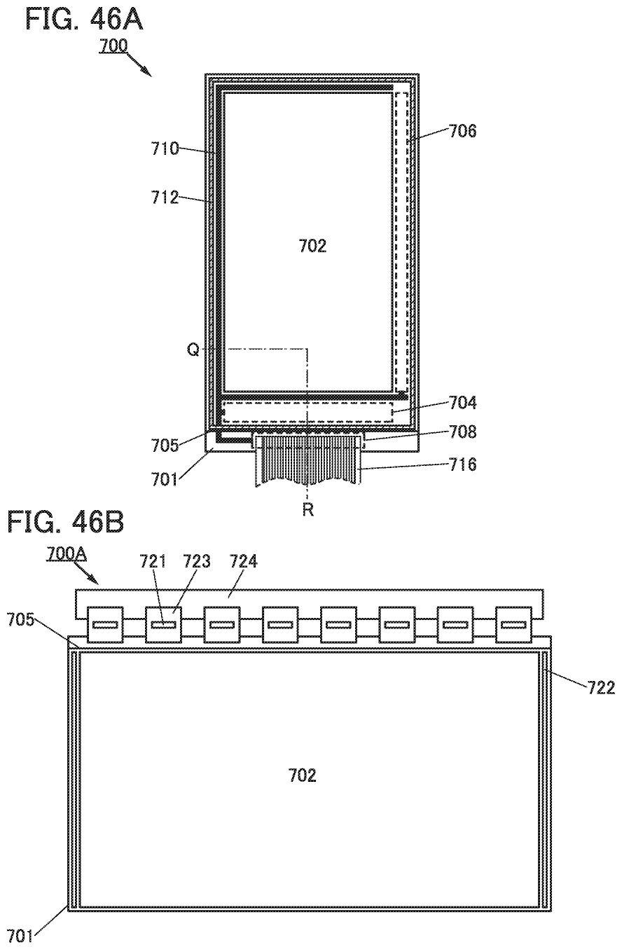

FIG. 46(A) is a top view illustrating an example of a display device. A display device 700 in FIG. 46(A) includes a pixel portion 702 provided over a first substrate 701; a source driver circuit portion 704 and a gate driver circuit portion 706 provided over the first substrate 701; a sealant 712 provided to surround the pixel portion 702, the source driver circuit portion 704, and the gate driver circuit portion 706; and a second substrate 705 provided to face the first substrate 701. The first substrate 701 and the second substrate 705 are bonded to each other with the sealant 712. That is, the pixel portion 702, the source driver circuit portion 704, and the gate driver circuit portion 706 are sealed with the first substrate 701, the sealant 712, and the second substrate 705. Although not illustrated in FIG. 46(A), a display element is provided between the first substrate 701 and the second substrate 705.

In the display device 700, an FPC terminal portion 708 (FPC: Flexible printed circuit) is provided over the first substrate 701 in a region different from the region surrounded by the sealant 712. The FPC terminal portion 708 is electrically connected to the pixel portion 702, the source driver circuit portion 704, the gate driver circuit portion 706, and the gate driver circuit portion 706. An FPC 716 is connected to the FPC terminal portion 708, and a variety of signals and the like are supplied from the FPC 716 to the pixel portion 702, the source driver circuit portion 704, and the gate driver circuit portion 706. A signal line 710 is connected to the pixel portion 702, the source driver circuit portion 704, the gate driver circuit portion 706, and the FPC terminal portion 708. A variety of signals and the like supplied from the FPC 716 are supplied to the pixel portion 702, the source driver circuit portion 704, the gate driver circuit portion 706, and the FPC terminal portion 708 via the signal line 710.

A plurality of gate driver circuit portions 706 may be provided in the display device 700. An example of the display device 700 in which the source driver circuit portion 704 and the gate driver circuit portion 706 are formed over the first substrate 701 where the pixel portion 702 is also formed is described; however, the structure is not limited thereto. For example, only the gate driver circuit portion 706 may be formed over the first substrate 701, or only the source driver circuit portion 704 may be formed over the first substrate 701. In such a case, a structure in which a substrate where the source driver circuit, the gate driver circuit, or the like is formed (e.g., a driver circuit board formed using a single crystal semiconductor film or a polycrystalline semiconductor film) is provided on the first substrate 701 may be employed. There is no particular limitation on a method for connecting such a separately formed driver circuit substrate; for example, a COG (Chip On Glass) method or a wire bonding method can be used.

The pixel portion 702, the source driver circuit portion 704, and the gate driver circuit portion 706 included in the display device 700 include a plurality of transistors. As the plurality of transistors, any of the transistors that are the semiconductor devices of embodiments of the present invention can be used.

The display device 700 can include any of a variety of elements. Examples of the elements include an electroluminescent (EL) element (e.g., an EL element containing organic and inorganic materials, an organic EL element, an inorganic EL element, and an LED), a light-emitting transistor element (a transistor that emits light depending on current), an electron emitter, a liquid crystal element, an electronic ink element, an electrophoretic element, an electrowetting element, a plasma display panel (PDP), a microelectromechanical systems (MEMS) display (e.g., a grating light valve (GLV), a digital micromirror device (DMD), a digital micro shutter (DMS) element, and an interferometric modulator display (IMOD) element), and a piezoelectric ceramic display.

An example of a display device including an EL element is an EL display. Examples of display devices including electron emitters are a field emission display (FED) and an SED-type flat panel display (SED: Surface-conduction Electron-emitter Display). Examples of display devices including liquid crystal elements include liquid crystal displays (e.g., a transmissive liquid crystal display, a transflective liquid crystal display, a reflective liquid crystal display, a direct-view liquid crystal display, and a projection liquid crystal display). An example of a display device including an electronic ink element or an electrophoretic element is electronic paper. In a transflective liquid crystal display or a reflective liquid crystal display, some or all of pixel electrodes function as reflective electrodes. For example, some or all of the pixel electrodes are formed to contain aluminum, silver, or the like. In such a case, a memory circuit such as an SRAM can be provided under the reflective electrodes, which can further reduce power consumption.

As a display method in the display device 700, a progressive method, an interlace method, or the like can be employed. Furthermore, color elements controlled in pixels for color display are not limited to three colors of RGB (R, G, and B represent red, green, and blue). For example, four pixels of the R pixel, the G pixel, the B pixel, and a W (white) pixel may be employed. Alternatively, a color element may be composed of two colors among R, G, and B as in PenTile layout; the two colors may differ among color elements. Alternatively, one or more colors of yellow, cyan, magenta, and the like may be added to RGB. Furthermore, the size of a display region may be different depending on respective dots of the color elements. Note that one embodiment of the disclosed invention is not limited to a display device for color display; the disclosed invention can also be applied to a display device for monochrome display.

A coloring layer (also referred to as color filter) may be used to obtain a color display device in which white light (W) is used for a backlight (e.g., an organic EL element, an inorganic EL element, an LED, or a fluorescent lamp). For example, a red (R) coloring layer, a green (G) coloring layer, a blue (B) coloring layer, and a yellow (Y) coloring layer can be used in combination as appropriate. With the use of the coloring layer, higher color reproducibility can be obtained as compared with the case without the coloring layer. Here, by providing a region with a coloring layer and a region without a coloring layer, white light in the region without the coloring layer may be directly utilized for display. By partly providing the region without the coloring layer, a decrease in the luminance of a bright image due to the coloring layer can be suppressed, and power consumption can sometimes be reduced by approximately 20% to 30%. In the case where full-color display is performed using a self-luminous element such as an organic EL element or an inorganic EL element, elements may emit light of their respective colors R, G, B, Y, and W. By using a self-luminous element, power consumption can sometimes be further reduced compared to the case of using the coloring layer.

As a coloring method, the above-described method in which part of white light is converted into red light, green light, and blue light through color filters (color filter method); a method in which red light, green light, and blue light are used (three-color method); or a method in which part of blue light is converted into red light or green light (color conversion method or quantum dot method), may be employed.

A display device 700A illustrated in FIG. 46(B) is a display device that can be favorably used for an electronic device with a large screen. The display device 700A is suitable for a television device, a monitor, or digital signage, for example.

The display device 700A includes a plurality of source driver ICs 721 and a pair of gate driver circuits 722.

The plurality of source driver ICs 721 are attached to respective FPCs 723. In each of the plurality of FPCs 723, one of terminals is connected to the substrate 701, and the other terminal is connected to a printed circuit board 724. By bending the FPCs 723, the printed circuit board 724 can be placed on the back of the pixel portion 702 to be mounted on an electrical device.

On the other hand, the gate driver circuits 722 are provided over the substrate 701. Thus, an electronic device with a narrow bezel can be achieved.

With such a structure, a large-size and high-resolution display device can be provided. For example, such a structure can be adopted to a display device with a screen size (diagonal) of 30 inches or more, 40 inches or more, 50 inches or more, or 60 inches or more. Furthermore, a display device with extremely high resolution such as full high definition, 4K2K, or 8K4K can be provided.

### [Cross-Sectional Structure Examples]

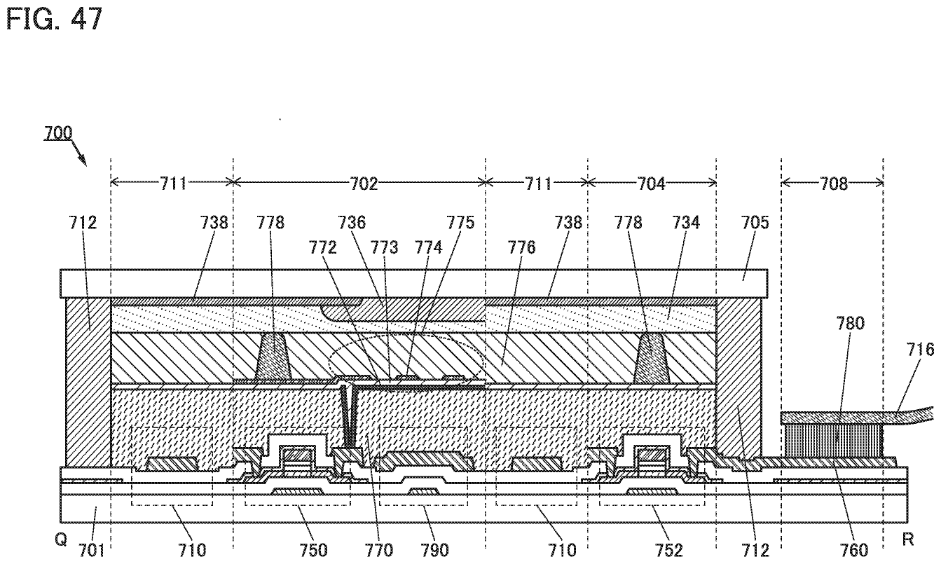

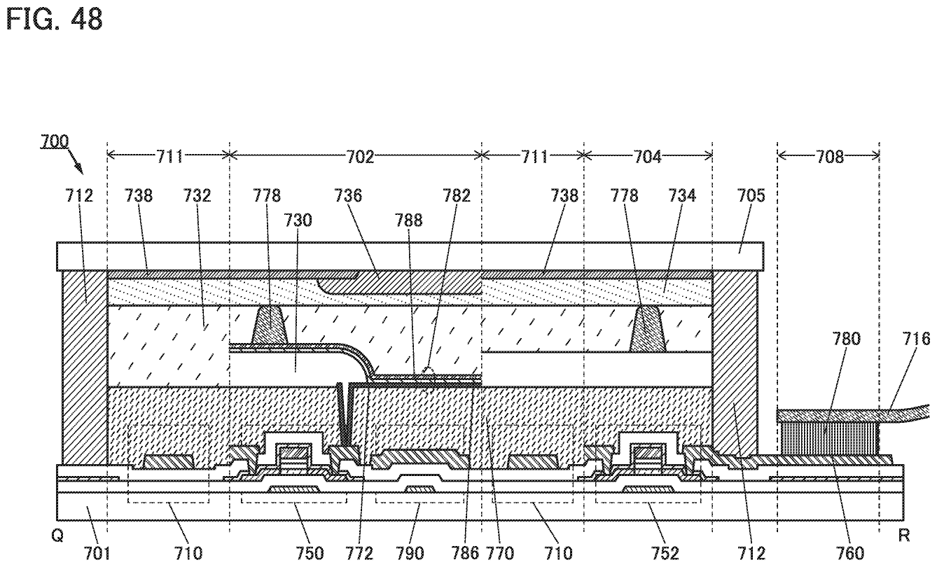

Structures including a liquid crystal element or an EL element as a display element will be described below with reference to FIG. 47 and FIG. 48. FIG. 47 is a cross-sectional view along the dashed-dotted line Q-R in FIG. 46(A) and illustrates a structure including a liquid crystal element as a display element. FIG. 48 is a cross-sectional view along the dashed-dotted line Q-R in FIG. 46(A) and illustrates a structure including an EL element as a display element.

Hereinafter, common components among FIG. 47 and FIG. 48 will be described first, and then, components that are different between FIG. 47 and FIG. 48 will be described.

### [Common Components in Display Devices]

The display devices 700 in FIG. 47 and FIG. 48 each include a lead wiring portion 711, the pixel portion 702, the source driver circuit portion 704, and the FPC terminal portion 708. The lead wiring portion 711 includes the signal line 710. The pixel portion 702 includes a transistor 750 and a capacitor 790. The source driver circuit portion 704 includes a transistor 752.

As the transistor 750 and the transistor 752, any of the transistors described in Embodiment 1 can be used.

The transistor used in this embodiment includes a highly purified oxide semiconductor film in which formation of oxygen vacancies is suppressed. The transistor can have a low off-state current. Accordingly, an electrical signal such as an image signal can be held for a longer period, and intervals between write operations can be set longer in a power-on state. Thus, the frequency of refresh operations can be decreased, resulting in an effect of reducing power consumption.

In addition, the transistor used in this embodiment can have relatively high field-effect mobility and thus is capable of high-speed operation. For example, with such a high-speed transistor used for a display device, a switching transistor in a pixel portion and a driver transistor in a driver circuit portion can be formed over one substrate. That is, a semiconductor device formed using a silicon wafer or the like is not additionally needed as a driver circuit, by which the number of components of the semiconductor device can be reduced. Moreover, the use of the high-speed transistor in the pixel portion can provide a high-quality image.

The capacitor 790 includes a lower electrode which is formed through a step of processing a conductive film that is the same as a conductive film functioning as a first gate electrode of the transistor 750, and an upper electrode which is formed through a step of processing a conductive film that is the same as a conductive film functioning as a source electrode or a drain electrodes of the transistor 750. Between the lower electrode and the upper electrode, an insulating film formed through a step of forming an insulating film that is the same as an insulating film functioning as a first gate insulating film of the transistor 750 and an insulating film formed through a step of forming an insulating film that is the same as an insulating film functioning as a protective insulating film over the transistor 750 are provided. That is, the capacitor 790 has a stacked-layer structure in which an insulating film functioning as a dielectric film is positioned between the pair of electrodes.

In FIG. 47 and FIG. 48, a planarization insulating film 770 is provided over the transistor 750, the transistor 752, and the capacitor 790.

Although FIG. 47 and FIG. 48 show an example in which transistors with the same structure are used as the transistor 750 included in the pixel portion 702 and the transistor 752 included in the source driver circuit portion 704, one embodiment of the present invention is not limited thereto. For example, different transistors may be used in the pixel portion 702 and the source driver circuit portion 704. Specifically, a structure in which a top-gate transistor is used in the pixel portion 702 and a bottom-gate transistor is used in the source driver circuit portion 704, a structure in which a bottom-gate transistor is used in the pixel portion 702 and a top-gate transistor is used in the source driver circuit portion 704, and the like are given. Note that the source driver circuit portion 704 may be replaced with a gate driver circuit portion.

The signal line 710 is formed through the same process as the conductive films functioning as source and drain electrodes of the transistors 750 and 752. When the signal line 710 is formed using a material containing a copper element, for example, signal delay or the like due to wiring resistance is reduced, which enables display on a large screen.

The FPC terminal portion 708 includes a connection electrode 760, an anisotropic conductive film 780, and the FPC 716. The connection electrode 760 is formed through the same process as the conductive films functioning as the source electrodes and the drain electrodes of the transistors 750 and 752. The connection electrode 760 is electrically connected to a terminal of the FPC 716 through the anisotropic conductive film 780.

For example, a glass substrate can be used as the first substrate 701 and the second substrate 705. Alternatively, a flexible substrate may be used as the first substrate 701 and the second substrate 705. An example of the flexible substrate includes a plastic substrate.

A structure body 778 is provided between the first substrate 701 and the second substrate 705. The structure body 778 is a columnar spacer and is provided to control the distance (cell gap) between the first substrate 701 and the second substrate 705. Note that a spherical spacer may be used as the structure body 778.

A light-blocking film 738 functioning as a black matrix, a coloring film 736 functioning as a color filter, and an insulating film 734 in contact with the light-blocking film 738 and the coloring film 736 are provided on the second substrate 705 side.

### [Structure Examples of Display Device Using Liquid Crystal Element]

The display device 700 illustrated in FIG. 47 includes a liquid crystal element 775. The liquid crystal element 775 includes a conductive film 772, a conductive film 774, and a liquid crystal layer 776. The conductive film 774 is provided on the second substrate 705 side and functions as a counter electrode.

The display device 700 illustrated in FIG. 47 is an example of employing a horizontal electric field mode (e.g., an FFS mode) as a driving mode of the liquid crystal element. In the structure illustrated in FIG. 47, an insulating film 773 is provided over the conductive film 772, and the conductive film 774 is provided over the insulating film 773. In this structure, the conductive film 774 functions as a common electrode, and an electric field generated between the conductive film 772 and the conductive film 774 through the insulating film 773 can control the alignment state in the liquid crystal layer 776.

Although not illustrated in FIG. 47, the conductive film 772 and/or the conductive film 774 may be provided with an alignment film on the side in contact with the liquid crystal layer 776. Although not illustrated in FIG. 47, an optical member (optical substrate) such as a polarizing member, a retardation member, or an anti-reflection member, for example, may be provided as appropriate. For example, circular polarization may be employed by using a polarizing substrate and a retardation substrate. In addition, a backlight, a side light, or the like may be used as a light source.

The conductive film 772 is electrically connected to the conductive film functioning as the source electrode or the drain electrode of the transistor 750. The conductive film 772 is formed over the planarization insulating film 770 and functions as a pixel electrode, that is, one electrode of the display element.

A conductive film that transmits visible light or a conductive film that reflects visible light can be used as the conductive film 772. The conductive film that transmits visible light is preferably formed using a material containing one kind selected from indium (In), zinc (Zn), and tin (Sn), for example. The conductive film that reflects visible light is preferably formed using a material containing aluminum or silver, for example.

When a conductive film that reflects visible light is used as the conductive film 772, the display device 700 is a reflective liquid crystal display device. When a conductive film that transmits visible light is used as the conductive film 772, the display device 700 is a transmissive liquid crystal display device. For a reflective liquid crystal display device, a polarizing plate is provided on the viewer side. On the other hand, for a transmissive liquid crystal display device, a pair of polarizing plates are provided so that the liquid crystal element is placed therebetween.

When the liquid crystal element is used as the display element, a thermotropic liquid crystal, a low-molecular liquid crystal, a high-molecular liquid crystal, a polymer dispersed liquid crystal, a polymer network liquid crystal, a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions.

In the case of employing a horizontal electric field mode, a liquid crystal exhibiting a blue phase for which an alignment film is unnecessary may be used. The blue phase is one of liquid crystal phases, which is generated just before a cholesteric phase changes into an isotropic phase while the temperature of a cholesteric liquid crystal is increased. Since the blue phase appears only in a narrow temperature range, a liquid crystal composition in which a chiral material is mixed to account for several weight percent or more is used for the liquid crystal layer in order to improve the temperature range. The liquid crystal composition that contains a liquid crystal exhibiting the blue phase and a chiral material has a short response time and optical isotropy, which makes the alignment process unneeded. An alignment film does not need to be provided and rubbing treatment is thus not necessary; accordingly, electrostatic discharge damage caused by the rubbing treatment can be prevented and defects and damage of the liquid crystal display device in the manufacturing process can be reduced. Moreover, the liquid crystal material that exhibits the blue phase has small viewing angle dependence.

When the liquid crystal element is used as the display element, it is possible to employ a TN (Twisted Nematic) mode, an IPS (In-Plane-Switching) mode, an FFS (Fringe Field Switching) mode, an ASM (Axially Symmetric aligned Micro-cell) mode, an OCB (Optical Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like.

The display device may also be a normally black liquid crystal display device such as a transmissive liquid crystal display device utilizing a vertical alignment (VA) mode. Examples of a vertical alignment mode to be employed are an MVA (Multi-Domain Vertical Alignment) mode, a PVA (Patterned Vertical Alignment) mode, and an ASV mode.

### [Display Device Using Light-Emitting Element]

The display device 700 illustrated in FIG. 48 includes a light-emitting element 782. The light-emitting element 782 includes the conductive film 772, an EL layer 786, and a conductive film 788. The display device 700 illustrated in FIG. 48 can display an image by utilizing light emission from the EL layer 786 of the light-emitting element 782 provided in each pixel. Note that the EL layer 786 contains an organic compound or an inorganic compound such as a quantum dot.

Examples of materials that can be used for an organic compound include a fluorescent material and a phosphorescent material. Examples of materials that can be used for a quantum dot include a colloidal quantum dot material, an alloyed quantum dot material, a core-shell quantum dot material, and a core quantum dot material. A material containing elements belonging to Groups 12 and 16, elements belonging to Groups 13 and 15, or elements belonging to Groups 14 and 16 may be used. Alternatively, a quantum dot material containing an element such as cadmium (Cd), selenium (Se), zinc (Zn), sulfur (S), phosphorus (P), indium (In), tellurium (Te), lead (Pb), gallium (Ga), arsenic (As), or aluminum (Al) may be used.

In the display device 700 in FIG. 48, an insulating film 730 is provided over the planarization insulating film 770 and the conductive film 772. The insulating film 730 covers part of the conductive film 772. Note that the light-emitting element 782 has a top-emission structure; hence, the conductive film 788 has light-transmitting properties and transmits light emitted from the EL layer 786. Although the top-emission structure is described as an example in this embodiment, one embodiment of the present invention is not limited thereto. For example, a bottom-emission structure in which light is emitted to the conductive film 772 side, or a dual-emission structure in which light is emitted to both the conductive film 772 and the conductive film 788 may also be employed.

The coloring film 736 is provided to overlap the light-emitting element 782. The light-blocking film 738 is provided in the lead wiring portion 711 and the source driver circuit portion 704 to overlap the insulating film 730. The coloring film 736 and the light-blocking film 738 are covered with the insulating film 734. A space between the light-emitting element 782 and the insulating film 734 is filled with a sealing film 732. The structure of the display device 700 is not limited to the example in FIG. 48, in which the coloring film 736 is provided. For example, a structure without the coloring film 736 may also be employed when the EL layer 786 is formed into an island shape for each pixel (i.e., formed by side-by-side patterning).

At least part of any of the structure examples, the drawings corresponding thereto, and the like described in this embodiment can be implemented in combination with any of the other structure examples, the other drawings corresponding thereto, and the like as appropriate.

At least part of this embodiment can be implemented in combination with any of the other embodiments described in this specification as appropriate.

### Embodiment 12

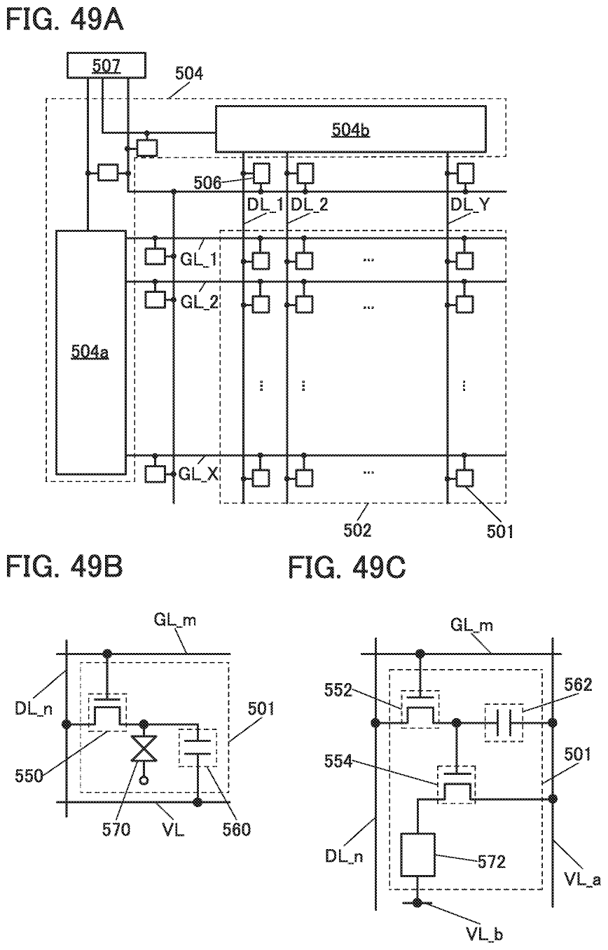

In this embodiment, a display device including a semiconductor device of one embodiment of the present invention is described with reference to FIG. 49.

A display device illustrated in FIG. 49(A) includes a region including pixels of display elements (hereinafter referred to as a pixel portion 502), a circuit portion that is provided outside the pixel portion 502 and includes a circuit for driving the pixels (hereinafter referred to as a driver circuit portion 504), circuits having a function of protecting elements (hereinafter referred to as protection circuits 506), and a terminal portion 507. Note that the protection circuits 506 are not necessarily provided.

Part or the whole of the driver circuit portion 504 is preferably formed over a substrate over which the pixel portion 502 is formed. Thus, the number of components and the number of terminals can be reduced. When part or the whole of the driver circuit portion 504 is not formed over the substrate over which the pixel portion 502 is formed, the part or the whole of the driver circuit portion 504 can be mounted by COG or TAB (Tape Automated Bonding).

The pixel portion 502 includes a plurality of circuits for driving display elements arranged in X rows (X is a natural number of 2 or more) and Y columns (Y is a natural number of 2 or more) (hereinafter referred to as pixel circuits 501). The driver circuit portion 504 includes driver circuits such as a circuit for outputting a signal (scan signal) to select a pixel (hereinafter referred to as a gate driver 504a) and a circuit for supplying a signal (data signal) to drive a display element in a pixel (hereinafter referred to as a source driver 504b).

The gate driver 504a includes a shift register or the like. A signal for driving the shift register is input through the terminal portion 507 to the gate driver 504a, and the gate driver 504a outputs a signal. For example, a start pulse signal, a clock signal, or the like is input to the gate driver 504a, and the gate driver 504a outputs a pulse signal. The gate driver 504a has a function of controlling the potentials of wirings supplied with scan signals (hereinafter referred to as scan lines GL_1 to GL_X). Note that a plurality of gate drivers 504a may be provided, and the scan lines GL_1 to GL_X may be controlled separately by the plurality of gate drivers 504a. The gate driver 504a also has a function of supplying an initialization signal. Without being limited thereto, the gate driver 504a can also supply another signal.

The source driver 504b includes a shift register or the like. A signal (image signal) from which a data signal is derived, as well as a signal for driving the shift register is input to the source driver 504b through the terminal portion 507. The source driver 504b has a function of generating a data signal to be written to the pixel circuit 501 on the basis of the image signal. In addition, the source driver 504b has a function of controlling output of a data signal in response to a pulse signal produced by input of a start pulse signal, a clock signal, or the like. Furthermore, the source driver 504b has a function of controlling the potentials of wirings supplied with data signals (hereinafter referred to as data lines DL_1 to DL_Y). The source driver 504b also has a function of supplying an initialization signal. Without being limited thereto, the source driver 504b can also supply another signal.

The source driver 504b is formed with use of a plurality of analog switches, for example. The source driver 504b can output, as the data signals, signals obtained by time-dividing the image signal by sequentially turning on the plurality of analog switches. The source driver 504b may be formed with use of a shift register or the like.

A pulse signal and a data signal are input to each of the plurality of pixel circuits 501 through one of the plurality of scan lines GL supplied with scan signals and one of the plurality of data lines DL supplied with data signals, respectively. Writing and holding of data of the data signal in each of the plurality of pixel circuits 501 are controlled by the gate driver 504a. For example, to the pixel circuit 501 in the m-th row and the n-th column, a pulse signal is input from the gate driver 504a through the scan line GL_m (m is a natural number of less than or equal to X), and a data signal is input from the source driver 504b through the data line DL_n (n is a natural number of less than or equal to Y) in accordance with the potential of the scan line GL_m.

The protection circuit 506 in FIG. 49(A) is connected to, for example, the scan line GL between the gate driver 504a and the pixel circuit 501. Alternatively, the protection circuit 506 is connected to the data line DL between the source driver 504b and the pixel circuit 501.

Alternatively, the protection circuit 506 can be connected to a wiring between the gate driver 504a and the terminal portion 507. Alternatively, the protection circuit 506 can be connected to a wiring between the source driver 504b and the terminal portion 507. Note that the terminal portion 507 refers to a portion having terminals for inputting power, control signals, and image signals to the display device from external circuits.

The protection circuit 506 is a circuit that electrically connects a wiring connected to the protection circuit to another wiring when a potential out of a certain range is applied to the wiring connected to the protection circuit.

As illustrated in FIG. 49(A), the protection circuits 506 provided for each of the pixel portion 502 and the driver circuit portion 504 can improve the resistance of the display device to overcurrent generated by ESD (Electro Static Discharge) or the like. Note that the configuration of the protection circuits 506 is not limited to that; for example, a configuration in which the protection circuit 506 is connected to the gate driver 504a or a configuration in which the protection circuit 506 is connected to the source driver 504b can be employed. Alternatively, a configuration in which the protection circuit 506 is connected to the terminal portion 507 can be employed.

Although in FIG. 49(A) an example in which the gate driver 504a and the source driver 504b constitute the driver circuit portion 504 is illustrated, one embodiment is not limited to this example. For example, only the gate driver 504a may be formed and a separately prepared substrate where a source driver circuit is formed (e.g., a driver circuit substrate formed with a single crystal semiconductor film or a polycrystalline semiconductor film) may be mounted.

The pixel circuit 501 in FIG. 49(B) includes a liquid crystal element 570, a transistor 550, and a capacitor 560. As the transistor 550, the transistors described in the above embodiments, for example, can be used.

The potential of one of a pair of electrodes of the liquid crystal element 570 is set in accordance with the specifications of the pixel circuit 501 as appropriate. The alignment state of the liquid crystal element 570 depends on written data. A common potential may be applied to one of the pair of electrodes of the liquid crystal element 570 included in each of the plurality of pixel circuits 501. Furthermore, the potential applied to one of the pair of electrodes of the liquid crystal element 570 in the pixel circuit 501 may be different row by row.

As a driving method of the display device including the liquid crystal element 570, for example, a TN mode, an STN mode, a VA mode, an ASM (Axially Symmetric Aligned Micro-cell) mode, an OCB (Optically Compensated Birefringence) mode, an FLC (Ferroelectric Liquid Crystal) mode, an AFLC (AntiFerroelectric Liquid Crystal) mode, an MVA mode, a PVA (Patterned Vertical Alignment) mode, an IPS mode, an FFS mode, a TBA (Transverse Bend Alignment) mode, and the like may be used. Examples of a driving method of the display device include, in addition to the above driving methods, an ECB (Electrically Controlled Birefringence) mode, a PDLC (Polymer Dispersed Liquid Crystal) mode, a PNLC (Polymer Network Liquid Crystal) mode, and a guest-host mode. However, not limited to the above, a variety of liquid crystal elements and the driving methods thereof can be used.

In the pixel circuit 501 in the m-th row and the n-th column, one of a source electrode and a drain electrode of the transistor 550 is electrically connected to the data line DL_n, and the other is electrically connected to the other of the pair of electrodes of the liquid crystal element 570. A gate electrode of the transistor 550 is electrically connected to the scan line GL_m. The transistor 550 has a function of controlling writing of data of a data signal.

One of a pair of electrodes of the capacitor 560 is electrically connected to a wiring to which a potential is supplied (hereinafter referred to as a potential supply line VL), and the other is electrically connected to the other of the pair of electrodes of the liquid crystal element 570. The potential value of the potential supply line VL is set in accordance with the specifications of the pixel circuit 501 as appropriate. The capacitor 560 has a function of a storage capacitor for storing written data.

In the display device including the pixel circuits 501 in FIG. 49(B), for example, the gate driver 504a in FIG. 49(A) sequentially selects the pixel circuits 501 row by row to turn on the transistors 550, and data of data signals is written.

When the transistors 550 are turned off, the pixel circuits 501 in which the data has been written are brought into a holding state. This operation is sequentially performed row by row; thus, an image can be displayed.

Each of the plurality of pixel circuits 501 in FIG. 49(A) can have the configuration illustrated in FIG. 49(C), for example.

The pixel circuit 501 in FIG. 49(C) includes transistors 552 and 554, a capacitor 562, and a light-emitting element 572. The transistors described in the above embodiments can be used as one of or both the transistor 552 and the transistor 554.

One of a source electrode and a drain electrode of the transistor 552 is electrically connected to a wiring to which a data signal is supplied (hereinafter referred to as a signal line DL_n). A gate electrode of the transistor 552 is electrically connected to a wiring to which a gate signal is supplied (hereinafter referred to as a scan line GL_m).

The transistor 552 has a function of controlling writing of data of a data signal.

One of a pair of electrodes of the capacitor 562 is electrically connected to a wiring to which a potential is applied (hereinafter referred to as a potential supply line VL_a), and the other is electrically connected to the other of the source electrode and the drain electrode of the transistor 552.

The capacitor 562 has a function of a storage capacitor for storing written data.

One of a source electrode and a drain electrode of the transistor 554 is electrically connected to the potential supply line VL_a. Furthermore, a gate electrode of the transistor 554 is electrically connected to the other of the source electrode and the drain electrode of the transistor 552.

One of an anode and a cathode of the light-emitting element 572 is electrically connected to a potential supply line VL_b, and the other is electrically connected to the other of the source electrode and the drain electrode of the transistor 554.

As the light-emitting element 572, an organic electroluminescent element (also referred to as an organic EL element) or the like can be used, for example. However, the light-emitting element 572 is not limited to this; an inorganic EL element formed of an inorganic material may be used.

Note that a high power supply potential VDD is applied to one of the potential supply line VL_a and the potential supply line VL_b, and a low power supply potential VSS is applied to the other.

In the display device that includes the pixel circuits 501 in FIG. 49(C), the gate driver 504a in FIG. 49(A) sequentially selects the pixel circuits 501 row by row to turn on the transistors 552, and data of data signals is written.

When the transistors 552 are turned off, the pixel circuits 501 in which the data has been written are brought into a holding state. Furthermore, the amount of current flowing between the source electrode and the drain electrode of the transistor 554 is controlled in accordance with the potential of the written data signal, and the light-emitting element 572 emits light with luminance corresponding to the amount of flowing current. This operation is sequentially performed row by row; thus, an image is displayed.

At least part of any of the structure examples, the drawings corresponding thereto, and the like described in this embodiment can be implemented in combination with any of the other structure examples, the other drawings corresponding thereto, and the like as appropriate.

At least part of this embodiment can be implemented in combination with any of the other embodiments described in this specification as appropriate.

### Embodiment 13

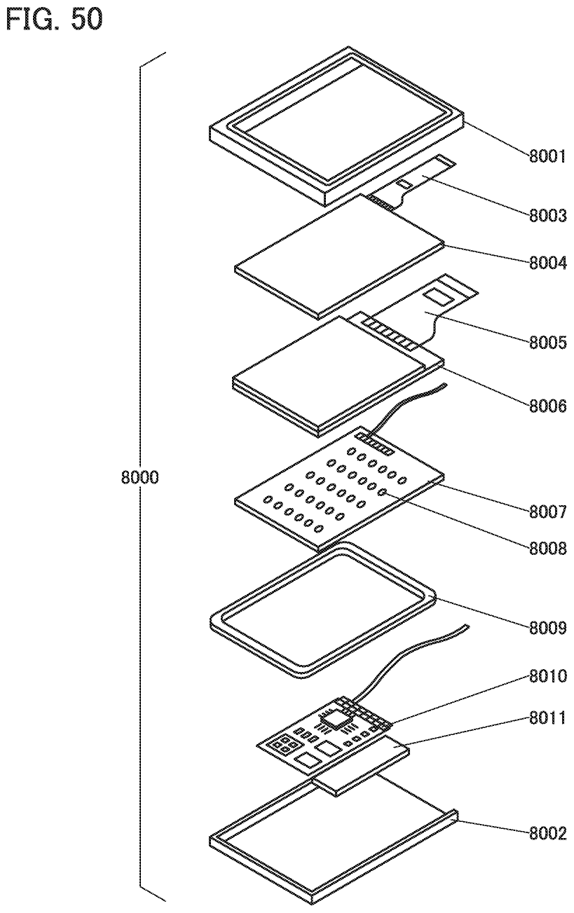

In this embodiment, a display module that includes the semiconductor device of one embodiment of the present invention will be described with reference to FIG. 50.

### [1. Display Module]

In a display module 8000 illustrated in FIG. 50, a touch panel 8004 connected to an FPC 8003, a display panel 8006 connected to an FPC 8005, a backlight 8007, a frame 8009, a printed board 8010, and a battery 8011 are provided between an upper cover 8001 and a lower cover 8002.

The semiconductor device of one embodiment of the present invention can be used for, for example, the display panel 8006.

The shapes and sizes of the upper cover 8001 and the lower cover 8002 can be changed as appropriate in accordance with the sizes of the touch panel 8004 and the display panel 8006.

The touch panel 8004 can be a resistive or capacitive touch panel and overlap with the display panel 8006. Alternatively, a counter substrate (sealing substrate) of the display panel 8006 can have a touch panel function. Further alternatively, a photosensor may be provided in each pixel of the display panel 8006 to form an optical touch panel.

The backlight 8007 includes a light source 8008. Although a structure in which the light source 8008 is provided over the backlight 8007 is illustrated in FIG. 50, one embodiment of the present invention is not limited to this. For example, a structure in which the light source 8008 is provided at an end portion of the backlight 8007 and a light diffusion plate is further provided may be employed. Note that the backlight 8007 need not be provided in the case where a self-luminous light-emitting element such as an organic EL element is used or in the case where a reflective panel or the like is employed.

The frame 8009 has a function of an electromagnetic shield for blocking electromagnetic waves generated by the operation of the printed circuit board 8010, in addition to a function of protecting the display panel 8006. The frame 8009 may also have a function of a radiator plate.

The printed board 8010 is provided with a power supply circuit and a signal processing circuit for outputting a video signal and a clock signal. As a power source for supplying power to the power supply circuit, an external commercial power source or a power source using the battery 8011 provided separately may be used. The battery 8011 can be omitted in the case of using a commercial power source.

The display module 8000 may be additionally provided with a component such as a polarizing plate, a retardation plate, or a prism sheet.

At least part of the structure examples, the drawings corresponding thereto, and the like described in this embodiment can be implemented in combination with the other structure examples, the other drawings corresponding thereto, and the like as appropriate.

At least part of this embodiment can be implemented in combination with the other embodiments described in this specification as appropriate.

### REFERENCE NUMERALS

100 capacitor
100A transistor
102 substrate
104 insulating layer
108 semiconductor layer
108n region
110 conductor
112 conductor
114 metal oxide layer
116 insulating layer
118 insulating layer
120 conductor
121a conductive layer
121b conductive layer
130 insulator
140 insulating layer
141 conductive layer
141a opening portion
141b opening portion
142 conductive layer
150 insulator
200 transistor
200a transistor
200b transistor
200c transistor
200d transistor
200e transistor
200f transistor
200g transistor
200h transistor
200i transistor
200j transistor
200k transistor
203 conductor
203a conductor
203b conductor
205 conductor
205a conductor
205b conductor
208 insulator
210 insulator
212 insulator
214 insulator
216 insulator
218 conductor
220 insulator
222 insulator
224 insulator
224A insulating film
230 oxide
230a oxide
230A oxide film
230b oxide
230B oxide film
230c oxide
230C oxide film
231 region
231a region
231b region
232 junction region
232a junction region
232b junction region
234 region
239 region
246 conductor
248 conductor
250 insulator
250A insulating film
252a conductor
252b conductor
260 conductor
260a conductor
260A conductive film
260b conductor
260B conductive film
270 insulator
270A insulating film
271 insulator
271A insulating film
272 insulator
272A insulating film
274 insulator
274A insulating film
275 insulator
275A insulating film
280 insulator
282 insulator
286 insulator
288 excess oxygen
300 transistor
311 substrate
313 semiconductor region
314a low-resistance region
314b low-resistance region
315 insulator
316 conductor
320 insulator
322 insulator
324 insulator
326 insulator
328 conductor
330 conductor
350 insulator
352 insulator
354 insulator
356 conductor
360 insulator
362 insulator
364 insulator
366 conductor
370 insulator
372 insulator
374 insulator
376 conductor
380 insulator
382 insulator
384 insulator
386 conductor
400 transistor
403 conductor
403a conductor
403b conductor
405 conductor
405a conductor
405b conductor
430c oxide
431a oxide
431b oxide
432a oxide
432b oxide
450 insulator
460 conductor
460a conductor
460b conductor
470 insulator
472 insulator
501 pixel circuit
502 pixel portion
504 driver circuit portion
504a gate driver
504b source driver
506 protection circuit
507 terminal portion
550 transistor
552 transistor
554 transistor
560 capacitor
562 capacitor
570 liquid crystal element
572 light-emitting element
650a memory cell
650b memory cell
700 display device
700A display device
701 substrate
702 pixel portion
704 source driver circuit portion
705 substrate
706 gate driver circuit portion
708 FPC terminal portion
710 signal line
711 wiring portion
712 sealant
716 FPC
721 source driver IC
722 gate driver circuit
723 FPC
724 printed circuit board
730 insulating film
732 sealing film
734 insulating film
736 coloring film
738 light-blocking film
750 transistor
752 transistor
760 connection electrode
770 planarization insulating film
772 conductive film
773 insulating film
774 conductive film
775 liquid crystal element
776 liquid crystal layer
778 structure body
780 anisotropic conductive film
782 light-emitting element
786 EL layer
788 conductive film
790 capacitor
811 substrate
812 circuit region
813 separation region
814 separation line
815 chip
850 electronic component
852 printed circuit board
854 mounted board
855 lead
1001 wiring
1002 wiring
1003 wiring
1004 wiring
1005 wiring
1006 wiring
1007 wiring
1008 wiring
1009 wiring
1010 wiring
1400 DOSRAM
1405 controller
1410 row circuit
1411 decoder
1412 word line driver circuit
1413 column selector
1414 sense amplifier driver circuit
1415 column circuit
1416 global sense amplifier array
1417 input/output circuit
1420 MC-SA array
1422 memory cell array
1423 sense amplifier array
1425 local memory cell array
1426 local sense amplifier array
1444 switch array
1445 memory cell
1446 sense amplifier
1447 global sense amplifier
1600 NOSRAM
1610 memory cell array
1611 memory cell
1611-1614 memory cells
1612 memory cell
1613 memory cell
1614 memory cell
1640 controller
1650 row driver
1651 row decoder
1652 word line driver
1660 column driver
1661 column decoder
1662 driver
1663 DAC
1670 output driver
1671 selector
1672 ADC
1673 output buffer
2000 CDMA
2910 information terminal
2911 housing
2912 display portion
2913 camera
2914 speaker portion
2915 operation switch
2916 external connection portion
2917 microphone
2920 notebook personal computer
2921 housing
2922 display portion
2923 keyboard
2924 pointing device
2940 video camera
2941 housing
2942 housing
2943 display portion
2944 operation switch
2945 lens
2946 joint
2950 information terminal
2951 housing
2952 display portion
2960 information terminal
2961 housing
2962 display portion
2963 band
2964 buckle
2965 operation switch
2966 input output terminal
2967 icon
2980 car
2981 car body
2982 wheel
2983 dashboard
2984 light
3110 OS-FPGA
3111 controller
3112 word driver
3113 data driver
3115 programmable area
3117 IOB
3119 core
3120 LAB
3121 PLE
3123 LUT block
3124 register block
3125 selector
3126 CM
3127 power switch
3128 CM
3130 SAB
3131 SB
3133 PRS
3135 CM
3137 memory circuit
3137B memory circuit
3140 OS-FF
3141 FF
3142 shadow register
3143 memory circuit
3143B memory circuit
3188 inverter circuit
3189 inverter circuit
4010 arithmetic portion
4011 analog arithmetic circuit
4012 DOSRAM
4013 NOSRAM
4014 FPGA
4020 control portion
4021 CPU
4022 GPU
4023 PLL
4025 PROM
4026 memory controller
4027 power supply circuit
4028 PMU
4030 input/output portion
4031 external memory control circuit
4032 audio codec
4033 video codec
4034 general-purpose input/output module
4035 communication module
4041 AI system
4041_n AI system
4041_1 AI system
4041A AI system
4041B AI system
4098 bus line
4099 network
7000 AI system IC
7001 lead
7003 circuit portion
7031 Si transistor layer
7032 wiring layer
7033 OS transistor layer
8000 display module
8001 upper cover
8002 lower cover
8003 FPC
8004 touch panel
8005 FPC
8006 display panel
8007 backlight
8008 light source
8009 frame
8010 printed board
8011 battery

1. A semiconductor device comprising:
a first insulator over a substrate;
an oxide over the first insulator;
a second insulator over the oxide;
a conductor over the second insulator;
a third insulator in contact with a side surface of the second insulator and a side surface of the conductor;
a fourth insulator in contact with a top surface of the oxide and a side surface of the third insulator;
a fifth insulator over the fourth insulator;
a sixth insulator over the fifth insulator; and
a seventh insulator over the sixth insulator,
wherein the sixth insulator comprises oxygen, and
wherein the sixth insulator and the first insulator comprise a region where the sixth insulator and the first insulator are in contact with each other.

2. A semiconductor device comprising:
a first insulator over a substrate;
a first oxide over the first insulator;
a second oxide over the first oxide;
a third oxide over the second oxide;
a second insulator over the third oxide;
a conductor over the second insulator;
a third insulator in contact with a side surface of the second insulator and a side surface of the conductor;
a fourth insulator in contact with a top surface of the second oxide, a side surface of the third oxide, and a side surface of the third insulator;
a fifth insulator over the fourth insulator;
a sixth insulator over the fifth insulator; and
a seventh insulator over the sixth insulator,
wherein the sixth insulator comprises oxygen,
wherein the sixth insulator and the first insulator comprise a region where the sixth insulator and the first insulator are in contact with each other,
wherein the third oxide less easily transmits oxygen than the second insulator, and
wherein the third oxide less easily transmits oxygen than the second oxide.

3. The semiconductor device according to claim 1, wherein the third insulator, the fifth insulator, and the seventh insulator comprise an oxide of one or both of aluminum and hafnium.

4. The semiconductor device according to claim 1, wherein an angle formed by a side surface of the conductor and a bottom surface of the oxide is greater than or equal to 75° and less than or equal to 100°.

5. The semiconductor device according to claim 1,
wherein the oxide comprises a curved surface between a side surface of the oxide and a top surface of the oxide, and
wherein a radius of curvature of the curved surface is greater than or equal to 3 nm and less than or equal to 10 nm.

6. The semiconductor device according to claim 1,
wherein the oxide comprises In, an element M, and Zn, and
wherein the element M is Al, Ga, Y, or Sn.

7. The semiconductor device according to claim 1,
wherein the oxide comprises a first region and a second region overlapping with the second insulator,
wherein the first region is in contact with the fourth insulator, and
wherein the first region has a higher concentration of at least one of hydrogen and nitrogen than the second region.

8. The semiconductor device according to claim 7, wherein the second region comprises a portion overlapping with the third insulator and the second insulator.

9. The semiconductor device according to claim 1, wherein the conductor comprises a conductive oxide.

10. The semiconductor device according to claim 1, wherein the fourth insulator comprises one or both of hydrogen and nitrogen.

11. A manufacturing method of a semiconductor device, comprising:
forming a first insulator over a substrate;
forming an oxide layer over the first insulator;
forming a first insulating film and a conductive film in order over the oxide layer;
etching the first insulating film and the conductive film to form a second insulator and a conductor;
forming a second insulating film by an ALD method so as to cover the first insulator, the oxide layer, the second insulator, and the conductor;
performing dry etching treatment on the second insulating film so as to form a third insulator in contact with a side surface of the second insulator and a side surface of the conductor;
forming a third insulating film by a PECVD method so as to cover the first insulator, the oxide layer, the third insulator, and the conductor;
forming a fourth insulating film over the third insulating film;
processing the third insulating film and the fourth insulating film so that the oxide layer is covered, so as to form a fourth insulator and a fifth insulator;
forming a sixth insulator over the fifth insulator; and
forming a seventh insulator over the sixth insulator by a sputtering method.
